(19) United States
(12) Patent Application Publication
(10) Pub. No.: US 2026/0286175 A1
(43) Pub. Date: Sep. 24, 2026

(54) RESIN, COPOLYMER, ELECTRONIC SUBSTRATE MATERIAL, RESIN COMPOSITION, COATING LIQUID COMPOSITION, CURED PRODUCT, FILM, SHEET, AND ELECTRONIC SUBSTRATE

(71) Applicant: IDEMITSU KOSAN CO.,LTD., Tokyo (JP)

(72) Inventors: Masato NAKAMURA, Tokyo (JP); Hironobu MORISHITA, Tokyo (JP)

(73) Assignee: IDEMITSU KOSAN CO.,LTD., Tokyo (JP)

(21) Appl. No.: 19/477,245

(22) PCT Filed: Feb. 26, 2024
(86) PCT No.: PCT/JP2024/006857

§ 371 Date: Oct. 21, 2025

(30) Foreign Application Priority Data
Apr. 28, 2023 (JP) 2023-074455

(51) Int. Cl. C09D 169/00; C08G 63/199; C08G 64/06; C08G 64/24; C09D 163/00; C09D 167/02

(52) U.S. Cl. CPC C09D 169/00; C08G 63/199; C08G 64/06; C08G 64/24; C09D 163/00; C09D 167/02

(57) ABSTRACT

An electronic substrate material includes a first resin. The first resin is at least one resin selected from the group consisting of polycarbonate, polyester, and polyester polycarbonate. The first resin includes a structural unit represented by a formula (C1) below and at least one structural unit selected from the group consisting of structural units represented by formulae (A1), (B1), and (D1).

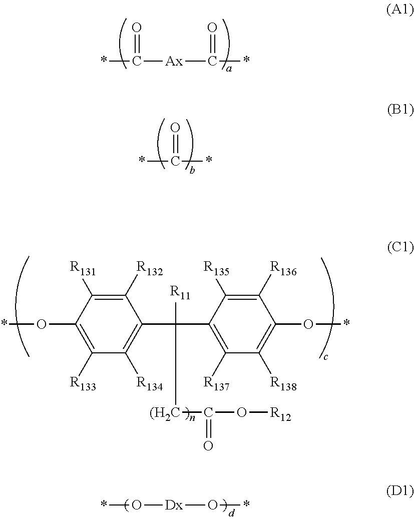

### TECHNICAL FIELD

The present invention relates to a resin, copolymer, electronic substrate material, resin composition, coating liquid composition, cured product, film, sheet, and electronic substrate.

### BACKGROUND ART

Next-generation high-speed communication technologies, known as 5G or 6G, have features such as “high speed and large capacity,” “multiple simultaneous connections,” and “ultra-low latency”. Such technologies are being introduced into a variety of communication networks in fields such as electrical and electronic equipment, mobility such as automobiles, and medical care, bringing about changes in the economy and society. Electronic circuit boards and semiconductor package substrates (hereinafter referred to as electronic substrates) used in electronic devices such as communication devices in the above fields also face various challenges in improving their performance. One of the major issues is that as the volume of information and communication increases, the frequencies used for communication become higher. As a result, materials used in current electronic substrates have a large transmission loss, resulting in problems of energy loss and heat generation from the substrate. The transmission loss is a ratio of loss that occurs when electric signal energy is converted into undesired energy such as thermal energy.

The transmission loss consists of two components: conductor loss and dielectric loss. The dielectric loss is proportional to the square root of the dielectric constant (Dk) of the dielectric and to the dissipation factor (Df) of the dielectric. Thus, in order to reduce, the transmission loss of the electronic substrates and the like in which an insulating material is used, it is necessary to reduce the dielectric constant and dissipation factor of the material used as the insulating material. In addition, there is a trend to reduce the roughness of an interface between the substrate and the metal wiring in order to reduce conductor loss. Accordingly, insulating materials are increasingly required to exhibit better adhesion to metallic foils and metallic plating.

Furthermore, electronic substrate materials are required to have not only reduced transmission loss but also various other properties. Examples thereof include high heat resistance that can withstand high-temperature solder reflow, and low thermal expansion to prevent warping of the substrate due to the difference in thermal expansion coefficient between the copper circuit and the insulating layer. When the electronic substrate material as an insulating material is used for applications in which it is applied and molded onto a substrate, the properties required of the electronic substrate material include high solubility in solvents, low solution viscosity, and filler dispersibility. Furthermore, when the electronic substrate material is used for forming thin films employed in the lamination molding of wiring layers, the properties required of the electronic substrate material include high solubility in solvents, low viscosity, filler dispersibility, and small variations in dielectric properties under service conditions such as temperature and humidity.

As the insulating material, resins such as thermoplastic resins including liquid crystal polymers, polyphenylene ether, polyimide, and fluorine resin, and thermosetting resins including epoxy resin and maleimide resin, have been improved and developed for electronic substrates for various applications.

Among these resins, polycarbonate resin has been used as a material for molded products in various industrial fields because of its excellent mechanical properties, thermal properties, electrical properties, transparency, and the like. However, for use in the above-described electronic substrates for high-frequency applications, general bisphenol A polycarbonates have poor solubility in organic solvents and poor solution stability, and are therefore difficult to apply to the formation of insulating coating solutions for fine wiring or to the molding of thin insulating films.

Patent Literature 1 describes that a polyester resin using divalent phenol derived from diphenolic acid can be used as a binder resin for an electrophotographic photoreceptor.

Patent Literature 2 describes a thermosetting resin synthesized using divalent phenol derived from diphenolic acid.

### CITATION LIST

### Patent Literature(S)

Patent Literature 1: JP 2001-290288 A
Patent Literature 2: JP 2008-222732 A

### SUMMARY OF THE INVENTION

### Problem(s) to be Solved by the Invention

Patent Literature 1 does not refer to the curing performance of a polyester resin and an epoxy resin, and furthermore, neither discloses nor suggests properties required for use as an electronic substrate, such as dielectric properties and thermal properties. Patent Literature 2 does not describe the compatibility of the thermosetting resin with solvents other than water, and furthermore, neither discloses nor suggests properties required for use as an electronic substrate, such as dielectric properties and thermal properties.

An object of the invention is to provide a resin, a copolymer, and an electronic substrate material, each of which has dielectric properties enabling use as an electronic substrate material and exhibits excellent solubility in non-halogen solvents; to provide a resin composition, a coating liquid composition, a film, a sheet, and an electronic substrate each containing the resin; and to provide a cured product obtained by curing the resin composition.

### Means for Solving the Problem(s)

As a result of extensive studies, the inventors have found that a resin, a copolymer, and an electronic substrate material each having specific structural units possess dielectric properties that enable their use as an electronic substrate material and exhibit excellent solubility in non-halogen solvents. That is, the gist of the invention lies in [Configuration 1] to [Configuration 48] as below.

### [Configuration 1]

An electronic substrate material includes a first resin, in which
the first resin is at least one resin selected from the group consisting of polycarbonate, polyester, and polyester polycarbonate, and
the first resin includes a structural unit represented by a formula (C1) below, and at least one structural unit selected from the group consisting of structural units represented by formulae (A1), (B1), and (D1) below.

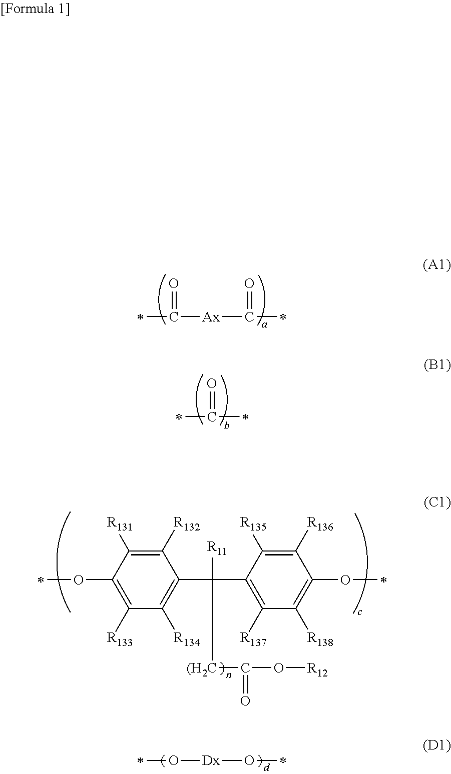

In the formula (A1):
Ax is a divalent group containing at least one group selected from the group consisting of a substituted or unsubstituted divalent aromatic hydrocarbon group, a substituted or unsubstituted divalent cyclic aliphatic hydrocarbon group, and a substituted or unsubstituted divalent acyclic aliphatic hydrocarbon group; and
a is a mole fraction of the structural unit represented by the formula (A1),
in the formula (B1):
b is a mole fraction of the structural unit represented by the formula (B1); and
the structural unit represented by the formula (B1) is different from carbonyl groups in the formulae (A1), (C1), and (D1),
in the formula (C1):
R₁₁ is a hydrogen atom, a substituted or unsubstituted alkyl group having 1 to 20 carbon atoms, a substituted or unsubstituted cycloalkyl group having 3 to 20 ring carbon atoms, a substituted or unsubstituted cycloalkoxy group having 3 to 20 ring carbon atoms, a substituted or unsubstituted alkenyl group having 2 to 10 carbon atoms, or a substituted or unsubstituted aryl group having 6 to 14 carbon atoms;
R₁₂ is a group containing at least one selected from the group consisting of a substituted or unsubstituted monovalent aromatic hydrocarbon group, a substituted or unsubstituted monovalent cyclic aliphatic hydrocarbon group, a substituted or unsubstituted monovalent acyclic aliphatic hydrocarbon group, a substituted or unsubstituted divalent aromatic hydrocarbon group, a substituted or unsubstituted divalent cyclic aliphatic hydrocarbon group, and a substituted or unsubstituted divalent acyclic aliphatic hydrocarbon group;
R₁₃₁ to R₁₃₈ are each independently a hydrogen atom, a substituted or unsubstituted alkyl group having 1 to 10 carbon atoms, a substituted or unsubstituted alkenyl group having 2 to 10 carbon atoms, a substituted or unsubstituted alkynyl group having 2 to 10 carbon atoms, a substituted or unsubstituted cycloalkyl group having 3 to 20 ring carbon atoms, or a substituted or unsubstituted aryl group having 6 to 14 carbon atoms;
c is a mole fraction of the structural unit represented by the formula (C1); and
n represents 0, 1, 2, 3, or 4; and
in the formula (D1):
Dx is a divalent group containing at least one group selected from the group consisting of a substituted or unsubstituted divalent aromatic hydrocarbon group, a substituted or unsubstituted divalent cyclic aliphatic hydrocarbon group, and a substituted or unsubstituted divalent acyclic aliphatic hydrocarbon group; and
d is a mole fraction of the structural unit represented by the formula (D1),
substituents for a “substituted or unsubstituted” group are bonded to each other to form a monocyclic ring, bonded to each other to form a fused ring, or not bonded to each other,
each * in the formulae (A1), (B1), (C1), and (D1) represents a bond,
when the first resin includes a plurality of structural units represented by the formula (A1), the plurality of structural units represented by the formula (A1) are identical to each other or different from each other,
when the first resin includes a plurality of structural units represented by the formula (C1), the plurality of structural units represented by the formula (C1) are identical to each other or different from each other, and
when the first resin includes a plurality of structural units represented by the formula (D1), the plurality of structural units represented by the formula (D1) are identical to each other or different from each other.

### [Configuration 2]

In the electronic substrate material according to [Configuration 1], the structural unit represented by the formula (D1) is represented by a formula (D2) below.

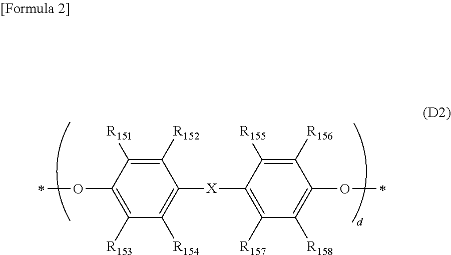

In the formula (D2):
R₁₅₁ to R₁₅₈ are each independently a hydrogen atom, a halogen atom, a substituted or unsubstituted alkyl group having 1 to 18 carbon atoms, a substituted or unsubstituted alkoxy group having 1 to 18 carbon atoms, a substituted or unsubstituted cycloalkyl group having 6 to 20 ring carbon atoms, a substituted or unsubstituted cycloalkoxy group having 6 to 20 ring carbon atoms, a substituted or unsubstituted alkenyl group having 2 to 10 carbon atoms, a substituted or unsubstituted aryl group having 6 to 14 ring carbon atoms, a substituted or unsubstituted aryloxy group having 6 to 14 ring carbon atoms, a substituted or unsubstituted aralkyl group having 7 to 20 carbon atoms, a substituted or unsubstituted aralkyloxy group having 7 to 20 carbon atoms, a nitro group, an aldehyde group, a cyano group, and a carboxy group;
X is (i) a single bond, (ii) a group selected from the group consisting of a substituted or unsubstituted alkylene group having 1 to 28 carbon atoms, a substituted or unsubstituted alkylidene group having 2 to 28 carbon atoms, a substituted or unsubstituted cycloalkylene group having 5 to 15 ring carbon atoms, a substituted or unsubstituted cycloalkylidene group having 3 to 26 ring carbon atoms, a substituted or unsubstituted arylene group having 6 to 20 ring carbon atoms, —S—, —SO—, —SO₂—, —O—, and —CO—, or (iii) a divalent group formed by linking two or more groups selected from the group described in (ii);
d represents the same as d in the formula (D1); and
each * represents a bond.

### [Configuration 3]

In the electronic substrate material according to [Configuration 2], X is a substituted or unsubstituted cycloalkylidene group having 5 to 15 ring carbon atoms.

### [Configuration 4]

In the electronic substrate material according to [Configuration 2] or [Configuration 3], R₁₅₁ to R₁₅₈ are each independently a hydrogen atom, a substituted or unsubstituted alkyl group having 1 to 18 carbon atoms, or a substituted or unsubstituted cycloalkyl group having 6 to 20 ring carbon atoms.

### [Configuration 5]

In the electronic substrate material according to any one of [Configuration 1] to [Configuration 4], the first resin is a resin including the structural units represented by the formulae (C1) and (B1).

### [Configuration 6]

In the electronic substrate material according to [Configuration 5], a ratio c:d of a mole fraction c of the structural unit represented by the formula (C1) to a mole fraction d of the structural unit represented by the formula (D1) is from 0.5:99.5 to 100:0.

### [Configuration 7]

In the electronic substrate material according to [Configuration 6], the ratio c:d of the mole fraction c of the structural unit represented by the formula (C1) to the mole fraction d of the structural unit represented by the formula (D1) is from 20:80 to 100:0.

### [Configuration 8]

In the electronic substrate material according to any one of [Configuration 1] to [Configuration 7], R₁₂ includes a substituted or unsubstituted monovalent cyclic aliphatic hydrocarbon group.

### [Configuration 9]

In the electronic substrate material according to any one of [Configuration 1] to [Configuration 8], R₁₂ includes a substituted or unsubstituted cycloalkyl group having 3 to 20 ring carbon atoms.

### [Configuration 10]

In the electronic substrate material according to any one of [Configuration 1] to [Configuration 9], the structural unit represented by the formula (C1) is represented by a formula (C2) below.

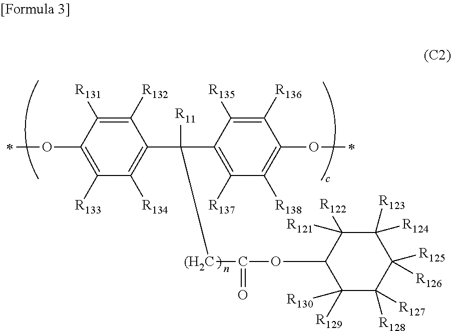

In the formula (C2):
R₁₁, R₁₃₁ to R₁₃₈, c, and n respectively represent the same as R₁₁, R₁₃₁ to R₁₃₈, c, and n in the formula (C1);
R₁₂₁ to R₁₃₀ are each independently a hydrogen atom, a substituted or unsubstituted alkyl group having 1 to 20 carbon atoms, a substituted or unsubstituted cycloalkyl group having 3 to 20 ring carbon atoms, a substituted or unsubstituted cycloalkoxy group having 3 to 20 ring carbon atoms, a substituted or unsubstituted alkenyl group having 2 to 10 carbon atoms, or a substituted or unsubstituted aryl group having 6 to 14 carbon atoms; and
each * represents a bond.

### [Configuration 11]

In the electronic substrate material according to any one of [Configuration 1] to [Configuration 10], R₁₃₁, R₁₃₃, R₁₃₆, and R₁₃₈ are each independently a hydrogen atom, a substituted or unsubstituted alkyl group having 1 to 5 carbon atoms, a substituted or unsubstituted cycloalkyl group having 3 to 20 ring carbon atoms, or a substituted or unsubstituted aryl group having 6 to 14 ring carbon atoms.

### [Configuration 12]

A coating liquid composition includes the electronic substrate material according to any one of [Configuration 1] to [Configuration 11] and a non-halogen solvent.

### [Configuration 13]

The coating liquid composition according to [Configuration 12] further includes an epoxy resin.

### [Configuration 14]

A film includes the electronic substrate material according to any one of [Configuration 1] to [Configuration 11].

### [Configuration 15]

A sheet includes the electronic substrate material according to any one of [Configuration 1] to [Configuration 11].

### [Configuration 16]

An electronic substrate includes the electronic substrate material according to any one of [Configuration 1] to [Configuration 11].

### [Configuration 17]

A copolymer includes: at least one copolymer selected from the group consisting of a polycarbonate copolymer, a polyester copolymer, and a polyester polycarbonate copolymer, in which the copolymer includes a structural unit represented by a formula (C1) below, and at least one structural unit selected from the group consisting of structural units represented by formulae (A1), (B1), and (D1) below.

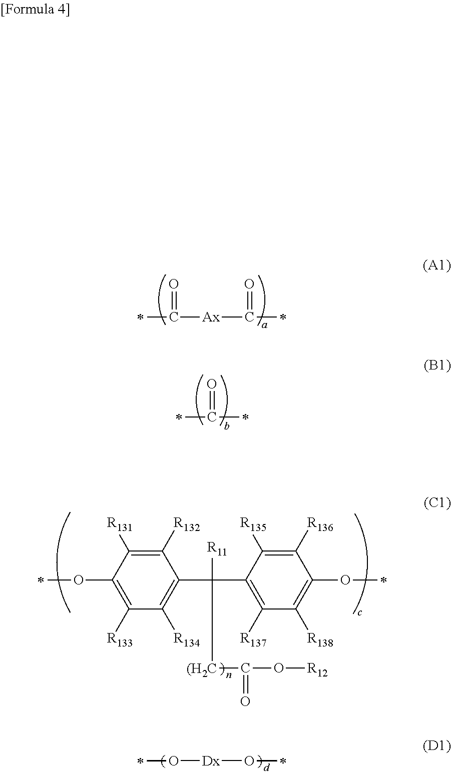

In the formula (A1):
Ax is a divalent group containing at least one group selected from the group consisting of a substituted or unsubstituted divalent aromatic hydrocarbon group, a substituted or unsubstituted divalent cyclic aliphatic hydrocarbon group, and a substituted or unsubstituted divalent acyclic aliphatic hydrocarbon group; and
a is a mole fraction of the structural unit represented by the formula (A1),
in the formula (B1):
b is a mole fraction of the structural unit represented by the formula (B1); and
the structural unit represented by the formula (B1) is different from carbonyl groups in the formulae (A1), (C1), and (D1),
in the formula (C1):
R₁₁ is a hydrogen atom, a substituted or unsubstituted alkyl group having 1 to 20 carbon atoms, a substituted or unsubstituted cycloalkyl group having 3 to 20 ring carbon atoms, a substituted or unsubstituted cycloalkoxy group having 3 to 20 ring carbon atoms, a substituted or unsubstituted alkenyl group having 2 to 10 carbon atoms, or a substituted or unsubstituted aryl group having 6 to 14 carbon atoms;
R₁₂ is a group containing at least one selected from the group consisting of a substituted or unsubstituted monovalent aromatic hydrocarbon group, a substituted or unsubstituted monovalent cyclic aliphatic hydrocarbon group, a substituted or unsubstituted monovalent branched-chain aliphatic hydrocarbon group, a substituted or unsubstituted divalent aromatic hydrocarbon group, a substituted or unsubstituted divalent cyclic aliphatic hydrocarbon group, and a substituted or unsubstituted divalent branched-chain aliphatic hydrocarbon group;
R₁₃₁ to R₁₃₈ are each independently a hydrogen atom, a substituted or unsubstituted alkyl group having 1 to 10 carbon atoms, a substituted or unsubstituted alkenyl group having 2 to 10 carbon atoms, a substituted or unsubstituted alkynyl group having 2 to 10 carbon atoms, a substituted or unsubstituted cycloalkyl group having 3 to 20 ring carbon atoms, or a substituted or unsubstituted aryl group having 6 to 14 carbon atoms;
c is a mole fraction of the structural unit represented by the formula (C1); and
n represents 0, 1, 2, 3, or 4; and
in the formula (D1):
Dx is a divalent group containing at least one group selected from the group consisting of a substituted or unsubstituted divalent aromatic hydrocarbon group, a substituted or unsubstituted divalent cyclic aliphatic hydrocarbon group, and a substituted or unsubstituted divalent acyclic aliphatic hydrocarbon group;
Dx includes no divalent group represented by a formula (D3) below; and
d is a mole fraction of the structural unit represented by the formula (D1),
substituents for a “substituted or unsubstituted” group are bonded to each other to form a monocyclic ring, bonded to each other to form a fused ring, or not bonded to each other,
each * in the formulae (A1), (B1), (C1), and (D1) represents a bond,
when the copolymer includes a plurality of structural units represented by the formula (A1), the plurality of structural units represented by the formula (A1) are identical to each other or different from each other,
when the copolymer includes a plurality of structural units represented by the formula (C1), the plurality of structural units represented by the formula (C1) are identical to each other or different from each other, and
when the copolymer includes a plurality of structural units represented by the formula (D1), the plurality of structural units represented by the formula (D1) are identical to each other or different from each other.

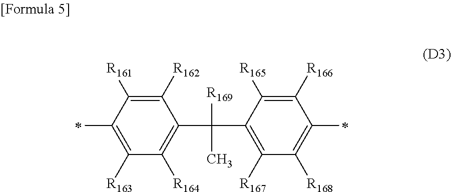

In the formula (D3):
R₁₆₉ is a methyl group or a phenyl group;
R₁₆₁ to R₁₆₈ are each independently a hydrogen atom, a halogen atom, a substituted or unsubstituted alkyl group having 1 to 18 carbon atoms, a substituted or unsubstituted alkoxy group having 1 to 18 carbon atoms, a substituted or unsubstituted cycloalkyl group having 6 to 20 ring carbon atoms, a substituted or unsubstituted cycloalkoxy group having 6 to 20 ring carbon atoms, a substituted or unsubstituted alkenyl group having 2 to 10 carbon atoms, a substituted or unsubstituted aryl group having 6 to 14 ring carbon atoms, a substituted or unsubstituted aryloxy group having 6 to 14 ring carbon atoms, a substituted or unsubstituted aralkyl group having 7 to 20 carbon atoms, a substituted or unsubstituted aralkyloxy group having 7 to 20 carbon atoms, a nitro group, an aldehyde group, a cyano group, and a carboxy group; and
each * represents a bond.

### [Configuration 18]

In the copolymer according to [Configuration 17], the structural unit represented by the formula (D1) is represented by a formula (D2) below.

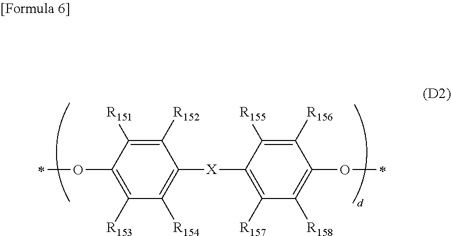

In the formula (D2):
R₁₅₁ to R₁₅₈ are each independently a hydrogen atom, a halogen atom, a substituted or unsubstituted alkyl group having 1 to 18 carbon atoms, a substituted or unsubstituted alkoxy group having 1 to 18 carbon atoms, a substituted or unsubstituted cycloalkyl group having 6 to 20 ring carbon atoms, a substituted or unsubstituted cycloalkoxy group having 6 to 20 ring carbon atoms, a substituted or unsubstituted alkenyl group having 2 to 10 carbon atoms, a substituted or unsubstituted aryl group having 6 to 14 ring carbon atoms, a substituted or unsubstituted aryloxy group having 6 to 14 ring carbon atoms, a substituted or unsubstituted aralkyl group having 7 to 20 carbon atoms, a substituted or unsubstituted aralkyloxy group having 7 to 20 carbon atoms, a nitro group, an aldehyde group, a cyano group, and a carboxy group;
X is (i) a single bond, (ii) a group selected from the group consisting of a substituted or unsubstituted alkylene group having 1 to 28 carbon atoms, a substituted or unsubstituted alkylidene group having 2 to 28 carbon atoms, a substituted or unsubstituted cycloalkylene group having 5 to 15 ring carbon atoms, a substituted or unsubstituted cycloalkylidene group having 3 to 26 ring carbon atoms, a substituted or unsubstituted arylene group having 6 to 20 ring carbon atoms, —S—, —SO—, —SO₂—, —O—, and —CO—, or (iii) a divalent group formed by linking two or more groups selected from the group described in (ii);
d represents the same as d in the formula (D1); and
each * represents a bond.

### [Configuration 19]

In the copolymer according to [Configuration 18], X is a substituted or unsubstituted cycloalkylidene group having 5 to 15 ring carbon atoms.

### [Configuration 20]

In the copolymer according to [Configuration 18] or [Configuration 19], R₁₅₁ to R₁₅₈ are each independently a hydrogen atom, a substituted or unsubstituted alkyl group having 1 to 18 carbon atoms, or a substituted or unsubstituted cycloalkyl group having 6 to 20 ring carbon atoms.

### [Configuration 21]

In the copolymer according to any one of [Configuration 17] to [Configuration 20], the copolymer includes the structural units represented by the formulae (C1) and (B1).

### [Configuration 22]

In the copolymer according to [Configuration 21], a ratio c:d of a mole fraction c of the structural unit represented by the formula (C1) to a mole fraction d of the structural unit represented by the formula (D1) is from 0.5:99.5 to 100:0.

### [Configuration 23]

In the copolymer according to [Configuration 22], the ratio c:d of the mole fraction c of the structural unit represented by the formula (C1) to the mole fraction d of the structural unit represented by the formula (D1) is from 0.5:99.5 to 50:50.

### [Configuration 24]

In the copolymer according to any one of [Configuration 17] to [Configuration 23], R₁₂ includes a substituted or unsubstituted monovalent cyclic aliphatic hydrocarbon group.

### [Configuration 25]

In the copolymer according to any one of [Configuration 17] to [Configuration 24], R₁₂ includes a substituted or unsubstituted cycloalkyl group having 3 to 20 ring carbon atoms.

### [Configuration 26]

In the copolymer according to any one of [Configuration 17] to [Configuration 25], the structural unit represented by the formula (C1) is represented by a formula (C2) below.

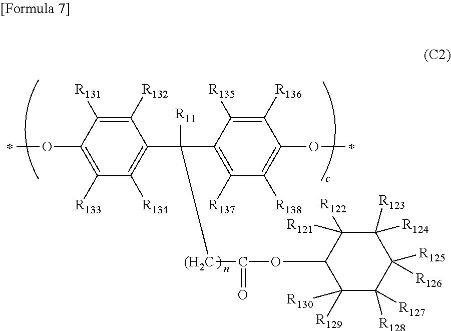

In the formula (C2):
R₁₁, R₁₃₁ to R₁₃₈, c, and n respectively represent the same as R₁₁, R₁₃₁ to R₁₃₈, c, and n in the formula (C1);
R₁₂₁ to R₁₃₀ are each independently a hydrogen atom, a substituted or unsubstituted alkyl group having 1 to 20 carbon atoms, a substituted or unsubstituted cycloalkyl group having 3 to 20 ring carbon atoms, a substituted or unsubstituted cycloalkoxy group having 3 to 20 ring carbon atoms, a substituted or unsubstituted alkenyl group having 2 to 10 carbon atoms, or a substituted or unsubstituted aryl group having 6 to 14 carbon atoms; and
each * represents a bond.

### [Configuration 27]

In the copolymer according to any one of [Configuration 17] to [Configuration 26], R₁₃₁, R₁₃₃, R₁₃₆, and R₁₃₈ are each independently a hydrogen atom, a substituted or unsubstituted alkyl group having 1 to 5 carbon atoms, a substituted or unsubstituted cycloalkyl group having 3 to 20 ring carbon atoms, or a substituted or unsubstituted aryl group having 6 to 14 ring carbon atoms.

### [Configuration 28]

A resin includes: at least one resin selected from the group consisting of polyester and polyester polycarbonate, in which the resin includes a structural unit represented by a formula (C1) below, and at least one structural unit selected from the group consisting of structural units represented by formulae (A1) and (B1) below.

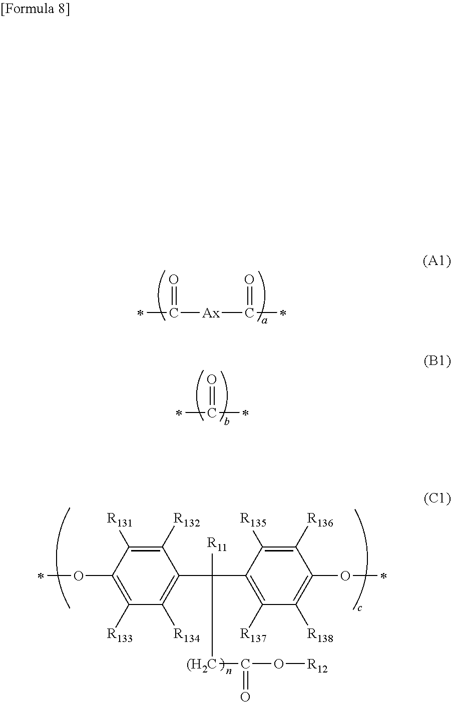

In the formula (A1):
Ax is a divalent group containing at least one group selected from the group consisting of a substituted or unsubstituted divalent aromatic hydrocarbon group, a substituted or unsubstituted divalent cyclic aliphatic hydrocarbon group, and a substituted or unsubstituted divalent acyclic aliphatic hydrocarbon group; and
a is a mole fraction of the structural unit represented by the formula (A1),
in the formula (B1):
b is a mole fraction of the structural unit represented by the formula (B1); and
the structural unit represented by the formula (B1) is different from carbonyl groups in the formulae (A1) and (C1),
in the formula (C1):
R₁₁ is a hydrogen atom, a substituted or unsubstituted alkyl group having 1 to 20 carbon atoms, a substituted or unsubstituted cycloalkyl group having 3 to 20 ring carbon atoms, a substituted or unsubstituted cycloalkoxy group having 3 to 20 ring carbon atoms, a substituted or unsubstituted alkenyl group having 2 to 10 carbon atoms, or a substituted or unsubstituted aryl group having 6 to 14 carbon atoms;
R₁₂ is a group containing at least one selected from the group consisting of a substituted or unsubstituted monovalent aromatic hydrocarbon group, a substituted or unsubstituted monovalent cyclic aliphatic hydrocarbon group, a substituted or unsubstituted monovalent acyclic aliphatic hydrocarbon group, a substituted or unsubstituted divalent aromatic hydrocarbon group, a substituted or unsubstituted divalent cyclic aliphatic hydrocarbon group, and a substituted or unsubstituted divalent acyclic aliphatic hydrocarbon group;
R₁₃₁ to R₁₃₈ are each independently a hydrogen atom, a substituted or unsubstituted alkyl group having 1 to 10 carbon atoms, a substituted or unsubstituted alkenyl group having 2 to 10 carbon atoms, a substituted or unsubstituted alkynyl group having 2 to 10 carbon atoms, a substituted or unsubstituted cycloalkyl group having 3 to 20 ring carbon atoms, or a substituted or unsubstituted aryl group having 6 to 14 carbon atoms;
c is a mole fraction of the structural unit represented by the formula (C1); and
n represents 0, 1, 2, 3, or 4,
substituents for a “substituted or unsubstituted” group are bonded to each other to form a monocyclic ring, bonded to each other to form a fused ring, or not bonded to each other,
each * in the formulae (A1), (B1), and (C1) represents a bond,
when the resin includes a plurality of structural units represented by the formula (A1), the plurality of structural units represented by the formula (A1) are identical to each other or different from each other, and
when the resin includes a plurality of structural units represented by the formula (C1), the plurality of structural units represented by the formula (C1) are identical to each other or different from each other.

### [Configuration 29]

A resin composition includes a first resin and a second resin, in which
the first resin is at least one resin selected from the group consisting of polycarbonate, polyester, and polyester polycarbonate,
the first resin includes a structural unit represented by a formula (C1) below, and at least one structural unit selected from the group consisting of structural units represented by formulae (A1), (B1), and (D1) below, and
the second resin is an epoxy resin.

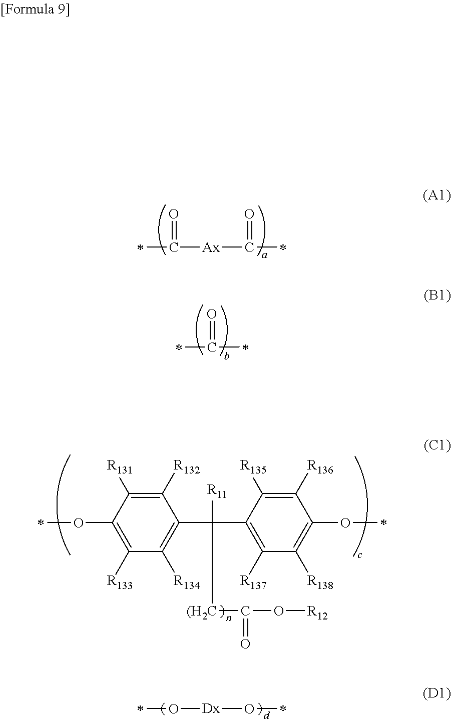

In the formula (A1):
Ax is a divalent group containing at least one group selected from the group consisting of a substituted or unsubstituted divalent aromatic hydrocarbon group, a substituted or unsubstituted divalent cyclic aliphatic hydrocarbon group, and a substituted or unsubstituted divalent acyclic aliphatic hydrocarbon group; and
a is a mole fraction of the structural unit represented by the formula (A1),
in the formula (B1):
b is a mole fraction of the structural unit represented by the formula (B1); and
the structural unit represented by the formula (B1) is different from carbonyl groups in the formulae (A1), (C1), and (D1),
in the formula (C1):
R₁₁ is a hydrogen atom, a substituted or unsubstituted alkyl group having 1 to 20 carbon atoms, a substituted or unsubstituted cycloalkyl group having 3 to 20 ring carbon atoms, a substituted or unsubstituted cycloalkoxy group having 3 to 20 ring carbon atoms, a substituted or unsubstituted alkenyl group having 2 to 10 carbon atoms, or a substituted or unsubstituted aryl group having 6 to 14 carbon atoms;
R₁₂ is a group containing at least one selected from the group consisting of a substituted or unsubstituted monovalent aromatic hydrocarbon group, a substituted or unsubstituted monovalent cyclic aliphatic hydrocarbon group, a substituted or unsubstituted monovalent acyclic aliphatic hydrocarbon group, a substituted or unsubstituted divalent aromatic hydrocarbon group, a substituted or unsubstituted divalent cyclic aliphatic hydrocarbon group, and a substituted or unsubstituted divalent acyclic aliphatic hydrocarbon group;
R₁₃₁ to R₁₃₈ are each independently a hydrogen atom, a substituted or unsubstituted alkyl group having 1 to 10 carbon atoms, a substituted or unsubstituted alkenyl group having 2 to 10 carbon atoms, a substituted or unsubstituted alkynyl group having 2 to 10 carbon atoms, a substituted or unsubstituted cycloalkyl group having 3 to 20 ring carbon atoms, or a substituted or unsubstituted aryl group having 6 to 14 carbon atoms;
c is a mole fraction of the structural unit represented by the formula (C1); and
n represents 0, 1, 2, 3, or 4; and
in the formula (D1):
Dx is a divalent group containing at least one group selected from the group consisting of a substituted or unsubstituted divalent aromatic hydrocarbon group, a substituted or unsubstituted divalent cyclic aliphatic hydrocarbon group, and a substituted or unsubstituted divalent acyclic aliphatic hydrocarbon group;
d is a mole fraction of the structural unit represented by the formula (D1),
substituents for a “substituted or unsubstituted” group are bonded to each other to form a monocyclic ring, bonded to each other to form a fused ring, or not bonded to each other,
each * in the formulae (A1), (B1), (C1), and (D1) represents a bond,
when the first resin includes a plurality of structural units represented by the formula (A1), the plurality of structural units represented by the formula (A1) are identical to each other or different from each other,
when the first resin includes a plurality of structural units represented by the formula (C1), the plurality of structural units represented by the formula (C1) are identical to each other or different from each other, and
when the first resin includes a plurality of structural units represented by the formula (D1), the plurality of structural units represented by the formula (D1) are identical to each other or different from each other.

### [Configuration 30]

In the resin composition according to [Configuration 29], the structural unit represented by the formula (D1) is represented by a formula (D2) below.

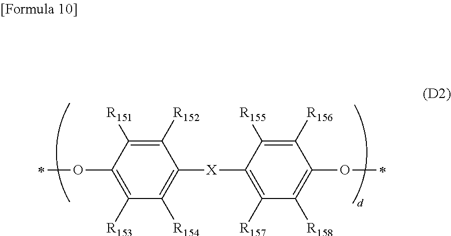

In the formula (D2):
R₁₅₁ to R₁₅₈ are each independently a hydrogen atom, a halogen atom, a substituted or unsubstituted alkyl group having 1 to 18 carbon atoms, a substituted or unsubstituted alkoxy group having 1 to 18 carbon atoms, a substituted or unsubstituted cycloalkyl group having 6 to 20 ring carbon atoms, a substituted or unsubstituted cycloalkoxy group having 6 to 20 ring carbon atoms, a substituted or unsubstituted alkenyl group having 2 to 10 carbon atoms, a substituted or unsubstituted aryl group having 6 to 14 ring carbon atoms, a substituted or unsubstituted aryloxy group having 6 to 14 ring carbon atoms, a substituted or unsubstituted aralkyl group having 7 to 20 carbon atoms, a substituted or unsubstituted aralkyloxy group having 7 to 20 carbon atoms, a nitro group, an aldehyde group, a cyano group, and a carboxy group;
X is (i) a single bond, (ii) a group selected from the group consisting of a substituted or unsubstituted alkylene group having 1 to 28 carbon atoms, a substituted or unsubstituted alkylidene group having 2 to 28 carbon atoms, a substituted or unsubstituted cycloalkylene group having 5 to 15 ring carbon atoms, a substituted or unsubstituted cycloalkylidene group having 3 to 26 ring carbon atoms, a substituted or unsubstituted arylene group having 6 to 20 ring carbon atoms, —S—, —SO—, —SO₂—, —O—, and —CO—, or (iii) a divalent group formed by linking two or more groups selected from the group described in (ii);
d represents the same as d in the formula (D1); and
each * represents a bond.

### [Configuration 31]

In the resin composition according to [Configuration 30], X is a substituted or unsubstituted cycloalkylidene group having 5 to 15 ring carbon atoms.

### [Configuration 32]

In the resin composition according to [Configuration 30] or [Configuration 31], R₁₅₁ to R₁₅₈ are each independently a hydrogen atom, a substituted or unsubstituted alkyl group having 1 to 18 carbon atoms, or a substituted or unsubstituted cycloalkyl group having 6 to 20 ring carbon atoms.

### [Configuration 33]

In the resin composition according to any one of [Configuration 29] to [Configuration 32], the first resin is a resin including the structural units represented by the formulae (C1) and (B1).

### [Configuration 34]

In the resin composition according to [Configuration 33], a ratio c:d of a mole fraction c of the structural unit represented by the formula (C1) to a mole fraction d of the structural unit represented by the formula (D1) is from 0.5:99.5 to 100:0.

### [Configuration 35]

In the resin composition according to [Configuration 34], the ratio c:d of the mole fraction c of the structural unit represented by the formula (C1) to the mole fraction d of the structural unit represented by the formula (D1) is from 20:80 to 100:0.

### [Configuration 36]

In the resin composition according to any one of [Configuration 29] to [Configuration 32], the first resin includes the structural units represented by the formulae (C1) and (A1).

### [Configuration 37]

In the resin composition according to [Configuration 36], a ratio c:a of the mole fraction c of the structural unit represented by the formula (C1) to the mole fraction a of the structural unit represented by the formula (A1) is from 0.5:99.5 to 66.7:33.3.

### [Configuration 38]

In the resin composition according to [Configuration 36], a ratio c:d of a mole fraction c of the structural unit represented by the formula (C1) to a mole fraction d of the structural unit represented by the formula (D1) is from 0.5:99.5 to 100:0.

### [Configuration 39]

In the resin composition according to [Configuration 37] or [Configuration 38], the first resin further includes the structural units represented by the formulae (B1) and (D1).

### [Configuration 40]

In the resin composition according to [Configuration 39], a ratio (c+d):a of a sum c+d of the mole fraction c of the structural unit represented by formula (C1) and the mole fraction d of the structural unit represented by formula (D1) to the mole fraction a of the structural unit represented by formula (A1) is from 33.3:66.7 to 66.7:33.3.

### [Configuration 41]

In the resin composition according to any one of [Configuration 29] to [Configuration 40], the structural unit represented by the formula (A1) is represented by a formula (A2), (A3), (A4), or (A5) below.

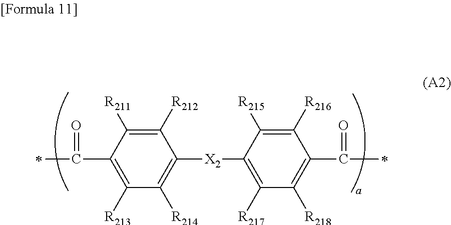

In the formula (A2):
R₂₁₁ to R₂₁₈ are each independently a hydrogen atom, a halogen atom, a substituted or unsubstituted alkyl group having 1 to 18 carbon atoms, a substituted or unsubstituted alkoxy group having 1 to 18 carbon atoms, a substituted or unsubstituted cycloalkyl group having 6 to 20 ring carbon atoms, a substituted or unsubstituted cycloalkoxy group having 6 to 20 ring carbon atoms, a substituted or unsubstituted alkenyl group having 2 to 10 carbon atoms, a substituted or unsubstituted aryl group having 6 to 14 ring carbon atoms, a substituted or unsubstituted aryloxy group having 6 to 14 ring carbon atoms, a substituted or unsubstituted aralkyl group having 7 to 20 carbon atoms, a substituted or unsubstituted aralkyloxy group having 7 to 20 carbon atoms, a nitro group, an aldehyde group, a cyano group, and a carboxy group;
X₂ is (i) a single bond, (ii) a group selected from the group consisting of a substituted or unsubstituted alkylene group having 1 to 28 carbon atoms, a substituted or unsubstituted alkylidene group having 2 to 28 carbon atoms, a substituted or unsubstituted cycloalkylene group having 5 to 15 ring carbon atoms, a substituted or unsubstituted cycloalkylidene group having 3 to 26 ring carbon atoms, a substituted or unsubstituted arylene group having 6 to 20 ring carbon atoms, —S—, —SO—, —SO₂—, —O—, and —CO—, or (iii) a divalent group formed by linking two or more groups selected from the group described in (ii);
a represents the same as a in the formula (A1); and
each * represents a bond.

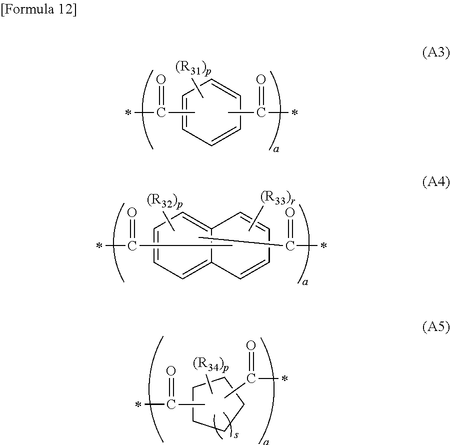

In the formulae (A3), (A4), and (A5):
R₃₁ to R₃₄ are each independently a hydrogen atom, a halogen atom, a substituted or unsubstituted alkyl group having 1 to 18 carbon atoms, a substituted or unsubstituted alkoxy group having 1 to 18 carbon atoms, a substituted or unsubstituted cycloalkyl group having 6 to 20 ring carbon atoms, a substituted or unsubstituted cycloalkoxy group having 6 to 20 ring carbon atoms, a substituted or unsubstituted alkenyl group having 2 to 10 carbon atoms, a substituted or unsubstituted aryl group having 6 to 14 ring carbon atoms, a substituted or unsubstituted aryloxy group having 6 to 14 ring carbon atoms, a substituted or unsubstituted aralkyl group having 7 to 20 carbon atoms, a substituted or unsubstituted aralkyloxy group having 7 to 20 carbon atoms, a nitro group, an aldehyde group, a cyano group, and a carboxy group;
p is 4;
q is 2, 3, or 4; r is 2, 3, or 4; and q+r is 6;
s is 1, 2, 3, 4, 5, 6, 7, or 8; and t is 2s+6;
a plurality of R₃₁ are identical to each other or different from each other;
a plurality of R₃₂ are identical to each other or different from each other;
a plurality of R₃₃ are identical to each other or different from each other;
a plurality of R₃₄ are identical to each other or different from each other;
a represents the same as a in the formula (A1); and
each * represents a bond.

### [Configuration 42]

In the resin composition according to any one of [Configuration 29] to [Configuration 41], R₁₂ includes a substituted or unsubstituted monovalent cyclic aliphatic hydrocarbon group.

### [Configuration 43]

In the resin composition according to any one of [Configuration 29] to [Configuration 42], R₁₂ includes a substituted or unsubstituted cycloalkyl group having 3 to 20 ring carbon atoms.

### [Configuration 44]

In the resin composition according to any one of [Configuration 29] to [Configuration 43], the structural unit represented by the formula (C1) is represented by a formula (C2) below.

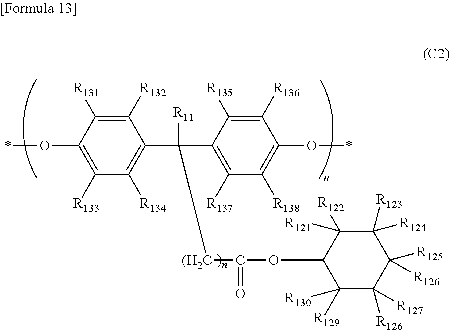

In the formula (C2):
R₁₁, R₁₃₁ to R₁₃₈, c, and n respectively represent the same as R₁₁, R₁₃₁ to R₁₃₈, c, and n in the formula (C1);
R₁₂₁ to R₁₃₀ are each independently a hydrogen atom, a substituted or unsubstituted alkyl group having 1 to 20 carbon atoms, a substituted or unsubstituted cycloalkyl group having 3 to 20 ring carbon atoms, a substituted or unsubstituted cycloalkoxy group having 3 to 20 ring carbon atoms, a substituted or unsubstituted alkenyl group having 2 to 10 carbon atoms, or a substituted or unsubstituted aryl group having 6 to 14 carbon atoms; and
each * represents a bond.

### [Configuration 45]

In the resin composition according to any one of [Configuration 29] to [Configuration 44], R₁₃₁, R₁₃₃, R₁₃₆, and R₁₃₈ are each independently a hydrogen atom, a substituted or unsubstituted alkyl group having 1 to 5 carbon atoms, a substituted or unsubstituted cycloalkyl group having 3 to 20 ring carbon atoms, or a substituted or unsubstituted aryl group having 6 to 14 ring carbon atoms.

### [Configuration 46]

In the resin composition according to any one of [Configuration 29] to [Configuration 45], the second resin includes at least one compound selected from the group consisting of compounds represented by formulae (E1), (E2), (E3), and (E4).

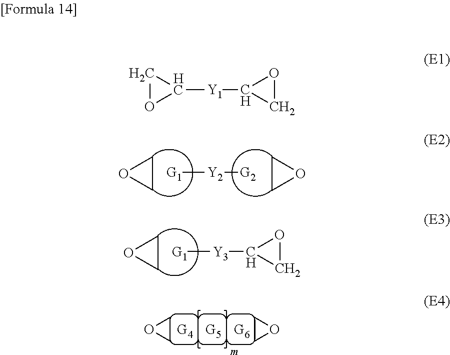

In the formula (E1), Y₁ represents a linking group linking epoxy groups to each other,
in formula (E2), G₁ and G₂ each independently represent a ring structure fused with an oxirane ring, and Y₂ represents a linking group that links the ring structure G₁ and the ring structure G₂,
in formula (E3), G₃ represents a ring structure fused with an oxirane ring, and Y₃ represents a linking group that links the ring structure G₃ and an epoxy group, and
in formula (E4), G₄ and G₆ each independently represent a ring structure fused with an oxirane ring, G₅ represents a ring structure fused with G₄ and G₆, and m is an integer of 0 or 1 or more, representing the number of ring structures G₅, in which when m is 0, the ring structure G₄ and the ring structure G₆ are directly fused with each other.

### [Configuration 47]

A cured product formed by curing the resin composition according to any one of [Configuration 29] to [Configuration 46].

### [Configuration 48]

The cured product according to [Configuration 47], having a crosslinking structure represented by a formula (C10) below.

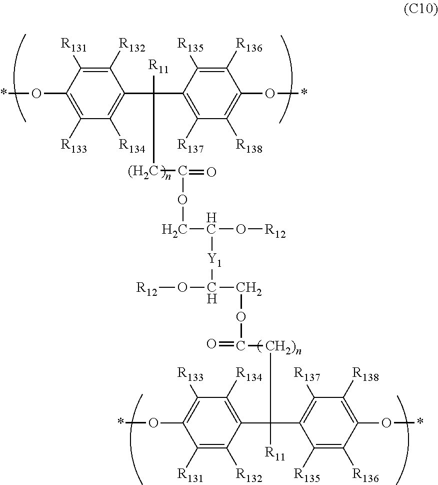

In the formula (C10):
R₁₁, R₁₂, R₁₃₁ to R₁₃₈, and n respectively represent the same as R₁₁, R₁₂, R₁₃₁ to R₁₃₈, and n in the formula (C1);
a plurality of Rₙ are identical to each other or different from each other;
a plurality of R₁₂ are identical to each other or different from each other;
a plurality of R₁₃₁ to R₁₃₈ are identical to each other or different from each other;
a plurality of n are identical to each other or different from each other;
Y₁ is a linking group; and
each * represents a bond.

According to an aspect of the invention, it is possible to provide a resin, a copolymer, and an electronic substrate material, each of which has dielectric properties enabling their use as an electronic substrate material and exhibits excellent solubility in non-halogen solvents; to provide a resin composition, a coating liquid composition, a film, a sheet, and an electronic substrate each containing the resin; and to provide a cured product obtained by curing the resin composition.

### BRIEF DESCRIPTION OF DRAWINGS

FIG. 1 is a ¹H-NMR spectrum of a polycarbonate polymer (PC-1) obtained in Synthetic Example 1.

FIG. 2 is a ¹H-NMR spectrum of a polycarbonate polymer (PC-2) obtained in Synthetic Example 2.

FIG. 3 is a ¹H-NMR spectrum of a polycarbonate polymer (PC-3) obtained in Synthetic Example 3.

FIG. 4 is a ¹H-NMR spectrum of a polycarbonate polymer (PC-4) obtained in Synthetic Example 4.

FIG. 5 is a ¹H-NMR spectrum of a polycarbonate polymer (PC-5) obtained in Synthetic Example 5.

FIG. 6 is a ¹H-NMR spectrum of a polycarbonate polymer (PC-6) obtained in Synthetic Example 6.

FIG. 7 is a ¹H-NMR spectrum of a polycarbonate polymer (PC-7) obtained in Synthetic Example 7.

FIG. 8 is a ¹H-NMR spectrum of a polycarbonate polymer (PE-1) obtained in Synthetic Example 8.

### DESCRIPTION OF EMBODIMENT(S)

### First Exemplary Embodiment

### Resin

A resin according to a first exemplary embodiment is at least one resin selected from the group consisting of polycarbonate, polyester, and polyester polycarbonate. The resin according to the first exemplary embodiment is sometimes referred to as a first resin.

The resin according to the exemplary embodiment includes a structural unit represented by a formula (C1) below, and at least one structural unit selected from the group consisting of structural units represented by formulae (A1), (B1), and (D1) below.

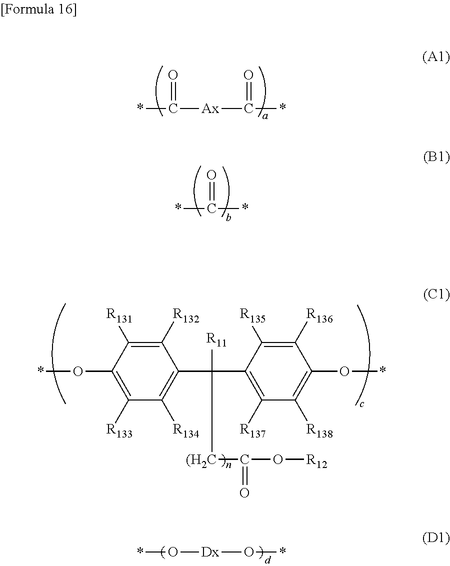

In the formula (A1):
Ax is a divalent group containing at least one group selected from the group consisting of a substituted or unsubstituted divalent aromatic hydrocarbon group, a substituted or unsubstituted divalent cyclic aliphatic hydrocarbon group, and a substituted or unsubstituted divalent acyclic aliphatic hydrocarbon group; and
a is a mole fraction of the structural unit represented by the formula (A1),
in the formula (B1):
b is a mole fraction of the structural unit represented by the formula (B1); and
the structural unit represented by the formula (B1) is different from carbonyl groups in the formulae (A1), (C1), and (D1),
in the formula (C1):
R₁₁ is a hydrogen atom, a substituted or unsubstituted alkyl group having 1 to 20 carbon atoms, a substituted or unsubstituted cycloalkyl group having 3 to 20 ring carbon atoms, a substituted or unsubstituted cycloalkoxy group having 3 to 20 ring carbon atoms, a substituted or unsubstituted alkenyl group having 2 to 10 carbon atoms, or a substituted or unsubstituted aryl group having 6 to 14 carbon atoms;
R₁₂ is a group containing at least one selected from the group consisting of a substituted or unsubstituted monovalent aromatic hydrocarbon group, a substituted or unsubstituted monovalent cyclic aliphatic hydrocarbon group, a substituted or unsubstituted monovalent acyclic aliphatic hydrocarbon group, a substituted or unsubstituted divalent aromatic hydrocarbon group, a substituted or unsubstituted divalent cyclic aliphatic hydrocarbon group, and a substituted or unsubstituted divalent acyclic aliphatic hydrocarbon group;
R₁₃₁ to R₁₃₈ are each independently a hydrogen atom, a substituted or unsubstituted alkyl group having 1 to 10 carbon atoms, a substituted or unsubstituted alkenyl group having 2 to 10 carbon atoms, a substituted or unsubstituted alkynyl group having 2 to 10 carbon atoms, a substituted or unsubstituted cycloalkyl group having 3 to 20 ring carbon atoms, or a substituted or unsubstituted aryl group having 6 to 14 carbon atoms;
c is a mole fraction of the structural unit represented by the formula (C1); and
n represents 0, 1, 2, 3, or 4; and
in the formula (D1):
Dx is a divalent group containing at least one group selected from the group consisting of a substituted or unsubstituted divalent aromatic hydrocarbon group, a substituted or unsubstituted divalent cyclic aliphatic hydrocarbon group, and a substituted or unsubstituted divalent acyclic aliphatic hydrocarbon group;
d is a mole fraction of the structural unit represented by the formula (D1),
substituents for a “substituted or unsubstituted” group are bonded to each other to form a monocyclic ring, bonded to each other to form a fused ring, or not bonded to each other,
each * in the formulae (A1), (B1), (C1), and (D1) represents a bond,
when the first resin includes a plurality of structural units represented by the formula (A1), the plurality of structural units represented by the formula (A1) are identical to each other or different from each other,
when the first resin includes a plurality of structural units represented by the formula (C1), the plurality of structural units represented by the formula (C1) are identical to each other or different from each other, and
when the first resin includes a plurality of structural units represented by the formula (D1), the plurality of structural units represented by the formula (D1) are identical to each other or different from each other.

The resin according to the exemplary embodiment includes the structural unit represented by the formula (C1), and has a specific ester bond in a side chain of the resin, thereby exhibiting dielectric properties that enable its use as an electronic substrate material and also exhibiting excellent solubility in a non-halogen solvent.

In the resin according to the exemplary embodiment, it is preferable that R₁₂ in the formula (C1) does not include an —NH₂ group (amino group), an —OH group (hydroxy group), or a —COOH group (carboxy group).

In the resin according to the exemplary embodiment, it is preferable that neither the main chain nor the side chain (excluding a terminal) includes an —NH₂ group (amino group), an —OH group (hydroxy group), or a —COOH group (carboxy group).

In the resin according to the exemplary embodiment, it is more preferable that neither the main chain, the side chain, nor a terminal includes an —NH₂ group (amino group), an —OH group (hydroxy group), or a —COOH group (carboxy group).

In the resin according to the exemplary embodiment, it is still more preferable that the resin does not include an —NH₂ group (amino group), an —OH group (hydroxy group), or a —COOH group (carboxy group) in a molecule.

In the resin according to the exemplary embodiment, the structural units represented by the formula (A1) are not continuously bonded to each other, the structural units represented by the formula (B1) are not continuously bonded to each other, the structural units represented by the formula (C1) are not continuously bonded to each other, and the structural units represented by the formula (D1) are not continuously bonded to each other.

The resin according to the exemplary embodiment is at least one resin selected from the group consisting of polyester and polyester polycarbonate, and preferably includes the structural unit represented by the formula (C1) and at least one structural unit selected from the group consisting of the structural units represented by the formulae (A1) and (B1).

One embodiment of the resin according to the exemplary embodiment is a resin including the structural units represented by the formulae (C1) and (B1).

In one embodiment of the resin according to the exemplary embodiment, d in the formula (D1) is 0. One embodiment of the resin according to the exemplary embodiment is a resin including the structural unit represented by the formula (C1), at least one selected from the group consisting of the structural units represented by the formulae (A1) and (B1), and excluding the structural unit represented by the formula (D1).

One embodiment of the resin according to the exemplary embodiment is a resin including the structural units represented by the formulae (C1) and (B1) and excluding the structural unit represented by the formula (D1).

One embodiment of the resin according to the exemplary embodiment is a resin (polycarbonate resin or polyester polycarbonate resin) including a repeating unit represented by a formula (PC-CB1) below.

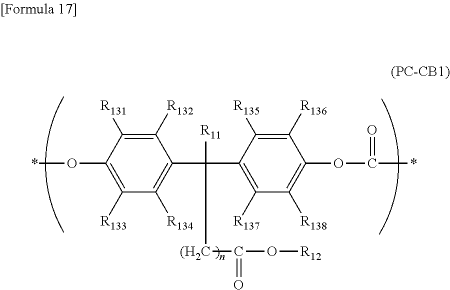

In the formula (PC-CB1): R₁₁, R₁₂, R₁₃₁ to R₁₃₈, and n respectively represent the same as R₁₁, R₁₂, R₁₃₁ to R₁₃₈, and n in the formula (C1); and each * represents a bond.

One embodiment of the resin according to the exemplary embodiment is a resin (polycarbonate resin) consisting of the repeating unit represented by formula (PC-CB1) as a repeating unit.

One embodiment of the resin according to the exemplary embodiment is a resin including the structural units represented by the formulae (C1) and (A1).

One embodiment of the resin according to the exemplary embodiment is a resin including the structural units represented by the formulae (C1) and (A1) and excluding the structural unit represented by the formula (D1).

One embodiment of the resin according to the exemplary embodiment is a resin (polyester resin or polyester polycarbonate resin) including a repeating unit represented by a formula (PE-CA1) below.

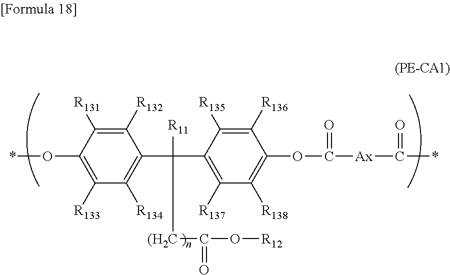

In the formula (PE-CA1): R₁₁, R₁₂, R₁₃₁ to R₁₃₈, and n respectively represent the same as R₁₁, R₁₂, R₁₃₁ to R₁₃₈, and n in the formula (C1); Ax represent the same as Ax in the formula (A1), and * represents a bond.

One embodiment of the resin according to the exemplary embodiment is a resin (polyester resin) consisting of the repeating unit represented by the formula (PE-CA1) as a repeating unit.

In one embodiment of the resin according to the exemplary embodiment, d in the formula (D1) is not 0. One embodiment of the resin according to the exemplary embodiment is a resin including the structural unit represented by the formula (D1).

### Copolymer

The resin according to the exemplary embodiment may be a copolymer.

A copolymer according to the exemplary embodiment is at least one copolymer selected from the group consisting of a polycarbonate copolymer, a polyester copolymer, and a polyester polycarbonate copolymer.

One embodiment of the copolymer according to the exemplary embodiment includes the structural unit represented by the formula (C1) and at least one structural unit selected from the group consisting of the structural units represented by the formulae (A1), (B1), and (D1).

One embodiment of the copolymer according to the exemplary embodiment includes the structural units represented by the formulae (C1) and (D1), and at least one structural unit selected from the group consisting of the structural units represented by formulae (A1) and (B1).

When the copolymer includes a plurality of structural units represented by the formula (A1), the plurality of structural units represented by the formula (A1) are identical to each other or different from each other,

When the copolymer includes a plurality of structural units represented by the formula (C1), the plurality of structural units represented by the formula (C1) are identical to each other or different from each other,

When the copolymer includes a plurality of structural units represented by the formula (D1), the plurality of structural units represented by the formula (D1) are identical to each other or different from each other,

When the copolymer according to the exemplary embodiment includes a plurality of structural units represented by a certain formula, the fact that the structures of the structural units differ from each other even though they are represented by the same formula means that the structures of the structural units are different, for instance, due to differences in constituent atoms, bonding sites, ring structures, linking groups, or substituents.

One embodiment of the resin and the copolymer according to the exemplary embodiment further includes the structural units represented by the formulae (B1) and (D1). That is, one embodiment of the resin and the copolymer according to the exemplary embodiment is a resin and a copolymer which include the structural units represented by the formulae (C1), (B1), and (D1).

One embodiment of the resin and the copolymer according to the exemplary embodiment is a resin (polycarbonate resin or polyester polycarbonate resin) and a copolymer which include the repeating unit represented by the formula (PC-DB1) and a repeating unit represented by a formula (PC-DB1) below.

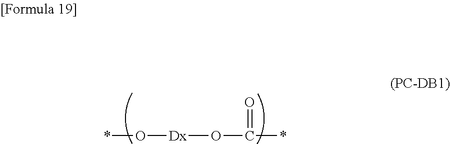

In the formula (PC-DB1), Dx represents the same as Dx in the formula (D1), and each * represents a bond.

One embodiment of the resin and the copolymer according to the exemplary embodiment is a resin (polycarbonate resin) which consists of the repeating unit represented by the formula (PC-CB1) and the repeating unit represented by the formula (PC-DB1) as a repeating unit.

In one embodiment of the resin and the copolymer according to the exemplary embodiment, a ratio c:d of the mole fraction c of the structural unit represented by the formula (C1) to the mole fraction d of the structural unit represented by the formula (D1) is from 0.5:99.5 to 100:0.

In one embodiment of the resin and the copolymer according to the exemplary embodiment, the ratio c:d of the mole fraction c of the structural unit represented by the formula (C1) to the mole fraction d of the structural unit represented by the formula (D1) is from 20:80 to 100:0.

In one embodiment of the resin and the copolymer according to the exemplary embodiment, the ratio c:d of the mole fraction c of the structural unit represented by the formula (C1) to the mole fraction d of the structural unit represented by the formula (D1) is from 0.5:99.5 to 50:50.

In one embodiment of the resin and the copolymer according to the exemplary embodiment, the ratio c:d of the mole fraction c of the structural unit represented by the formula (C1) to the mole fraction d of the structural unit represented by the formula (D1) is from 20:80 to 50:50.

In one embodiment of the resin and the copolymer according to the exemplary embodiment, the ratio c:d of the mole fraction c of the structural unit represented by the formula (C1) to the mole fraction d of the structural unit represented by the formula (D1) is from 0.5:99.5 to 99.5:0.5.

In one embodiment of the resin and the copolymer according to the exemplary embodiment, a ratio c:a of the mole fraction c of the structural unit represented by formula (C1) to the mole fraction a of the structural unit represented by the formula (A1) is in a range from 0.5:99.5 to 66.7:33.3.

In one embodiment of the resin and the copolymer according to the exemplary embodiment, when the structural units represented by the formulae (C1) and (A1) are included, a ratio c:d of the mole fraction c of the structural unit represented by the formula (C1) to the mole fraction d of the structural unit represented by the formula (D1) is in a range from 0.5:99.5 to 100:0.

In one embodiment of the resin and the copolymer according to the exemplary embodiment, when the structural units represented by the formulae (C1) and (A1) are included, the ratio c:d of the mole fraction c of the structural unit represented by the formula (C1) to the mole fraction d of the structural unit represented by the formula (D1) is in a range from 20:80 to 100:0.

In one embodiment of the resin and the copolymer according to the exemplary embodiment, when the structural units represented by the formulae (C1) and (B1) are included and, optionally, the structural unit represented by the formula (D1) is included, the ratio c:d of the mole fraction c of the structural unit represented by the formula (C1) to the mole fraction d of the structural unit represented by the formula (D1) may be in a range from 0.5:99.5 to 100:0 or may be in a range from 20:80 to 100:0.

One embodiment of the resin and the copolymer according to the exemplary embodiment is a resin and a copolymer which include the structural units represented by the formulae (C1), (A1), and (D1).

One embodiment of the resin and the copolymer according to the exemplary embodiment is a resin (polyester resin or polyester polycarbonate resin) and a copolymer which include a repeating unit represented by a formula (PE-DA1) below.

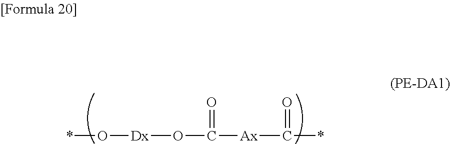

In the formula (PE-DA1), Dx represents the same as Dx in the formula (D1), Ax represents the same as Ax in the formula (A1), and each * represents a bond.

One embodiment of the resin and the copolymer according to the exemplary embodiment is a resin and a copolymer which include the repeating unit represented by the formula (PE-CA1) and the repeating unit represented by the formula (PE-DA1) as a repeating unit.

One embodiment of the resin and the copolymer according to the exemplary embodiment is a resin (polyester resin) and a copolymer which consist of the repeating unit represented by the formula (PE-CA1) and the repeating unit represented by the formula (PE-DA1) as a repeating unit.

One embodiment of the resin and the copolymer according to the exemplary embodiment is a resin and a copolymer which include the structural units represented by the formulae (C1), (A1), (B1), and (D1).

Examples of the resin and the copolymer which include the structural units represented by the formulae (C1), (A1), (B1), and (D1) include Embodiments (I) to (VII) below.

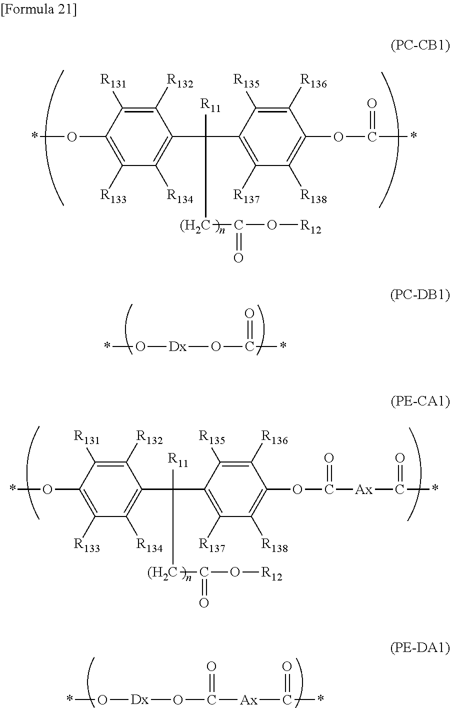

Embodiment (I): A resin and a copolymer which include the repeating units represented by the formulae (PC-CB1) and (PE-DA1), or a resin and a copolymer which consist of these repeating units.

In the resin and the copolymer according to Embodiment (I), the mole fraction of the repeating unit represented by the formula (PC-CB1) is preferably in a range from 1 mol % to 99 mol %, more preferably in a range from 10 mol % to 80 mol %.

In the resin and the copolymer according to Embodiment (I), the mole fraction of the repeating unit represented by the formula (PE-DA1) is preferably in a range from 1 mol % to 99 mol %, more preferably in a range from 20 mol % to 90 mol %.

Embodiment (II): A resin and a copolymer which include the repeating units represented by the formulae (PC-CB1), (PC-DB1), and (PE-DA1), or a resin and a copolymer which consist of these repeating units.

In the resin and the copolymer according to Embodiment (II), the mole fraction of the repeating unit represented by the formula (PC-CB1) is preferably in a range from 1 mol % to 98 mol %, more preferably in a range from 10 mol % to 80 mol %.

In the resin and the copolymer according to Embodiment (II), the mole fraction of the repeating unit represented by the formula (PC-DB1) is preferably in a range from 1 mol % to 98 mol %, more preferably in a range from 10 mol % to 80 mol %.

In the resin and the copolymer according to Embodiment (II), the mole fraction of the repeating unit represented by the formula (PE-DA1) is preferably in a range from 1 mol % to 98 mol %, more preferably in a range from 10 mol % to 80 mol %.

Embodiment (III): A resin and a copolymer which include the repeating units represented by the formulae (PC-CB1), (PC-DB1), and (PE-CA1), or a resin and a copolymer which consist of these repeating units.

In the resin and the copolymer according to Embodiment (III), the mole fraction of the repeating unit represented by the formula (PC-CB1) is preferably in a range from 1 mol % to 98 mol %, more preferably in a range from 10 mol % to 80 mol %.

In the resin and the copolymer according to Embodiment (III), the mole fraction of the repeating unit represented by the formula (PC-DB1) is preferably in a range from 1 mol % to 98 mol %, more preferably in a range from 10 mol % to 80 mol %.

In the resin and the copolymer according to Embodiment (III), the mole fraction of the repeating unit represented by the formula (PE-CA1) is preferably in a range from 1 mol % to 98 mol %, more preferably in a range from 10 mol % to 80 mol %.

Embodiment (IV): A resin and a copolymer which include the repeating units represented by the formulae (PE-CA1) and (PC-DB1), or a resin and a copolymer which consist of these repeating units.

In the resin and the copolymer according to Embodiment (IV), the mole fraction of the repeating unit represented by the formula (PC-DB1) is preferably in a range from 1 mol % to 99 mol %, more preferably in a range from 10 mol % to 80 mol %.

In the resin and the copolymer according to Embodiment (IV), the mole fraction of the repeating unit represented by the formula (PE-CA1) is preferably in a range from 1 mol % to 99 mol %, more preferably in a range from 20 mol % to 90 mol %.

Embodiment (V): A resin and a copolymer which include the repeating units represented by the formulae (PE-CA1), (PE-DA1), and (PC-DB1), or a resin and a copolymer which consist of these repeating units.

In the resin and the copolymer according to Embodiment (V), the mole fraction of the repeating unit represented by the formula (PE-CA1) is preferably in a range from 1 mol % to 98 mol %, more preferably in a range from 10 mol % to 80 mol %.

In the resin and the copolymer according to Embodiment (V), the mole fraction of the repeating unit represented by the formula (PE-DA1) is preferably in a range from 1 mol % to 98 mol %, more preferably in a range from 10 mol % to 80 mol %.

In the resin and the copolymer according to Embodiment (V), the mole fraction of the repeating unit represented by the formula (PC-DB1) is preferably in a range from 1 mol % to 98 mol %, more preferably in a range from 10 mol % to 80 mol %.

Embodiment (VI): A resin and a copolymer which include the repeating units represented by the formulae (PE-CA1), (PC-CB1), and (PE-DA1), or a resin and a copolymer which consist of these repeating units.

In the resin and the copolymer according to Embodiment (VI), the mole fraction of the repeating unit represented by the formula (PE-CA1) is preferably in a range from 1 mol % to 98 mol %, more preferably in a range from 10 mol % to 80 mol %.

In the resin and the copolymer according to Embodiment (VI), the mole fraction of the repeating unit represented by the formula (PC-CB1) is preferably in a range from 1 mol % to 98 mol %, more preferably in a range from 10 mol % to 80 mol %.

In the resin and the copolymer according to Embodiment (VI), the mole fraction of the repeating unit represented by the formula (PE-DA1) is preferably in a range from 1 mol % to 98 mol %, more preferably in a range from 10 mol % to 80 mol %.

Embodiment (VII): A resin and a copolymer which include the repeating units represented by the formulae (PE-CA1), (PE-DA1), (PC-CB1), and (PC-DB1), or a resin and a copolymer which consist of these repeating units.

In the resin and the copolymer according to Embodiment (VII), the mole fraction of the repeating unit represented by the formula (PE-CA1) is preferably in a range from 1 mol % to 97 mol %, more preferably in a range from 10 mol % to 70 mol %.

In the resin and the copolymer according to Embodiment (VII), the mole fraction of the repeating unit represented by the formula (PE-DA1) is preferably in a range from 1 mol % to 97 mol %, more preferably in a range from 10 mol % to 70 mol %.

In the resin and the copolymer according to Embodiment (VII), the mole fraction of the repeating unit represented by the formula (PC-CB1) is preferably in a range from 1 mol % to 97 mol %, more preferably in a range from 10 mol % to 70 mol %.

In the resin and the copolymer according to Embodiment (VII), the mole fraction of the repeating unit represented by the formula (PC-DB1) is preferably in a range from 1 mol % to 97 mol %, more preferably in a range from 10 mol % to 70 mol %.

In one embodiment of the resin and the copolymer which include the structural units represented by the formulae (C1), (A1), and (D1), the ratio (c+d):a of the sum c+d of the mole fraction c of the structural unit represented by formula (C1) and the mole fraction d of the structural unit represented by formula (D1) to the mole fraction a of the structural unit represented by formula (A1) is in a range from 33.3:66.7 to 66.7:33.3.

In one embodiment of the resin according to the exemplary embodiment, c+d=a+b is satisfied.

In the resin and the copolymer according to the exemplary embodiment, the mole fraction of each structural unit or repeating unit is calculated by nuclear magnetic resonance (NMR) measurement. Specifically, ¹H-NMR measurement is performed, and each mole fraction is calculated from a peak integration value derived from the corresponding structural unit or repeating unit.

In the resin and the copolymer according to the exemplary embodiment, the structural unit represented by the formula (D1) is preferably represented by a formula (D2) below.

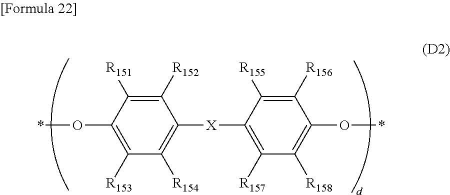

In the formula (D2):
R₁₅₁ to R₁₅₈ are each independently selected from the group consisting of a hydrogen atom, a halogen atom, a substituted or unsubstituted alkyl group having 1 to 18 carbon atoms, a substituted or unsubstituted alkoxy group having 1 to 18 carbon atoms, a substituted or unsubstituted cycloalkyl group having 6 to 20 ring carbon atoms, a substituted or unsubstituted cycloalkoxy group having 6 to 20 ring carbon atoms, a substituted or unsubstituted alkenyl group having 2 to 10 carbon atoms, a substituted or unsubstituted aryl group having 6 to 14 ring carbon atoms, a substituted or unsubstituted aryloxy group having 6 to 14 ring carbon atoms, a substituted or unsubstituted aralkyl group having 7 to 20 carbon atoms, a substituted or unsubstituted aralkyloxy group having 7 to 20 carbon atoms, a nitro group, an aldehyde group, a cyano group, and a carboxy group;
X is (i) a single bond, (ii) a group selected from the group consisting of a substituted or unsubstituted alkylene group having 1 to 28 carbon atoms, a substituted or unsubstituted alkylidene group having 2 to 28 carbon atoms, a substituted or unsubstituted cycloalkylene group having 5 to 15 ring carbon atoms, a substituted or unsubstituted cycloalkylidene group having 3 to 26 ring carbon atoms, a substituted or unsubstituted arylene group having 6 to 20 ring carbon atoms, —S—, —SO—, —SO₂—, —O—, and —CO—, or (iii) a divalent group formed by linking two or more groups selected from the group described in (ii);
d represents the same as d in the formula (D1); and
each * represents a bond.

In the resin and the copolymer according to the exemplary embodiment, X in the structural unit represented by formula (D2) is preferably a substituted or unsubstituted cycloalkylidene group having 5 to 15 ring carbon atoms.

In the resin and the copolymer according to the exemplary embodiment, R₁₅₁ to R₁₅₈ in the structural unit represented by formula (D2) are each independently preferably a hydrogen atom, a substituted or unsubstituted alkyl group having 1 to 18 carbon atoms, or a substituted or unsubstituted cycloalkyl group having 6 to 20 ring carbon atoms.

In the resin and the copolymer according to the exemplary embodiment, Dx in the structural unit represented by formula (D1) also preferably excludes a divalent group represented by formula (D3).

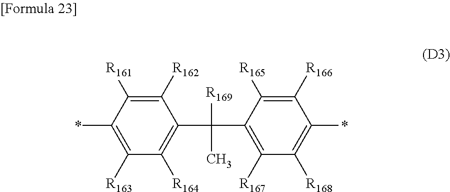

In the formula (D3):
R₁₆₉ is a methyl group or a phenyl group;
R₁₆₁ to R₁₆₈ are each independently selected from the group consisting of a hydrogen atom, a halogen atom, a substituted or unsubstituted alkyl group having 1 to 18 carbon atoms, a substituted or unsubstituted alkoxy group having 1 to 18 carbon atoms, a substituted or unsubstituted cycloalkyl group having 6 to 20 ring carbon atoms, a substituted or unsubstituted cycloalkoxy group having 6 to 20 ring carbon atoms, a substituted or unsubstituted alkenyl group having 2 to 10 carbon atoms, a substituted or unsubstituted aryl group having 6 to 14 ring carbon atoms, a substituted or unsubstituted aryloxy group having 6 to 14 ring carbon atoms, a substituted or unsubstituted aralkyl group having 7 to 20 carbon atoms, a substituted or unsubstituted aralkyloxy group having 7 to 20 carbon atoms, a nitro group, an aldehyde group, a cyano group, and a carboxy group; and
each * represents a bond.

In the resin and the copolymer according to the exemplary embodiment, R₁₂ in the formula (C1) is preferably at least one group selected from the group consisting of a substituted or unsubstituted monovalent aromatic hydrocarbon group, a substituted or unsubstituted monovalent cyclic aliphatic hydrocarbon group, a substituted or unsubstituted monovalent acyclic aliphatic hydrocarbon group, a substituted or unsubstituted divalent aromatic hydrocarbon group, a substituted or unsubstituted divalent cyclic aliphatic hydrocarbon group, and a substituted or unsubstituted divalent acyclic aliphatic hydrocarbon group.

In the resin and the copolymer according to the exemplary embodiment, the acyclic aliphatic hydrocarbon group includes a linear-chain aliphatic hydrocarbon group and a branched-chain aliphatic hydrocarbon group.

In the resin and the copolymer according to the exemplary embodiment, the substituted or unsubstituted monovalent acyclic aliphatic hydrocarbon group as R₁₂ in the structural unit represented by the formula (C1) is also preferably a substituted or unsubstituted monovalent branched-chain aliphatic hydrocarbon group.

In the resin and the copolymer according to the exemplary embodiment, the substituted or unsubstituted divalent acyclic aliphatic hydrocarbon group as R₁₂ in the structural unit represented by the formula (C1) is also preferably a substituted or unsubstituted divalent branched-chain aliphatic hydrocarbon group.

In the resin and the copolymer according to the exemplary embodiment, R₁₂ in the structural unit represented by formula (C1) preferably includes a substituted or unsubstituted monovalent cyclic aliphatic hydrocarbon group.

In the resin and the copolymer according to the exemplary embodiment, R₁₂ in the structural unit represented by formula (C1) preferably includes a substituted or unsubstituted cycloalkyl group having 3 to 20 ring carbon atoms.

In the resin and the copolymer according to the exemplary embodiment, the structural unit represented by the formula (C1) is preferably represented by a formula (C2) below.

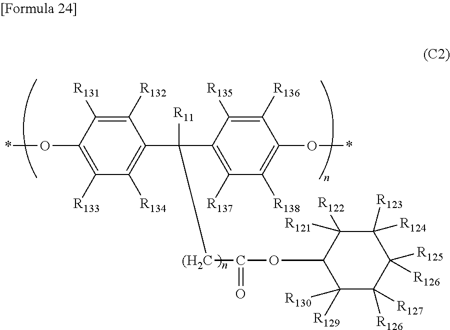

In the formula (C2):
R₁₁, R₁₃₁ to R₁₃₈, c, and n respectively represent the same as R₁₁, R₁₃₁ to R₁₃₈, c, and n in the formula (C1);
R₁₂₁ to R₁₃₀ are each independently a hydrogen atom, a substituted or unsubstituted alkyl group having 1 to 20 carbon atoms, a substituted or unsubstituted cycloalkyl group having 3 to 20 ring carbon atoms, a substituted or unsubstituted cycloalkoxy group having 3 to 20 ring carbon atoms, a substituted or unsubstituted alkenyl group having 2 to 10 carbon atoms, or a substituted or unsubstituted aryl group having 6 to 14 carbon atoms; and
each * represents a bond.

In the resin and the copolymer according to the exemplary embodiment, R₁₃₁ to R₁₃₈ in the structural unit represented by the formula (C1) are each independently preferably a hydrogen atom, a substituted or unsubstituted alkyl group having 1 to 5 carbon atoms, a substituted or unsubstituted cycloalkyl group having 3 to 20 ring carbon atoms, or a substituted or unsubstituted aryl group having 6 to 14 ring carbon atoms.

In the resin and the copolymer according to the exemplary embodiment, R₁₃₁, R₁₃₃, R₁₃₆, and R₁₃₈ in the structural unit represented by the formula (C1) are each independently more preferably a hydrogen atom, a substituted or unsubstituted alkyl group having 1 to 5 carbon atoms, a substituted or unsubstituted cycloalkyl group having 3 to 20 ring carbon atoms, or a substituted or unsubstituted aryl group having 6 to 14 ring carbon atoms.

In the resin and the copolymer according to the exemplary embodiment, R₁₃₂, R₁₃₄, R₁₃₅, and R₁₃₇ in the structural unit represented by formula (C1) are preferably a hydrogen atom.

In the resin and the copolymer according to the exemplary embodiment, it is preferable that at least one of R₁₃₁ or R₁₃₃ is a substituent other than a hydrogen atom and at least one of R₁₃₆ or R₁₃₈ is a substituent other than a hydrogen atom in the structural unit represented by formula (C1).

In the resin and the copolymer according to the exemplary embodiment, from the viewpoint of reducing dissipation factor, it is preferable that at least one selected from the group consisting of R₁₃₁ to R₁₃₈ in the structural unit represented by formula (C1) is a substituent other than a hydrogen atom. As a result, it is considered that the steric hindrance of the substituent can reduce the molecular mobility of a carbonate group or an ester group derived from the structural unit represented by formula (C1), and consequently, the dissipation factor of the resin and the copolymer according to the exemplary embodiment can be reduced.

In the resin and the copolymer according to the exemplary embodiment, from the viewpoint of facilitating the curing reaction with an epoxy resin, it is preferable that R₁₃₁ to R₁₃₈ in the structural unit represented by formula (C1) are each a hydrogen atom. As a result, it is considered that the steric hindrance around an ester group derived from the structural unit represented by formula (C1) can be reduced, and consequently, the curing reaction with an epoxy resin becomes favorable.

In the resin and the copolymer according to the exemplary embodiment, the structural unit represented by the formula (C1) is also preferably represented by a formula (C21) or (C22) below.

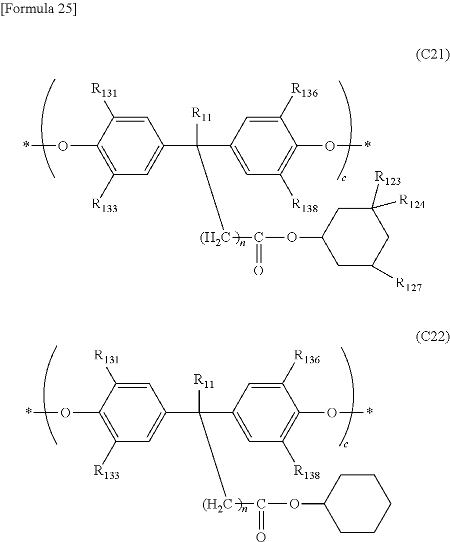

In the formulae (C21) and (C22):
R₁₁, c, and n respectively represent the same as R₁₁, c, and n in the formula (C1);
R₁₃₁, R₁₃₃, R₁₃₆, and R₁₃₈ are each independently a hydrogen atom, a substituted or unsubstituted alkyl group having 1 to 5 carbon atoms, a substituted or unsubstituted cycloalkyl group having 3 to 20 ring carbon atoms, or a substituted or unsubstituted aryl group having 6 to 14 carbon atoms;
at least one of R₁₃₁ or R₁₃₃ is a substituent other than a hydrogen atom; and
at least one of R₁₃₆ or R₁₃₈ is a substituent other than a hydrogen atom, and
in the formula (C21):
R₁₂₃, R₁₂₄, and R₁₂₇ are each independently a substituted or unsubstituted alkyl group having 1 to 20 carbon atoms, a substituted or unsubstituted cycloalkyl group having 3 to 20 ring carbon atoms, a substituted or unsubstituted cycloalkoxy group having 3 to 20 ring carbon atoms, a substituted or unsubstituted alkenyl group having 2 to 10 carbon atoms, or a substituted or unsubstituted aryl group having 6 to 14 carbon atoms; and
each * represents a bond.

In the resin and the copolymer according to the exemplary embodiment, the structural unit represented by the formula (A1) is preferably represented by a formula (A2), (A3), (A4) or (A5) below.

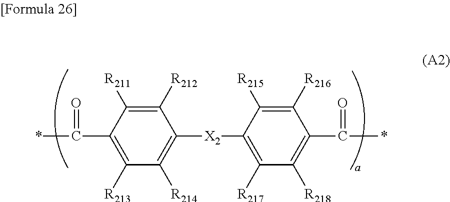

In the formula (A2):
R₂₁₁ to R₂₁₈ are each independently selected from the group consisting of a hydrogen atom, a halogen atom, a substituted or unsubstituted alkyl group having 1 to 18 carbon atoms, a substituted or unsubstituted alkoxy group having 1 to 18 carbon atoms, a substituted or unsubstituted cycloalkyl group having 6 to 20 ring carbon atoms, a substituted or unsubstituted cycloalkoxy group having 6 to 20 ring carbon atoms, a substituted or unsubstituted alkenyl group having 2 to 10 carbon atoms, a substituted or unsubstituted aryl group having 6 to 14 ring carbon atoms, a substituted or unsubstituted aryloxy group having 6 to 14 ring carbon atoms, a substituted or unsubstituted aralkyl group having 7 to 20 carbon atoms, a substituted or unsubstituted aralkyloxy group having 7 to 20 carbon atoms, a nitro group, an aldehyde group, a cyano group, and a carboxy group;
X₂ is (i) a single bond, (ii) a group selected from the group consisting of a substituted or unsubstituted alkylene group having 1 to 28 carbon atoms, a substituted or unsubstituted alkylidene group having 2 to 28 carbon atoms, a substituted or unsubstituted cycloalkylene group having 5 to 15 ring carbon atoms, a substituted or unsubstituted cycloalkylidene group having 3 to 26 ring carbon atoms, a substituted or unsubstituted arylene group having 6 to 20 ring carbon atoms, —S—, —SO—, —SO₂—, —O—, and —CO—, or (iii) a divalent group formed by linking two or more groups selected from the group described in (ii);
a represents the same as a in the formula (A1); and
each * represents a bond.

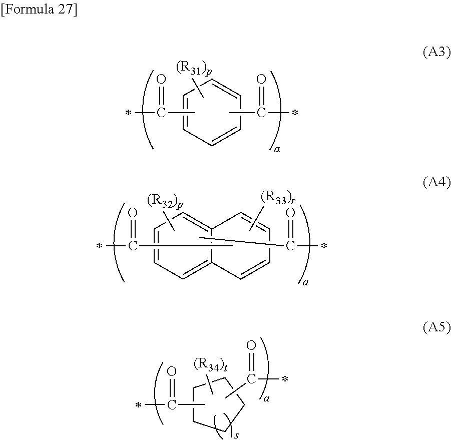

In the formulae (A3), (A4), and (A5):
R₃₁ to R₃₄ are each independently selected from the group consisting of a hydrogen atom, a halogen atom, a substituted or unsubstituted alkyl group having 1 to 18 carbon atoms, a substituted or unsubstituted alkoxy group having 1 to 18 carbon atoms, a substituted or unsubstituted cycloalkyl group having 6 to 20 ring carbon atoms, a substituted or unsubstituted cycloalkoxy group having 6 to 20 ring carbon atoms, a substituted or unsubstituted alkenyl group having 2 to 10 carbon atoms, a substituted or unsubstituted aryl group having 6 to 14 ring carbon atoms, a substituted or unsubstituted aryloxy group having 6 to 14 ring carbon atoms, a substituted or unsubstituted aralkyl group having 7 to 20 carbon atoms, a substituted or unsubstituted aralkyloxy group having 7 to 20 carbon atoms, a nitro group, an aldehyde group, a cyano group, and a carboxy group;
p is 4;
q is 2, 3, or 4; r is 2, 3, or 4; and q+r is 6;
s is 1, 2, 3, 4, 5, 6, 7, or 8; and t is 2s+6;
a plurality of R₃₁ are identical to each other or different from each other;
a plurality of R₃₂ are identical to each other or different from each other;
a plurality of R₃₃ are identical to each other or different from each other;
a plurality of R₃₄ are identical to each other or different from each other;
a represents the same as a in the formula (A1); and
each * represents a bond.

In the resin and the copolymer according to the exemplary embodiment, the group described in (iii) as X or X₂ is more preferably a divalent group formed by linking two to ten groups selected from the group described in (ii), and still more preferably a divalent group formed by linking two to eight groups selected from the group described in (ii).

In the structural unit represented by formula (A5), s is preferably 1 or 2. When s in the structural unit represented by formula (A5) is 1, the structural unit represented by formula (A1) is represented by a formula (A5-R5) below. When s is 2, the structural unit represented by formula (A1) is represented by a formula (A5-R6) below.

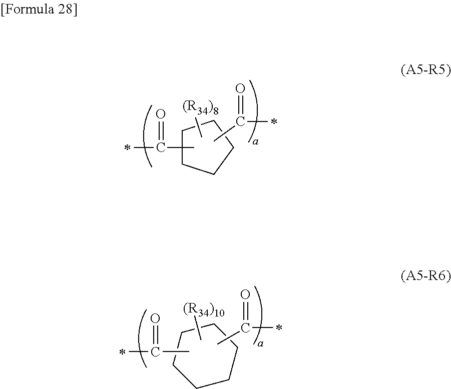

In formulae (A5-R5) and (A5-R6), R₃₄ represents the same as R₃₄ in formula (A5), a represents the same as a in formula (A1), and each * represents a bond.

The resin and the copolymer according to the exemplary embodiment may include a structural unit other than the aforementioned structural units. Examples of such a structural unit include a terminal structure derived from a chain terminator described later and a structural unit containing a silicon atom.

### Viscosity Average Molecular Weight

The viscosity average molecular weight (Mv) of the resin and the copolymer according to the exemplary embodiment is preferably in a range from 500 to 100,000, more preferably in a range from 1,000 to 80,000, and still more preferably in a range from 1,000 to 70,000, from the viewpoint of a solution viscosity.

Herein, the viscosity average molecular weight (Mv) is calculated by the following Schnell's equation, in which a solution is prepared by dissolving a resin or copolymer in methylene chloride serving as a solvent, the intrinsic viscosity [η] of the solution at 20 degrees C. is measured using an Ubbelohde viscometer, and the measured value is used in the equation.

$$[ η ] = 1.23 \times 1 {0}^{- 5} {Mv}^{0.83}$$

### Thermal Expansion Coefficient

Since the resin and the copolymer according to the exemplary embodiment preferably have a low thermal expansion coefficient, the thermal expansion coefficient at temperatures from 40 degrees C. to 100 degrees C. is preferably 150 ppm/K or less, more preferably 120 ppm/K or less, and still more preferably 115 ppm/K or less. The thermal expansion coefficient can be measured by the method described in Examples. The thermal expansion coefficient may also be referred to as a coefficient of thermal expansion.

### Glass Transition Temperature (Tg)

The resin and the copolymer according to the exemplary embodiment preferably have a glass transition temperature (Tg) of 80 degrees C. or more, more preferably 100 degrees C. or more, and still more preferably 120 degrees C. or more. The glass transition temperature can be measured by the method described in Examples.

### Dielectric Properties

There are various methods for evaluating dielectric properties. A commonly used method is a cavity resonator perturbation method (hereinafter referred to as a cavity resonator method), which uses an electric field along a sample to evaluate the dielectric properties. However, the electric field deflects to the outside of the sample at both ends of the sample. Since there is no known quantitative explanation for the imperfection, the dielectric constant is typically calculated by assuming that the electric field passes through the entire sample. Therefore, values of the dielectric properties are calculated assuming that the electric field is applied to the entire sample, even though no electric field is applied to either end of the sample. The dielectric constant is thus measured to be low. Unlike the cavity resonance method, a split cylinder resonator perturbation method (hereinafter referred to as a split cylinder method), which uses a circular electric field along a sample surface for measurement, does not cause errors due to the deflection of the electric field at both ends of the sample. Therefore, the split cylinder method outputs a dielectric property value closer to the true value than the cavity resonance method.

In the resin and the copolymer according to the exemplary embodiment, a dielectric constant (Dk) measured with a split-cylinder resonator at a frequency of 10 GHz at room temperature (23 degrees C.) is preferably 2.80 or less, more preferably 2.75 or less, still more preferably 2.70 or less, and still further more preferably 2.65 or less.

Moreover, in the resin and the copolymer according to the exemplary embodiment, the dissipation factor (Df) measured with a split-cylinder resonator at a frequency of 10 GHz at room temperature (23 degrees C.) is preferably 0.0200 or less, more preferably 0.0070 or less, still more preferably 0.0050 or less, and still further more preferably 0.0035 or less.

Since the dielectric constant (Dk) and the dissipation factor (Df) of the resin and the copolymer according to the exemplary embodiment are equal to or less than the aforementioned upper limit values, the use of the resin and the copolymer according to the exemplary embodiment as an electronic substrate material can reduce loss of electric signals in the electronic substrate.

### Description of Substituents Etc.

In the resin and the copolymer according to the exemplary embodiment, examples of the halogen atom include a fluorine atom, a chlorine atom, a bromine atom, and an iodine atom.

In the resin and the copolymer according to the exemplary embodiment, examples of the alkyl group include a methyl group, an ethyl group, an n-propyl group, an isopropyl group, a butyl group, a sec-butyl group, a tert-butyl group, various pentyl groups, and various hexyl groups. Herein, when the name of a substituent is preceded by the term “various,” the “various” indicates that both linear and all branched chain groups are included, and the same applies hereinafter.

In the resin and the copolymer according to the exemplary embodiment, examples of the substituted alkyl group include a trifluoromethyl group.

In the resin and the copolymer according to the exemplary embodiment, the number of carbon atoms of the alkyl group is preferably, for instance, in a range from 1 to 28, in a range from 1 to 20, in a range from 1 to 18, in a range from 1 to 10, or in a range from 1 to 5.

Herein, a numerical range expressed as “AA to BB” means a range from the lower limit value AA described in the former part of “AA to BB” to the upper limit value BB described in the latter part of “AA to BB.”

In the resin and the copolymer according to the exemplary embodiment, examples of the alkylene group include a methylene group, an ethylene group, a trimethylene group, a tetramethylene group, and a hexamethylene group.

In the resin and the copolymer according to the exemplary embodiment, the number of carbon atoms of the alkylene group is preferably in a range from 1 to 28, in a range from 1 to 20, in a range from 1 to 18, in a range from 1 to 10, or in a range from 1 to 5.

In the resin and the copolymer according to the exemplary embodiment, examples of the alkylidene group include an ethylidene group and an isopropylidene group.

In the resin and the copolymer according to the exemplary embodiment, the number of carbon atoms of the alkylidene group is preferably in a range from 2 to 28, in a range from 2 to 20, in a range from 2 to 18, in a range from 2 to 10, or in a range from 2 to 5.

In the resin and the copolymer according to the exemplary embodiment, examples of the alkoxy group include a methoxy group, an ethoxy group, a propoxy group, an isopropoxy group, a butoxy group, an isobutoxy group, a sec-butoxy group, a tert-butoxy group, various pentyloxy groups, and various hexyloxy groups.

In the resin and the copolymer according to the exemplary embodiment, the number of carbon atoms of the alkoxy group is, for instance, in a range from 1 to 18, in a range from 1 to 10, or in a range from 1 to 5.

In the resin and the copolymer according to the exemplary embodiment, examples of the cycloalkyl group include a cyclopropyl group, a cyclobutyl group, a cyclopentyl group, a cyclohexyl group, a cycloheptyl group, an adamantyl group, and a norbornyl group.

In the resin and the copolymer according to the exemplary embodiment, the number of ring carbon atoms of the cycloalkyl group is preferably in a range from 3 to 26, in a range from 3 to 20, or in a range from 6 to 20.

In the resin and the copolymer according to the exemplary embodiment, examples of the cycloalkylene group include a cyclopentane-diyl group, a cyclohexane-diyl group, and a cyclooctane-diyl group.

In the resin and the copolymer according to the exemplary embodiment, the number of ring carbon atoms of the cycloalkylene group is preferably in a range from 5 to 15 or in a range from 5 to 10.

In the resin and the copolymer according to the exemplary embodiment, examples of the cycloalkylidene group include a cyclohexylidene group, a 3,5,5-trimethylcyclohexylidene group, and a 2-adamantylidene group.

In the resin and the copolymer according to the exemplary embodiment, the number of ring carbon atoms of the cycloalkylidene group is preferably in a range from 3 to 26, in a range from 5 to 15, or in a range from 5 to 10.

In the resin and the copolymer according to the exemplary embodiment, examples of the cycloalkoxy group include a cycloalkoxy group in which the cycloalkyl moiety is the cycloalkyl group described above, that is, a group represented by —O-Arx in which Arx is the cycloalkyl group described above.

In the resin and the copolymer according to the exemplary embodiment, the number of ring carbon atoms of the cycloalkoxy group is preferably in a range from 3 to 20 or in a range from 6 to 20.

In the resin and the copolymer according to the exemplary embodiment, examples of the alkenyl group include an ethenyl group (vinyl group), a 1-propenyl group, a 2-propenyl group (allyl group), a butenyl group, a pentenyl group, and a hexenyl group.

In the resin and the copolymer according to the exemplary embodiment, the number of carbon atoms of the alkenyl group is preferably in a range from 2 to 10 or in a range from 2 to 6.

In the resin and the copolymer according to the exemplary embodiment, examples of the alkynyl group include an ethynyl group, a 1-propynyl group, a 2-propynyl group, a 1-butynyl group, and a 3-hexynyl group.

In the resin and the copolymer according to the exemplary embodiment, the number of carbon atoms of the alkynyl group is preferably in a range from 2 to 10 or in a range from 2 to 6.

In the resin and the copolymer according to the exemplary embodiment, examples of the aryl group include a phenyl group, a biphenyl group, a naphthyl group, an antryl group, and a phenanthryl group.

In the resin and the copolymer according to the exemplary embodiment, examples of the substituted aryl group include a 2-methylphenyl group, a 3-methylphenyl group, a 4-methylphenyl group, a 4-ethylphenyl group, a dichlorophenyl group, and a methylnaphthyl group.

In the resin and the copolymer according to the exemplary embodiment, the number of ring carbon atoms of the aryl group is preferably in a range from 6 to 20, for instance, in a range from 6 to 14 or in a range from 6 to 10.

In the resin and the copolymer according to the exemplary embodiment, examples of the arylene group include a phenylene group, a naphthylene group, an anthracenediyl group, a biphenylene group, and a terphenyldiyl group.

In one embodiment of the resin and the copolymer according to the exemplary embodiment, the number of ring carbon atoms of the arylene group is preferably in a range from 6 to 20, in a range from 6 to 14, or in a range from 6 to 10.

In the resin and the copolymer according to the exemplary embodiment, examples of the aryloxy group include a phenoxy group and a naphthyloxy group.

In the resin and the copolymer according to the exemplary embodiment, examples of the substituted aryloxy group include a tolyloxy group.

In the resin and the copolymer according to the exemplary embodiment, the number of ring carbon atoms of the aryloxy group is preferably in a range from 6 to 14 or in a range from 6 to 10.

In the resin and the copolymer according to the exemplary embodiment, examples of the aralkyl group include a phenylmethyl group and a phenylethyl group.

In the resin and the copolymer according to the exemplary embodiment, the number of carbon atoms of the aralkyl group is preferably in a range from 7 to 20 or in a range from 7 to 15.

In the resin and the copolymer according to the exemplary embodiment, examples of the aralkyloxy group include an aralkyloxy group in which the aralkyl moiety is the aforementioned aralkyl group, that is, a group represented by —O-Ary in which Ary is the aforementioned aralkyl group.

In the resin and the copolymer according to the exemplary embodiment, the number of carbon atoms of the aralkyloxy group is preferably in a range from 7 to 20 or in a range from 7 to 15.

In the resin and the copolymer according to the exemplary embodiment, examples of the monovalent aromatic hydrocarbon group include the aforementioned aryl group.

In the resin and the copolymer according to the exemplary embodiment, examples of the divalent aromatic hydrocarbon group include a divalent group derived by removing one hydrogen atom from an aryl ring of the aforementioned aryl group.

In the resin and the copolymer according to the exemplary embodiment, examples of the monovalent cyclic aliphatic hydrocarbon group include saturated or unsaturated alicyclic groups. The number of carbon atoms of the alicyclic group is, for instance, in a range from 3 to 20, preferably in a range from 3 to 12, more preferably in a range from 4 to 8. Specific examples of the saturated or unsaturated alicyclic group include: cycloalkyl groups such as cyclopropyl, cyclobutyl, cyclopentyl, cyclohexyl, cycloheptyl, adamantyl, and norbornyl, which are saturated alicyclic groups; and cycloalkenyl groups such as cyclopropenyl, cyclobutenyl, cyclopentenyl, cyclohexenyl, and cycloheptenyl, which are unsaturated alicyclic groups. It should be noted that the unsaturated alicyclic group does not include an aromatic group.

In the resin and the copolymer according to the exemplary embodiment, examples of the divalent cyclic aliphatic hydrocarbon group include a divalent group derived by removing one hydrogen atom from a ring of the aforementioned saturated or unsaturated alicyclic group.

In the resin and the copolymer according to the exemplary embodiment, examples of the monovalent acyclic aliphatic hydrocarbon group include the aforementioned alkyl group.

In the resin and the copolymer according to the exemplary embodiment, examples of the divalent acyclic aliphatic hydrocarbon group include a divalent group derived by removing one hydrogen atom from an alkyl chain of the aforementioned alkyl group. The examples include the aforementioned alkylene group and the aforementioned alkylidene group.

Herein, substituents for a “substituted or unsubstituted” group are bonded to each other to form a monocyclic ring, bonded to each other to form a fused ring, or not bonded to each other, Here, a case where substituents for a “substituted or unsubstituted” group are bonded to each other to form a monocyclic ring, or bonded to each other to form a fused ring also includes a case where substituents are bond to each other to form a polycyclic group. The polycyclic group is preferably a bicyclic group, a tricyclic group, or a tetracyclic group.

With respect to groups derived from cycloalkanes (such as a cycloalkyl group, cycloalkylene group, and cycloalkylidene group), a case where substituents for “substituted or unsubstituted” groups are bonded to each other to form a polycyclic group is exemplified by monovalent or divalent groups derived from bicycloalkanes, tricycloalkanes, and tetracycloalkanes.

Herein, substituents as referred to in “substituted” in the phrase “substituted or unsubstituted” group are each independently preferably at least one substituent selected from the group consisting of an alkyl group, a cycloalkyl group, an alkoxy group, an aryl group, an aryloxy group, and a halogen atom. Specific examples of these substituents include groups similar to the specific examples described above. Further, herein, the term “unsubstituted” in the phrase “substituted or unsubstituted” means that no substitution with the aforementioned substituents is present and a hydrogen atom is bonded.

Herein, in specific examples of compounds, D may represent a deuterium atom, Me may represent a methyl group, Ph may represent a phenyl group, and tBu may represent a tert-butyl group.

Herein, the preferred requirements can be optionally adopted, and combinations of the preferred ones can be said to be more preferable.

### Method for Producing Resin and Copolymer

### Divalent Phenol Compound

The resin and the copolymer according to the exemplary embodiment can preferably be produced using a divalent phenol compound (mc) represented by a formula (MC1) below. The structural unit represented by the formula (C1) is derived from the divalent phenol compound (mc).

Accordingly, the exemplary embodiment also provides for use of the divalent phenol compound (mc) represented by the formula (MC1) below for producing the resin and the copolymer according to the exemplary embodiment.

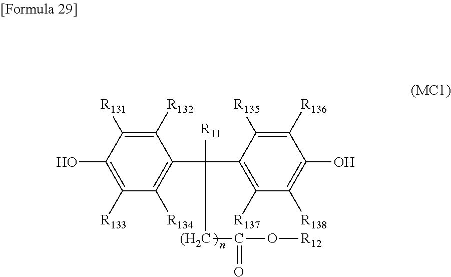

In the formula (MC1): R₁₁, R₁₂, R₁₃₁ to R₁₃₈, and n respectively represent the same as R₁₁, R₁₂, R₁₃₁ to R₁₃₈, and n in the formula (C1).

Preferred examples of the divalent phenol compound (mc) include a divalent phenol compound represented by a formula (MC2) below.

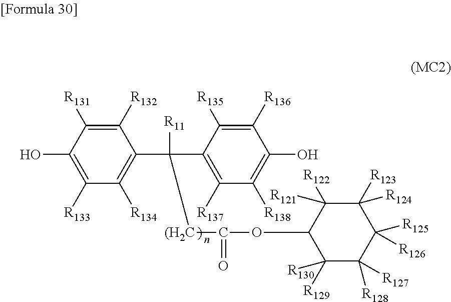

In the formula (MC2): R₁₁, R₁₃₁ to R₁₃₈, and n respectively represent the same as R₁₁, R₁₃₁ to R₁₃₈, and n in the formula (C1); and
R₁₂₁ to R₁₃₀ respectively represent the same as R₁₂₁ to R₁₃₀ in the formula (C2).

The divalent phenol compound (mc) can be produced, for instance, by reacting a carboxylic acid compound (mc-x) represented by a formula (MC1-x) below with an alcohol compound (mc-y) represented by a formula (Mc1-y) below, if necessary, in the presence of an acid catalyst.

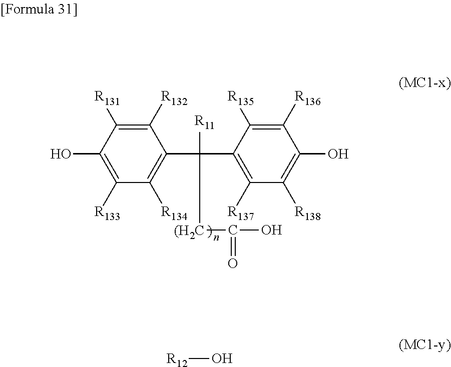

In the formula (MC1-x): R₁₁, R₁₃₁ to R₁₃₈, and n respectively represent the same as R₁₁, R₁₃₁ to R₁₃₈, and n in the formula (C1).

In the formula (MC1-y), R₁₂ represents the same as R₁₂ in the formula (C1).

### Method for Producing Polycarbonate Resin and Polycarbonate Copolymer

The resin and the copolymer including, as a polycarbonate repeating unit, the structural unit represented by formula (C1) (i.e., the repeating unit represented by formula (PC-CB1)) can be produced, for instance, by using the divalent phenol compound (mc) represented by the formula (MC1) as the divalent phenol compound, according to a known method for producing a polycarbonate resin. Examples of the method for producing the polycarbonate resin include production methods (P1-1), (P1-2), and (P1-3).

### Production Method (P1-1)

The production method (P1-1) is an interfacial polymerization method (phosgene method), in which a divalent phenol compound and phosgene are reacted in the presence of an organic solvent inert to the reaction and an alkaline aqueous solution, followed by the addition of a polymerization catalyst such as a tertiary amine or a quaternary ammonium salt to carry out the polymerization.

### Production Method (P1-2)

The production method (P1-2) is a melt polymerization method (ester-exchange method), in which a divalent phenol compound and a carbonate diester are subjected to a ester exchange reaction in a molten state without using a solvent, by adding a basic catalyst.

### Production Method (P1-3)

The production method (P1-3) is a pyridine method, in which a divalent phenol compound is dissolved in pyridine or in a mixed solution of pyridine and an inert solvent, and phosgene is introduced to directly produce the polycarbonate resin.

In the above reactions, for instance, at least one additive selected from the group consisting of a molecular weight regulator (chain terminator), a branching agent, and the like is used, if necessary.

As the method for producing the polycarbonate resin according to the exemplary embodiment, a production method (P1-4) below is preferable.

### Production Method (P1-4)

The production method (P1-4) is a method for producing an aromatic polycarbonate resin, which includes a step of subjecting a divalent phenol compound and a polycarbonate oligomer to interfacial polycondensation in the presence of a water-insoluble organic solvent and an aqueous solution of an alkaline compound, in which the divalent phenol compound includes the divalent phenol compound (mc) represented by formula (MC1).

Specifically, in the case of the interfacial polymerization method of the production method (P1-1) or (P1-4), a previously prepared polycarbonate oligomer described later is dissolved in a water-insoluble organic solvent (such as methylene chloride), an aqueous solution of an alkaline compound of a divalent phenol compound (such as an aqueous sodium hydroxide solution) is added, a tertiary amine (such as triethylamine) or a quaternary ammonium salt (such as trimethylbenzylammonium chloride) is used as a polymerization catalyst, and, if necessary, interfacial polycondensation is carried out in the presence of a chain terminator (a monohydric phenol such as p-tert-butylphenol), thereby producing the polycarbonate resin according to the exemplary embodiment. Further, in the case of the above-described interfacial polymerization method, the polycarbonate resin according to the exemplary embodiment can be produced by copolymerizing a divalent phenol with phosgene, a carbonate ester, or a chloroformate.

The polycarbonate oligomer can be produced by reacting a divalent phenol compound with a carbonate precursor (e.g., phosgene or triphosgene) in an organic solvent such as methylene chloride, chlorobenzene, or chloroform. When producing the polycarbonate oligomer by the ester-exchange method, the polycarbonate oligomer can also be produced by reacting a divalent phenol compound with a carbonate precursor such as diphenyl carbonate.

In the method for producing the polycarbonate resin according to the exemplary embodiment, the divalent phenol includes the divalent phenol compound (mc) represented by the formula (MC1) from which the structural unit represented by the formula (C1) is derived.

In the method for producing the polycarbonate resin according to the exemplary embodiment, it is preferable that the divalent phenol further includes a divalent phenol compound (md) represented by a formula (MD1) below, from which the structural unit represented by the formula (D1) is derived.

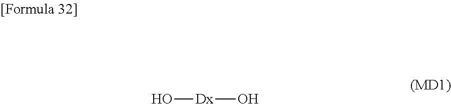

In the formula (MD1), Dx represents the same as Dx in the formula (D1).

Examples of the divalent phenol compound (md) include bis(hydroxyphenyl)alkane divalent phenols, bis(hydroxyphenyl)cycloalkane divalent phenols, dihydroxybiphenyl compounds, dihydroxybenzene compounds, dihydroxynaphthalene compounds, bis(4-hydroxyphenyl)oxide, bis(4-hydroxyphenyl)sulfide, bis(4-hydroxy-3-methylphenyl)sulfide, bis(4-hydroxyphenyl)ether, bis(3-fluoro-4-hydroxyphenyl)ether, bis(4-hydroxyphenyl)sulfone, bis(4-hydroxy-3-methylphenyl)sulfone, bis(4-hydroxyphenyl)sulfoxide, and 4,4′-dihydroxybenzophenone.

Examples of the bis(hydroxyphenyl)alkane divalent phenols include bis(4-hydroxyphenyl)methane, bis(4-hydroxy-3-methylphenyl)methane, 1,1-bis(4-hydroxyphenyl)-1,1-diphenylmethane, 1,1-bis(2-tert-butyl-4-hydroxy-5-methylphenyl)-1-phenylmethane, 1,1-bis(4-hydroxyphenyl)-1-phenylmethane, bis(3-chloro-4-hydroxyphenyl)methane, bis(3,5-dibromo-4-hydroxyphenyl)methane, 1,1-bis(4-hydroxyphenyl)ethane, 1,2-bis(4-hydroxyphenyl)ethane, 2-(4-hydroxy-3-methylphenyl)-2-(4-hydroxyphenyl)-1-phenylethane, 1,1-bis(4-hydroxyphenyl)-1-phenylethane, 1,1-bis(2-tert-butyl-4-hydroxy-3-methylphenyl)ethane, 1-phenyl-1,1-bis(3-fluoro-4-hydroxyphenyl)ethane, 2,2-bis(4-hydroxyphenyl)propane [bisphenol A (BPA)], 2,2-bis(4-hydroxy-3,5-dimethylphenyl)propane, 1,1-bis(3-cyclohexyl-4-hydroxyphenyl)propane, 1,1-bis(4-hydroxy-3-phenylphenyl)propane, 2,2-bis(4-hydroxy-3-methylphenyl)propane, 2,2-bis(4-hydroxy-2-methylphenyl)propane, 1,1-bis(2-tert-butyl-4-hydroxy-5-methylphenyl)propane, 2,2-bis(3-chloro-4-hydroxyphenyl)propane, 2,2-bis(3-fluoro-4-hydroxyphenyl)propane, 2,2-bis(3-bromo-4-hydroxyphenyl)propane, 2,2-bis(3,5-difluoro-4-hydroxyphenyl)propane, 2,2-bis(3,5-dichloro-4-hydroxyphenyl)propane, 2,2-bis(3,5-dibromo-4-hydroxyphenyl)propane, 2,2-bis(3-bromo-4-hydroxy-5-chlorophenyl)propane, 2,2-bis(3-hydroxyphenyl)hexafluoropropane, 2,2-bis(3-phenyl-4-hydroxyphenyl)propane, 1,1-bis(2-butyl-4-hydroxy-5-methylphenyl)butane, 1,1-bis(2-tert-butyl-4-hydroxy-5-methylphenyl)butane, 1,1-bis(2-tert-butyl-4-hydroxy-5-methylphenyl)isobutane, 1,1-bis(2-tert-amyl-4-hydroxy-5-methylphenyl)butane, 2,2-bis(4-hydroxy-3-methylphenyl)butane, 2,2-bis(4-hydroxyphenyl)butane, 2,2-bis(3,5-dichloro-4-hydroxyphenyl)butane, 2,2-bis(3,5-dibromo-4-hydroxyphenyl)butane, 2,2-bis(4-hydroxyphenyl)octane, 4,4-bis(4-hydroxyphenyl)heptane, and 1,1-bis(2-tert-butyl-4-hydroxy-5-methylphenyl)heptane.

Examples of the bis(hydroxyphenyl)cycloalkane divalent phenols include 1,1-bis(4-hydroxyphenyl)cyclopentane, 1,1-bis(4-hydroxyphenyl)cyclohexane, 1,1-bis(4-hydroxy-3-methylphenyl)cyclohexane, 1,1-bis(4-hydroxyphenyl)-3,3,5-trimethylcyclohexane, 1,1-bis(4-hydroxy-3,5-dimethylphenyl)-3,3,5-trimethylcyclohexane, 1,1-bis(3-cyclohexyl-4-hydroxyphenyl)cyclohexane, 1,1-bis(3-phenyl-4-hydroxyphenyl)cyclohexane, 1,1-bis(4-hydroxy-3-phenylphenyl)cyclohexane, 1,1-bis(4-hydroxyphenyl)cyclododecane, 1,1-bis(4-hydroxy-3-methylphenyl)cyclododecane, and 1,1-bis(4-hydroxy-3,5-dimethylphenyl)cyclododecane.

Examples of the dihydroxybiphenyl compounds include 4,4′-dihydroxybiphenyl, 3,3′-difluoro-4,4′-dihydroxybiphenyl, 4,4′-dihydroxy-3,3′-dimethylbiphenyl, 4,4′-dihydroxy-2,2′-dimethylbiphenyl, 4,4′-dihydroxy-2,2′,5,5′-dimethylbiphenyl, and 4,4′-dihydroxy-3,3′-dicyclohexylbiphenyl.

Examples of the dihydroxybenzene compounds include hydroquinone, resorcinol, and catechol.

Examples of the dihydroxynaphthalene compounds include 2,6-dihydroxynaphthalene and 1,4-dihydroxynaphthalene.

These divalent phenol compounds (md) may be used alone or in combination of two or more.

In one embodiment of the method for producing the polycarbonate resin and the copolymer according to the exemplary embodiment, only the divalent phenol compound (md) is usable as the divalent phenol compound for producing the above-described polycarbonate oligomer. In this case, in the interfacial polycondensation step, both the divalent phenol compound (mc) and the divalent phenol compound (md) may be used together, or only the divalent phenol compound (mc) may be used.

In order to adjust the molecular weight of the polycarbonate resin and the copolymer according to the exemplary embodiment, a chain terminator (molecular weight regulator) may be used. Examples of the chain terminator include monovalent phenols such as phenol, p-cresol, p-tert-butylphenol, p-tert-octylphenol, p-cumylphenol, p-nonylphenol, m-pentadecylphenol, and p-tert-amylphenol. These monovalent phenols may be used alone or in combination of two or more.

### Method for Producing Polyester Resin and Polyester Copolymer

The resin and the copolymer including, as a polyester repeating unit, the structural unit represented by the formula (C1) (i.e., the repeating unit represented by the formula (PE-CA1)) can be produced, for instance, by using the divalent phenol compound (mc) represented by the formula (MC1) as the divalent phenol compound, according to a known method for producing a polyester resin. As a method for producing a polyester resin, for instance, there may be mentioned a method in which a bisphenol for forming a repeating unit derived from bisphenol and a dicarboxylic acid for forming a repeating unit derived from dicarboxylic acid are subjected to polycondensation. Examples of the polycondensation method include solution polymerization, melt polymerization, and interfacial polymerization.

In one embodiment of the method for producing the polyester resin and the copolymer according to the exemplary embodiment, only the divalent phenol compound (mc) represented by the formula (MC1) or (MC2) may be used as the bisphenol for forming a repeating unit derived from bisphenol.

In one embodiment of the method for producing the polyester resin and the copolymer according to the exemplary embodiment, not only the divalent phenol compound (mc) but also the divalent phenol compound (md) represented by the formula (MD1) may additionally be used as the bisphenol for forming a repeating unit derived from bisphenol.

In one embodiment of the method for producing the polyester resin and the copolymer according to the exemplary embodiment, a dicarboxylic acid compound (ma) represented by a formula (MA1) below may be used as the dicarboxylic acid for forming a repeating unit derived from dicarboxylic acid.

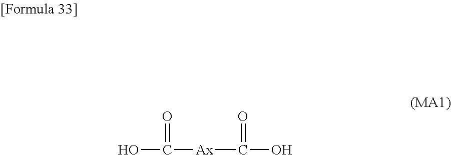

In the formula (MA1), Ax represents the same as Ax in the formula (A1).

In the method for producing the polyester resin and the copolymer according to the exemplary embodiment, it is preferable to use at least one dicarboxylic acid compound selected from the group consisting of the dicarboxylic acid compounds represented by formulae (MA2), (MA3), (MA4), and (MA5), as the dicarboxylic acid compound (ma) for forming a repeating unit derived from dicarboxylic acid.

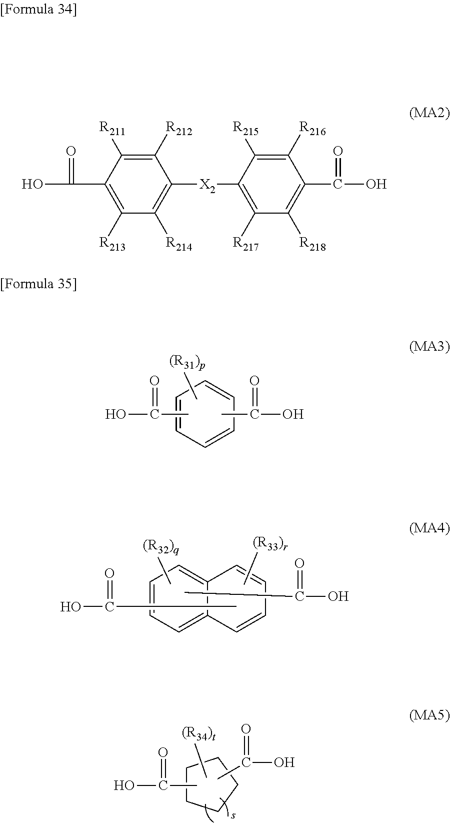

In the formula (MA2), R₂₁₁ to R₂₁₈ and X₂ respectively represent the same as R₂₁₁ to R₂₁₈ and X₂ in the formula (A2).

In the formula (MA3), R₃₁ and p respectively represent the same as R₃₁ and p in the formula (A3).

In the formula (MA4), R₃₂, R₃₃, q and r respectively represent the same as R₃₂, R₃₃, q and r in the formula (A4).

In the formula (MA5), R₃₄, t, and s respectively represent the same as R₃₄, t, and s in the formula (A5).

In the method for producing the polyester resin and the copolymer according to the exemplary embodiment, the bisphenol may be used after being derivatized into an aromatic diacetate.

In the method for producing the polyester resin and the copolymer according to the exemplary embodiment, the dicarboxylic acid compound (ma) may be used after being derivatized. Examples of derivatives of the dicarboxylic acid compound (ma) include a dicarboxylic acid dichloride, a dicarboxylic acid dimethyl ester, a dicarboxylic acid diethyl ester, and a dicarboxylic acid anhydride. The dicarboxylic acid dichloride is a compound in which the two “—C(═O)—OH” groups of the dicarboxylic acid are substituted with “—C(═O)—Cl” groups. For instance, dichloride of the dicarboxylic acid compound (ma) represented by the formula (MA1) is represented by a formula (MA1-CL) below.

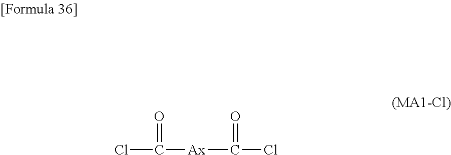

In the formula (MA1-CL), Ax represents the same as Ax in the formula (A1).

In the method for producing the polyester resin and the copolymer according to the exemplary embodiment, a chain terminator may be added during the polycondensation reaction between bisphenol and dicarboxylic acid. Examples of the chain terminator include p-tert-butylphenol, 2,6-dimethylphenol, and 1H,1H-perfluoro-1-heptanol. As the chain terminator, the chain terminator mentioned in the description of the method for producing the polycarbonate resin may also be used.

In the method for producing the polyester resin and the copolymer according to the exemplary embodiment, either or both of a base and a catalyst may be added during the polycondensation reaction between bisphenol and dicarboxylic acid. Examples of the base include sodium hydroxide. Examples of the catalyst include benzyltributylammonium chloride, ammonium chloride, ammonium bromide, quaternary ammonium salts, triethylamine, and trimethylamine.

### Method for Producing Polyester Polycarbonate Resin and Polyester Polycarbonate Copolymer

The resin and the copolymer that includes the structural unit represented by the formula (C1) as a polycarbonate repeating unit (the structural unit represented by the formula (PC-CB1)) and includes a polyester repeating unit can be produced by using the divalent phenol compound (mc) represented by the formula (MC1) as the divalent phenol compound, and employing a known method for producing a polyester polycarbonate resin.

The resin and the copolymer including the structural unit represented by the formula (C1) as a polyester repeating unit (the structural unit represented by the formula (PE-CA1)) and including a polycarbonate repeating unit can be produced by using the divalent phenol compound (mc) represented by the formula (MC1) as the divalent phenol compound, and employing a known method for producing a polyester polycarbonate resin.

The polyester polycarbonate resin and the copolymer according to the exemplary embodiment can be produced by using the divalent phenol compound (mc) represented by the formula (MC1) and the dicarboxylic acid compound (ma) represented by the formula (MA1). Examples of the method for producing the polyester polycarbonate resin and the copolymer include a method in which a bisphenol for constituting a repeating unit derived from bisphenol, a dicarboxylic acid for constituting a repeating unit derived from dicarboxylic acid, and a compound for constituting a repeating unit derived from carbonate are subjected to polycondensation. The polyester polycarbonate resin and the copolymer according to the exemplary embodiment are produced in the presence of at least one additive selected from the group consisting of acid bonding agents, catalysts, molecular weight regulators (such as chain terminator and branching agent), and solvents, as needed.

Examples of the method for producing the polyester polycarbonate resin and the copolymer include melt polymerization, in which bisphenol, dicarboxylic acid, and diphenyl carbonate are subjected to ester exchange reaction in the presence of a basic catalyst under non-solvent conditions, and interfacial polymerization, in which bisphenol, dicarboxylic acid, and phosgene are reacted in the presence of an organic solvent inert to the reaction and a basic aqueous solution, followed by the addition of a polymerization catalyst such as a tertiary amine or a quaternary ammonium salt. In particular, the method of interfacial polycondensation of bisphenol, dicarboxylic acid chloride, and polycarbonate oligomer in the presence of a non-aqueous organic solvent and a basic compound aqueous solution, similar to the production method (P1-4), is preferable because it is simple, does not cause side reactions, and allows easy molecular weight control.

In the method for producing the polyester polycarbonate resin and the copolymer according to the exemplary embodiment, not only the divalent phenol compound (mc) but also the divalent phenol compound (md) represented by the formula (MD1) can be used as the divalent phenol compound. These divalent phenol compounds may be used alone or in combination of two or more.

In the method for producing the polyester polycarbonate resin and the copolymer according to the exemplary embodiment, a derivative of the dicarboxylic acid compound (ma) represented by the formulas (MA1) to (MA5) can also be used instead of the dicarboxylic acid compound (ma). Examples of the derivative of the dicarboxylic acid compound (ma) include dicarboxylic acid halides such as dicarboxylic acid dichloride, and derivatives of the dicarboxylic acid compound (ma) exemplified in the above description of the method for producing the polyester resin and the copolymer.

One specific example of a reaction scheme suitable for producing the polyester polycarbonate resin and the copolymer according to the exemplary embodiment is a two-stage polymerization, which involves performing the following steps (P3-1) and (P3-2).

### Step (P3-1)

Step (P3-1) as the first stage is a step in which a polycarbonate oligomer is synthesized using a portion of the divalent phenol compound (mc) and a carbonate ester-forming compound.

### Step (P3-2)

Step (P3-2) as the second stage is a step in which the polycarbonate oligomer synthesized in step (P3-1) is mixed with a reaction system including the remaining portion of the divalent phenol compound (mc) and the dicarboxylic acid compound (ma) or its derivative, and then subjected to a polycondensation reaction.

In the method for producing the polyester polycarbonate resin and the copolymer according to the exemplary embodiment, the synthesis of the polycarbonate oligomer in step (P3-1) as the first stage can be carried out by the following synthesis methods (P3-1a) and (P3-1b) and the like.

### Synthesis Method (P3-1a)

The synthesis method (P3-1a) is a method in which polycondensation is carried out in the presence of a suitable acid bonding agent using a carbonate ester-forming compound, such as carbonyl dihalides, haloformates, or carbonate ester compounds. Examples of the carbonyl dihalides include phosgene. Examples of haloformates include chloroformate compounds.

The above-described reaction in which polycondensation is carried out in the presence of an acid bonding agent using a carbonate ester-forming compound, such as carbonyl dihalides, haloformates, or carbonate ester compounds, is typically conducted in a solvent. The proportion of the carbonate ester-forming compound to be used may be appropriately adjusted, taking into account the stoichiometric ratio (equivalents) of the reaction. In addition, when using a gaseous carbonate ester-forming compound such as phosgene, a method of introducing it into the reaction system by blowing is preferably employed.

Examples of the acid bonding agent used in the synthesis method (P3-1a) include alkali metal hydroxides such as sodium hydroxide and potassium hydroxide, alkali metal carbonates such as sodium carbonate and potassium carbonate, organic bases such as pyridine, or mixtures thereof. The proportion of the acid bonding agent used may be appropriately determined, taking into account the stoichiometric ratio (equivalent) of the reaction. Specifically, it is preferable to use 2 equivalents or a slightly excess amount of the acid bonding agent per mole of the divalent phenol compound (mc) used.

As the solvent used in the synthesis method (P3-1a), a solvent known to be used for the production of polycarbonates may be used either as a single solvent or as a mixed solvent. The solvent is exemplified by hydrocarbon solvents (e.g., xylene) and halogenated hydrocarbon solvents (e.g., methylene chloride and chlorobenzene). In the synthesis method (P3-1a), interfacial polycondensation may be carried out using two immiscible solvents.

In the synthesis method (P3-1a), if desired, a small amount of an antioxidant may be added. Examples of the antioxidant include sodium bisulfite and hydrosulfite.

The reaction in the synthesis method (P3-1a) is carried out at a temperature, typically in a range from 0 to 50 degrees C., preferably in a range from 10 to 30 degrees C. The reaction pressure can be either reduced pressure, atmospheric pressure, or elevated pressure, but the reaction may be typically preferably carried out at atmospheric pressure or at about the self-generated pressure of the reaction system. The reaction time depends on factors such as reaction temperature, but is typically in a range from 10 to 60 minutes, preferably in a range from approximately 15 to 30 minutes.

### Synthesis Method (P3-1b)

The synthesis method (P3-1b) is a method in which ester exchange reaction is carried out using bisaryl carbonates as the carbonate ester-forming compound.

When using bisaryl carbonate as the carbonate ester-forming compound and synthesizing the polycarbonate oligomer by ester exchange method, suitable reaction schemes include melt polycondensation and solid-phase polycondensation.

Examples of bisaryl carbonates include di-p-tolyl carbonate, phenyl-p-tolyl carbonate, di-p-chlorophenyl carbonate, and dinaphthyl carbonate.

In the synthesis method (P3-1b), when performing melt polycondensation, the divalent phenol compound (mc) and bisaryl carbonate are mixed and reacted in a molten state at high temperature under reduced pressure. The reaction is carried out at a temperature, typically in a range from 150 to 350 degrees C., preferably in a range from 200 to 300 degrees C.

In the synthesis method (P3-1b), when performing solid-phase polycondensation, the divalent phenol compound (mc) and bisaryl carbonate are mixed and heated in a solid state to a temperature equal to or less than the melting point of the resulting polycarbonate oligomer, thereby performing polycondensation. The reaction time depends on factors such as the reaction temperature and degree of vacuum, but is typically in a range from approximately 30 minutes to 2 hours. The reaction is preferably carried out under an inert gas atmosphere such as nitrogen or argon, and, if desired, the aforementioned antioxidant or the like may be added to the reaction.

Next, the step (P3-2) as the second stage in the method for producing the polyester polycarbonate resin and the copolymer according to the exemplary embodiment will be described. In the step (P3-2) as the second stage, the ratio of the remaining portion of the divalent phenol compound (mc) and the dicarboxylic acid compound (ma) or its derivative used to prepare the reaction system can be appropriately selected, taking into account the stoichiometric ratio of the polycondensation reaction. There are no particular limitations, but it is generally preferable to use approximately 1 mole of the dicarboxylic acid compound (ma) or its derivative per mole of the divalent phenol compound (mc). The reaction system including the remaining portion of the divalent phenol compound (mc) and the dicarboxylic acid compound (ma) or its derivative is typically prepared by dissolving the remaining portion of the divalent phenol compound (mc) in an aqueous solution of the above-described alkali metal hydroxide or alkali metal carbonate, then mixing it with the dicarboxylic acid compound (ma) or its derivative, which has been dissolved in the above-described organic solvent immiscible with water, and stirring the mixture. In this reaction system, a condensation reaction progresses between the remaining portion of the divalent phenol compound (mc) and the dicarboxylic acid compound (ma) or its derivative, resulting in the formation of a polyester oligomer.

Next, as the reaction in the step (P3-2) as the second stage, a solution of the polycarbonate oligomer synthesized in the step (P3-1), preferably, for instance, a solution of polycarbonate oligomer in methylene chloride, is mixed into the system in which the polyester oligomer has been formed, and polycondensation is carried out. The reaction temperature for this polycondensation reaction is typically in a range from approximately 0 to 50 degrees C., preferably in a range from approximately 5 to 20 degrees C. The reaction time is sufficient typically in a range from approximately 5 minutes to 3 hours, preferably in a range from approximately 10 minutes to 1.5 hours. There are no particular restrictions on the reaction pressure, but the reaction can typically and preferably be carried out at atmospheric pressure or with slight pressure. In carrying out this polycondensation reaction, if necessary, at an appropriate time, at least one additive selected from the group consisting of suitable molecular weight regulators, catalysts, and solvents may be added to the reaction system. In this way, the polyester polycarbonate resin and the copolymer according to the exemplary embodiment can be obtained.

Additionally, as another example of the two-stage polycondensation method for the polyester polycarbonate resin and the copolymer according to the exemplary embodiment, after synthesizing the polycarbonate oligomer in the first stage in the same manner as in the step (P3-1), the following step (P3-3) may be performed as the second stage.

### Step (P3-3)

In the step (P3-3), to a solution obtained by dissolving the polycarbonate oligomer synthesized in the step (P3-1) in an organic solvent that is immiscible with water was added a solution obtained by dissolving the dicarboxylic acid compound (ma) or its derivative in an aqueous solution of the above-described alkali metal hydroxide or alkali metal carbonate. The reaction is then carried out in the presence of at least one of a chain terminator or a catalyst.

Additionally, still another example of the two-stage polycondensation method for the polyester polycarbonate resin and the copolymer according to the exemplary embodiment is a two-stage polycondensation method in which the following steps (P3-4) and (P3-5) are carried out.

### Step (P3-4)

In the step (P3-4) as the first stage, a polyester oligomer is synthesized from a portion of the divalent phenol compound (mc) and the dicarboxylic acid compound (ma) or its derivative, in the same manner as in the step (P3-2).

### Step (P3-5)

In the step (P3-5) as the second stage, to a solution in which the polyester oligomer synthesized in the step (P3-4) is dissolved in an organic solvent is added a solution in which the remaining portion of the divalent phenol compound (mc) is dissolved in an aqueous solution of the alkali metal hydroxide or in an aqueous solution of alkali metal carbonate. The reaction is then carried out in the presence of the carbonate ester-forming compound, and at least one of a chain terminator or a catalyst.

As the method for producing the polyester polycarbonate resin and the copolymer according to the exemplary embodiment, the synthesis method may be selected depending on the desired structure and composition of the polyester polycarbonate.

In the method for producing the polyester polycarbonate resin and the copolymer according to the exemplary embodiment, examples of the above catalyst that can be used include tertiary amines such as triethylamine or quaternary ammonium salts.

Examples of the branching agent usable in the method for producing the polyester polycarbonate resin and the copolymer according to the exemplary embodiment include fluoroglucin, pyrogallol, 1,1,1-tris(4-hydroxyphenyl)methane, 1,1,1-tris(4-hydroxyphenyl)ethane, 1,1,1-tris(4-hydroxyphenyl)propane, 1,1,1-tris(3-methyl-4-hydroxyphenyl)ethane, 4,6-dimethyl-2,4,6-tris(4-hydroxyphenyl)-2-heptene, 4,6-dimethyl-2,4,6-tris(4-hydroxyphenyl)heptane, 2,6-dimethyl-2,4,6-tris(4-hydroxyphenyl)-3-heptene, 1,3,5-tris(2-hydroxyphenyl)benzene, 1,3,5-tris(4-hydroxyphenyl)benzene, tris(4-hydroxyphenyl)-phenylmethane, 2,2-bis[4,4-bis(4-hydroxyphenyl)cyclohexyl]propane, 2,4-bis(4-hydroxyphenylisopropyl)phenol, 2,6-bis(2-hydroxy-5-methylbenzyl)-4-methylphenol, 2-(4-hydroxyphenyl)-2-(2,4-dihydroxyphenyl)propane, α,α′,α″-tris(4-hydroxyphenyl)-1,3,5-triisopropylbenzene, 2,6-bis(2-hydroxy-5-methylbenzyl)-4-methylphenol, hexakis[4-(4-hydroxyphenylisopropyl)phenyl]-o-terephthalic acid ester, tetrakis(4-hydroxyphenyl)methane, tetrakis[4-(4-hydroxyphenylisopropyl)phenoxy]methane, 1,4-bis[(4′,4″-dihydroxytriphényl)methyl]benzene, 2,4-dihydroxybenzoic acid, trimesic acid, cyanuric acid chloride, 3,3-bis(3-methyl-4-hydroxyphenyl)-2-oxo-2,3-dihydroindole, 3,3-bis(4-hydroxyaryl)oxyindole (=isatin bisphenol), 5-chloroisatin, 5,7-dichloroisatin, 5-bromoisatin, and phloroglucide.

Examples of the chain terminator usable in the method for producing the polyester polycarbonate resin and the copolymer according to the exemplary embodiment include, for instance, phenol, α-naphthol, β-naphthol, o-cresol, m-cresol, p-cresol, 2,3-xyleneol, 2,4-xyleneol, 2,5-xyleneol, 2,6-xyleneol, 3,4-xyleneol, 3,5-xyleneol, p-ethylphenol, p-propylphenol, p-butylphenol, p-pentylphenol, p-hexylphenol, p-heptylphenol, p-octylphenol, p-nonylphenol, p-decylphenol, p-undecylphenol, p-dodecylphenol, p-isopropylphenol, p-tert-butylphenol, 2,6-dimethyl-p-tert-butylphenol, 2-tert-amyl-4-methylphenol, 3-methyl-6-tert-butylphenol, 2-methyl-4,6-di-tert-butylphenol, 2,4-di-tert-butylphenol, 2,6-di-tert-butyl-4-methylphenol, 4-tert-octylphenol, 4-tert-amylphenol, 2,4,6-tri-tert-butylphenol, p-phenylphenol, 2,6-di-tert-butyl-4-phenylphenol, 2,6-di-sec-butyl-4-methylphenol, o-anisole, m-anisole, p-anisole, o-chlorophenol, m-chlorophenol, p-chlorophenol, o-bromophenol, m-bromophenol, p-bromophenol, p-ethoxyphenol, o-aminophenol, m-aminophenol, p-aminophenol, p-cyanophenol, p-nitrophenol, 3-methyl-6-isopropylphenol, and 2-methyl-5-isopropylphenol. Preferred chain terminators are p-tert-butylphenol and p-phenylphenol.

In the exemplary embodiment, by using p-tert-butylphenol as the chain terminator, a resin and a copolymer having a terminal group represented by the following formula (T1) can be produced.

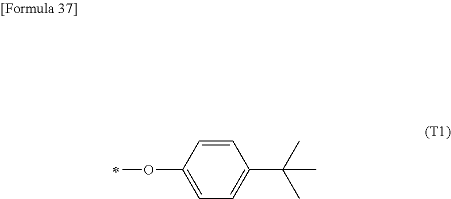

In the formula (T1), * represents a bonding position with a repeating unit at a terminal of the resin and the copolymer.

The reduced viscosity of the polyester polycarbonate resin and the copolymer according to the exemplary embodiment can be adjusted to a predetermined range by various methods, such as the selection of reaction conditions and adjustment of the amounts of the chain terminator and branching agent. Additionally, the obtained polyester polycarbonate resin and the copolymer can be subjected to at least one of a physical treatment or a chemical treatment as appropriate to obtain a polyester polycarbonate resin and a copolymer with a predetermined reduced viscosity. Examples of the physical treatment include mixing and fractionation. Examples of the chemical treatment include polymer reactions, crosslinking treatments, and partial degradation treatments.

### Second Exemplary Embodiment

### Electronic Substrate

An electronic substrate according to the exemplary embodiment includes the electronic substrate material according to the exemplary embodiment.

The electronic substrates can be broadly classified into a semiconductor substrate and an electronic circuit board.

### (1) Semiconductor Substrate

A semiconductor substrate is a substrate for forming a wiring layer for inputting and outputting electrical signals to and from chips, such as logic ICs, memories, and sensors. This wiring layer serves as a connection layer when connecting chips of the same or different types during parallel arrangement or stacking. Examples of chip types include FC-CSP (Flip Chip Chip Scale Package), FC-BGA (Flip Chip Ball Grid Array), and FO-WLP (Fan-Out Wafer Level Package).

### (2) Electronic Circuit Board

An electronic circuit board is a substrate having wiring layers formed to connect multiple electronic components such as semiconductors or capacitors. Types of the electronic circuit broad include multilayer boards (rigid and flexible) with stacked wiring.

### Electronic Substrate Material

An electronic substrate material according to the exemplary embodiment is used in the form of a coating liquid composition (varnish), a film, or a sheet in order to form an electronic substrate according to the exemplary embodiment. That is, these coating liquid composition (varnish), film, and sheet include the electronic substrate material according to the exemplary embodiment.

The electronic substrate material according to the exemplary embodiment is excellent in low dielectric properties, a low thermal expansion coefficient, and high heat resistance. The electronic substrate material according to the exemplary embodiment can provide a composition for coating liquid with high solvent solubility for coating molding and low solution viscosity characteristics.

The electronic substrate material according to the exemplary embodiment contains the first resin.

### First Resin

In the electronic substrate material according to the exemplary embodiment, the first resin is at least one resin selected from the group consisting of polycarbonate, polyester, and polyester polycarbonate.

In the electronic substrate material according to the exemplary embodiment, the first resin is the resin or the copolymer according to the first exemplary embodiment.

### Inorganic Filler

It is preferable that the electronic substrate material according to the exemplary embodiment further contains an inorganic filler.

In the exemplary embodiment, the inorganic filler is preferably at least one filler selected from the group consisting of silica, boron nitride, aluminum nitride, silicon nitride, silicon carbide, zinc oxide, titanium oxide, aluminum oxide, magnesium oxide, aluminum hydroxide, and magnesium hydroxide. Silica as the inorganic filler is preferably at least one type of silica selected from the group consisting of spherical silica, pulverized silica, hollow silica, and fumed silica.

### Thermoplastic Resin (Third Resin)

The electronic substrate material according to the exemplary embodiment may further include a thermoplastic resin (sometimes referred to as a third resin). The third resin is a thermoplastic resin that is different from the first resin. As the third resin, for instance, any known thermoplastic resin can be used.

### Coating Liquid Composition

The electronic substrate material according to the exemplary embodiment may be contained in a coating liquid composition.

The coating liquid composition in the exemplary embodiment contains the electronic substrate material, which is specifically the resin or the copolymer according to the first exemplary embodiment. The coating liquid composition according to the exemplary embodiment may be referred to as a varnish.

The coating liquid composition in the exemplary embodiment contains the electronic substrate material and an organic solvent.

During the molding process of the electronic substrate using the coating liquid composition, the solvent in the coating liquid composition is removed by heating.

As the organic solvent for the coating liquid composition, it can be appropriately selected considering factors such as the solubility of materials for the resin or copolymer according to the first exemplary embodiment, drying speed after molding, impact upon residue in the molded product, and potential hazards (fire risk or health hazards).

Examples of the organic solvent used for the coating liquid composition according to the exemplary embodiment include cyclic ethers (such as tetrahydrofuran (THF), dioxane, and dioxolane), cyclic ketones (such as cyclohexanone, cyclopentanone, and cycloheptanone), aromatic hydrocarbons (such as toluene, xylene, and chlorobenzene), ketones (such as methyl ethyl ketone (MEK) and methyl isobutyl ketone (MIBK)), halogenated hydrocarbons (such as dichloromethane and chloroform), esters (such as ethyl acetate, isopropyl acetate, isobutyl acetate, and butyl acetate), ethers (such as ethylene glycol dimethyl ether and ethylene glycol monoethyl ether), amides (such as N,N-dimethylformamide (DMF) and dimethylacetamide (DMAc), and aprotic polar solvents (such as dimethyl sulfoxide (DMSO)).

In the coating liquid composition according to the exemplary embodiment, considering environmental and safety aspects, it is preferable that the organic solvent is an organic solvent other than halogenated hydrocarbons, i.e., a non-halogen solvent. It is more preferable that the organic solvent is at least one selected from the group consisting of toluene, cyclohexanone, methyl ethyl ketone, tetrahydrofuran, dioxolane, and cyclopentanone.

The coating liquid composition according to the exemplary embodiment may contain the epoxy resin described in the third exemplary embodiment.

The concentration of the resin or copolymer according to the first exemplary embodiment in the coating liquid composition according to the second exemplary embodiment only needs to be a concentration that results in an appropriate viscosity for the intended use of the coating liquid composition. The concentration is preferably in a range from 0.1 mass % to 40 mass %.

The concentration of the resin or copolymer according to the first exemplary embodiment in the coating liquid composition according to the second exemplary embodiment is more preferably 1 mass % or more, still more preferably 5 mass % or more.

The concentration of the resin or copolymer according to the first exemplary embodiment in the coating liquid composition according to the second exemplary embodiment is more preferably 35 mass % or less, still more preferably 30 mass % or less.

When the concentration of the resin or copolymer according to the first exemplary embodiment in the coating liquid composition according to the second exemplary embodiment is 40 mass % or less, the viscosity does not become too high, resulting in good coating workability.

When the concentration of the resin or copolymer according to the first exemplary embodiment in the coating liquid composition according to the second exemplary embodiment is 0.1 mass % or more, a moderate viscosity can be kept to form a homogeneous film. Moreover, when the concentration is 0.1 mass % or more, it is possible to shorten the drying time after applying the coating liquid composition, and it becomes easier to form a film with the target thickness.

The electronic substrate material according to the exemplary embodiment may be applied in a solution state, i.e., as a coating liquid composition, directly onto a core material or the like made from polyimide, epoxy resin, or the like. In this case also, an inorganic filler such as silica may be dispersed in the coating liquid composition. As a solvent for dispersing the inorganic filler in the coating liquid composition, for instance, toluene, cyclohexanone, and MEK are preferably used.

### Film

A film according to the exemplary embodiment includes the electronic substrate material according to the exemplary embodiment.

The film according to the exemplary embodiment can be produced by forming a film of the electronic substrate material according to the exemplary embodiment through thermoforming (e.g., melt extrusion molding) or by forming a film through solution casting.

As the film according to the exemplary embodiment, when it is desired to obtain a thin film (e.g., a thickness of several micrometers to several tens of micrometers), a film is preferably formed through solution casting.

In addition, for the purpose of reducing thermal expansion, the electronic substrate material may be impregnated into glass cloth to form a film or may be formed into a film with an inorganic filler such as silica dispersed therein. Further, for purposes such as improving dielectric properties and adjusting the modulus of elasticity, the electronic substrate material containing a known thermoplastic resin as the third resin may also be used when forming a film. In the case where the electronic substrate material according to the exemplary embodiment has crosslinking sites, when such an electronic substrate material is formed into a film by solution casting, it is also possible to control the degree of crosslinking by incorporating a curing material into the electronic substrate material and adjusting the heating temperature, thereby varying properties such as the elastic modulus of the film.

### Sheet

A sheet according to the exemplary embodiment includes the electronic substrate material according to the exemplary embodiment.

When the electronic substrate material according to the exemplary embodiment is used as a sheet, it can be made into a sheet by impregnating a base material or the like with the coating liquid composition (varnish) described above.

### Third Exemplary Embodiment

### Resin Composition

The resin composition according to the exemplary embodiment contains the first resin and the second resin.

### First Resin

In the resin composition according to the exemplary embodiment, the first resin is at least one resin selected from the group consisting of polycarbonate, polyester, and polyester polycarbonate.

In the resin composition according to the exemplary embodiment, the first resin is the resin according to the first exemplary embodiment. The resin according to the first exemplary embodiment includes the structural unit represented by the formula (C1) and has an ester bond in a side chain of the resin, and therefore, can function as a curing agent for an epoxy resin.

The first resin included in the resin composition according to the exemplary embodiment is preferably a resin among the resins according to the first exemplary embodiment, in which R₁₂ in the structural unit represented by the formula (C1) does not include an —NH₂ group (amino group), —OH group (hydroxy group), and —COOH group (carboxy group).

More preferably, the first resin included in the resin composition according to the exemplary embodiment is a resin among the resins according to the first exemplary embodiment that does not include an —NH₂ group (amino group), an —OH group (hydroxy group), and a —COOH group (carboxy group) in the main chain and the side chain (excluding a terminal).

Still more preferably, the first resin included in the resin composition according to the exemplary embodiment is a resin among the resins according to the first exemplary embodiment that does not include an —NH₂ group (amino group), an —OH group (hydroxy group), and a —COOH group (carboxy group) in the main chain, the side chain, and a terminal.

Still further more preferably, the first resin included in the resin composition according to the exemplary embodiment is a resin among the resins according to the first exemplary embodiment that does not include an —NH₂ group, an —OH group, and a —COOH group in a molecule.

### Second Resin

In the resin composition according to the exemplary embodiment, the second resin is an epoxy resin.

In the resin composition according to the exemplary embodiment, the epoxy resin as the second resin is preferably, for instance, at least one epoxy resin selected from the group consisting of bixylenol epoxy resin, bisphenol A epoxy resin, bisphenol F epoxy resin, bisphenol S epoxy resin, bisphenol AF epoxy resin, dicyclopentadiene epoxy resin, trisphenol epoxy resin, xylene-structure-containing novolac epoxy resin, naphthol novolac epoxy resin, phenol novolac epoxy resin, tert-butyl catechol epoxy resin, naphthalene epoxy resin, naphthol epoxy resin, anthracene epoxy resin, glycidyl amine epoxy resin, glycidyl ester epoxy resin, cresol novolac epoxy resin, biphenyl epoxy resin, linear aliphatic epoxy resin, epoxy resin having a butadiene structure, alicyclic epoxy resin, heterocyclic epoxy resin, spiro-ring-containing epoxy resin, cyclohexane epoxy resin, cyclohexanedimethanol epoxy resin, naphthylene ether epoxy resin, trimethylol epoxy resin, and tetraphenylethane epoxy resin. In the resin composition according to the exemplary embodiment, the epoxy resin as the second resin may be used alone, or may be used in combination of two or more.

In the resin composition according to the exemplary embodiment, the second resin is preferably an epoxy resin having two or more epoxy groups in one molecule.

In the resin composition according to the exemplary embodiment, the second resin preferably includes at least one compound selected from the group consisting of compounds represented by formulae (E1), (E2), (E3), and (E4) below.

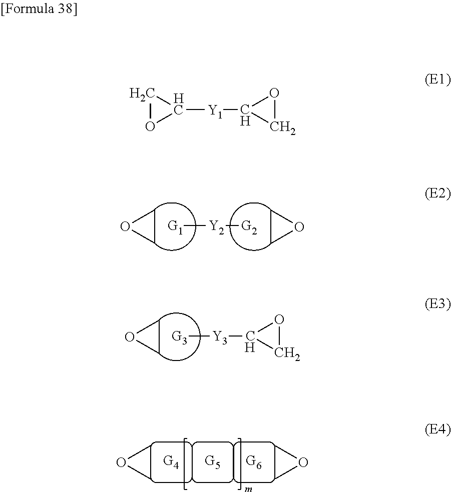

In the formula (E1), Y₁ represents a linking group linking epoxy groups to each other,
in formula (E2), G₁ and G₂ each independently represent a ring structure fused with an oxirane ring, and Y₂ represents a linking group that links the ring structure G₁ and the ring structure G₂,
in formula (E3), G₃ represents a ring structure fused with an oxirane ring, and Y₃ represents a linking group that links the ring structure G₃ and an epoxy group, and
in formula (E4), G₄ and G₆ each independently represent a ring structure fused with an oxirane ring, G₅ represents a ring structure fused with G₄ and G₆, and m is an integer of 0 or 1 or more, representing the number of ring structures G₅, in which when m is 0, the ring structure G₄ and the ring structure G₆ are directly fused with each other.

Y₁ to Y₃ as a linking group in the second resin are each independently preferably a group selected from the group (ep1) consisting of a substituted or unsubstituted alkylene group having 1 to 28 carbon atoms, a substituted or unsubstituted alkylidene group having 2 to 28 carbon atoms, a substituted or unsubstituted cycloalkylene group having 5 to 15 ring carbon atoms, a substituted or unsubstituted cycloalkylidene group having 3 to 26 ring carbon atoms, a substituted or unsubstituted arylene group having 6 to 20 ring carbon atoms, —S—, —SO—, —SO₂—, —O—, and —CO—, or (ep2) a divalent group formed by linking two or more groups selected from the group (ep1).

The group (ep2) is more preferably a divalent group formed by linking two to ten groups selected from the group (ep1), and still more preferably a divalent group formed by linking two to eight groups selected from the group (ep1).

In the second resin, the ring structures G₁ to G₆ are each independently preferably an aliphatic ring or an aromatic ring. Examples of the aliphatic rings in the ring structures G₁ to G₆ include a cyclopentane ring, a cyclohexane ring, a cycloheptane ring, a cyclooctane ring, a dicyclopentadiene ring, and a tricyclopentadiene ring. Examples of the aromatic rings in the ring structures G₁ to G₆ include a benzene ring, a naphthalene ring, an anthracene ring, and a fluorene ring.

### Cured Product

A cured product according to the exemplary embodiment is a cured product formed by curing the resin composition according to the exemplary embodiment.

The cured product according to the exemplary embodiment preferably has a crosslinking structure represented by a formula (C10) below.

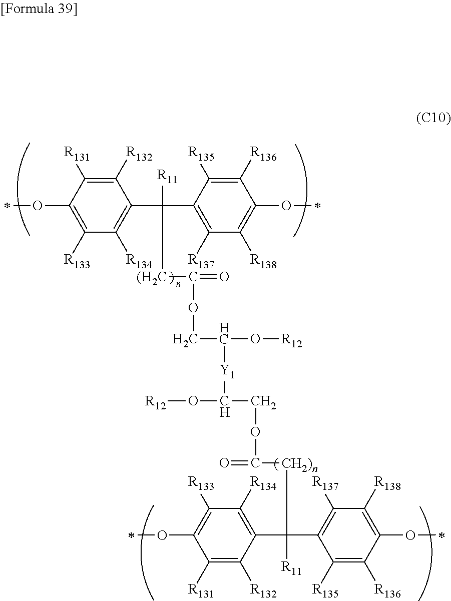

In the formula (C10):
R₁₁, R₁₂, R₁₃₁ to R₁₃₈, and n respectively represent the same as R₁₁, R₁₂, R₁₃₁ to R₁₃₈, and n in the formula (C1);
a plurality of Rₙ are identical to each other or different from each other;
a plurality of R₁₂ are identical to each other or different from each other;
a plurality of R₁₃₁ to R₁₃₈ are identical to each other or different from each other;
a plurality of n are identical to each other or different from each other;
Y₁ is a linking group; and
each * represents a bond.

Preferably, Y₁ in the formula (C10) represents the same as Y₁ in the formula (E1).

According to the resin composition of the exemplary embodiment, an epoxy thermosetting resin with improved dielectric properties can be obtained.

When a compound having an —NH₂ group, an —OH group, or a —COOH group is used as a curing agent for the epoxy resin, a thermosetting resin having an —OH group is produced after the curing reaction of the epoxy resin. The thermosetting resin having an —OH group exhibits poor dielectric properties.

On the other hand, the resin composition according to the exemplary embodiment uses the first resin (the resin according to the first exemplary embodiment) as a curing agent. The resin according to the first exemplary embodiment includes the structural unit represented by the formula (C1), in which R₁₂ is a substituted or unsubstituted monovalent or divalent aromatic hydrocarbon group, a substituted or unsubstituted monovalent or divalent cyclic aliphatic hydrocarbon group, or a substituted or unsubstituted monovalent or divalent acyclic aliphatic hydrocarbon group. Accordingly, according to the resin composition of the exemplary embodiment, the generation of a thermosetting resin having an —OH group is suppressed, and the dielectric properties of the thermosetting resin are improved, specifically, the dissipation factor can be reduced.

### Dielectric Properties

In the cured product according to the exemplary embodiment, the dielectric constant (Dk) measured with a split-cylinder resonator at a frequency of 10 GHz at room temperature (23 degrees C.) is preferably 3.00 or less, more preferably 2.80 or less, still more preferably 2.75 or less, still further more preferably 2.70 or less, and yet still further more preferably 2.65 or less.

Moreover, in the cured product according to the exemplary embodiment, the dissipation factor (Df) measured with a split-cylinder resonator at a frequency of 10 GHz at room temperature (23 degrees C.) is preferably 0.025 or less, more preferably 0.022 or less, still more preferably 0.020 or less, and still further more preferably 0.018 or less.

Since the dielectric constant (Dk) and the dissipation factor (Df) of the cured product according to the exemplary embodiment are equal to or less than the aforementioned upper limit values, the use of the cured product according to the exemplary embodiment as an electronic material can reduce loss of electric signals in the electronic material.

### EXAMPLES

Next, the invention will be described in more detail with reference to Examples and Comparatives. However, the invention is not limited to these Examples, and various modifications and applications can be made without departing from the idea of the invention.

### Production Examples: Preparation of Oligomer

### Production Example 1: Synthesis of 2,2-bis(4-hydroxyphenyl)pentanoic acid cyclohexyl oligomer (bischloroformate)

82.5 g (224 mmol) of 2,2-bis(4-hydroxyphenyl)pentanoic acid cyclohexyl was suspended in 1080 mL of methylene chloride, and 66.0 g (667 mmol) of phosgene was added thereto. To this solution, a liquid in which 44.0 g (435 mmol) of triethylamine was dissolved in 120 mL of methylene chloride was added dropwise in a temperature range from 5 degrees C. to 15 degrees C. Next, stirring was performed for 30 minutes, and methylene chloride was then distilled off until the concentration thereof reached a predetermined value. To the residual liquid, 210 mL of pure water, 1.2 g of concentrated hydrochloric acid, and 450 mg of hydrosulfite were added, and washing was performed. Subsequently, washing was repeated with 210 mL of pure water five times to obtain a methylene chloride solution of 2,2-bis(4-hydroxyphenyl)pentanoic acid cyclohexyl oligomer having a chloroformate group at molecular terminals. The obtained solution had a chloroformate concentration of 0.88 mol/L, a solid concentration of 0.231 kg/L, and an average number of repeating units of 1.08. Hereinafter, the obtained oligomer according to Production Example 1 is referred to as DPACyHex-CF.

### Production Example 2: Synthesis of 1,1-bis(4-hydroxyphenyl)cyclohexane oligomer (bischloroformate)

The oligomer according to Production Example 2 was produced in the same manner as in Production Example 1, except that 60.1 g (224 mmol) of 1,1-bis(4-hydroxyphenyl)cyclohexane was used in place of 2,2-bis(4-hydroxyphenyl)pentanoic acid cyclohexyl. The obtained solution had a chloroformate concentration of 1.10 mol/L, a solid concentration of 0.222 kg/L, and an average number of repeating units of 1.04. Hereinafter, the obtained oligomer according to Production Example 2 is referred to as Z-CF.

### Production Example 3: Synthesis of 1,1-bis(4-hydroxy-3-methylphenyl)-3,3,5-trimethylcyclohexane oligomer (bischloroformate)

The oligomer according to Production Example 3 was produced in the same manner as in Production Example 1, except that 75.8 g (224 mmol) of 1,1-bis(4-hydroxy-3-methylphenyl)-3,3,5-trimethylcyclohexane was used in place of 2,2-bis(4-hydroxyphenyl)pentanoic acid cyclohexyl. The obtained solution had a chloroformate concentration of 0.92 mol/L, a solid concentration of 0.223 kg/L, and an average number of repeating units of 1.06. Hereinafter, the obtained oligomer according to Production Example 3 is referred to as OCTMC-CF.

### Production Example 4: Synthesis of 1,1-bis(3-cyclohexyl-4-hydroxyphenyl)cyclohexane oligomer (bischloroformate)

The oligomer according to Production Example 4 was produced in the same manner as in Production Example 1, except that 96.9 g (224 mmol) of 1,1-bis(3-cyclohexyl-4-hydroxyphenyl)cyclohexane was used in place of 2,2-bis(4-hydroxyphenyl)pentanoic acid cyclohexyl. The obtained solution had a chloroformate concentration of 0.77 mol/L, a solid concentration of 0.222 kg/L, and an average number of repeating units of 1.04. Hereinafter, the obtained oligomer according to Production Example 4 is referred to as CHZ-CF.

### Synthesis Example 1

### Production of PC Polymer

Into a reaction vessel equipped with a mechanical stirrer, stirring blades, and baffles, 216 mL of DPACyHex-CF obtained in Production Example 1, 339 mL of methylene chloride, 35.1 g of 2,2-bis(4-hydroxyphenyl)pentanoic acid cyclohexyl (hereinafter referred to as DPACyHex), and 0.235 g of p-tert-butylphenol (hereinafter referred to as PTBP) were added, followed by stirring so as to be sufficiently mixed, thereby obtaining a methylene chloride solution (M1). To the methylene chloride solution (M1) was added the whole amount of an aqueous sodium hydroxide solution (prepared by cooling 185 mL of a 2.0 N aqueous sodium hydroxide solution (14.7 g of sodium hydroxide) to room temperature or lower, then adding 0.23 g of sodium hydrosulfite and completely dissolving the same), followed by addition of an aqueous triethylamine solution (7 vol %, 2.52 mL) with stirring, and stirring was continued for 1 hour.

The resulting reaction mixture was diluted with 0.72 L of methylene chloride and 0.04 L of water, and washing was performed. After the washing, the lower layer was separated and further washed with 0.23 L of water once, with 0.23 L of 0.03 N hydrochloric acid once, and with 0.23 L of water three times in this order. The resulting methylene chloride solution was added dropwise to methanol under stirring, and the resulting reprecipitated substance was filtered and dried to obtain a PC polymer (PC-1) having a structure below.

### Identification of PC Polymer

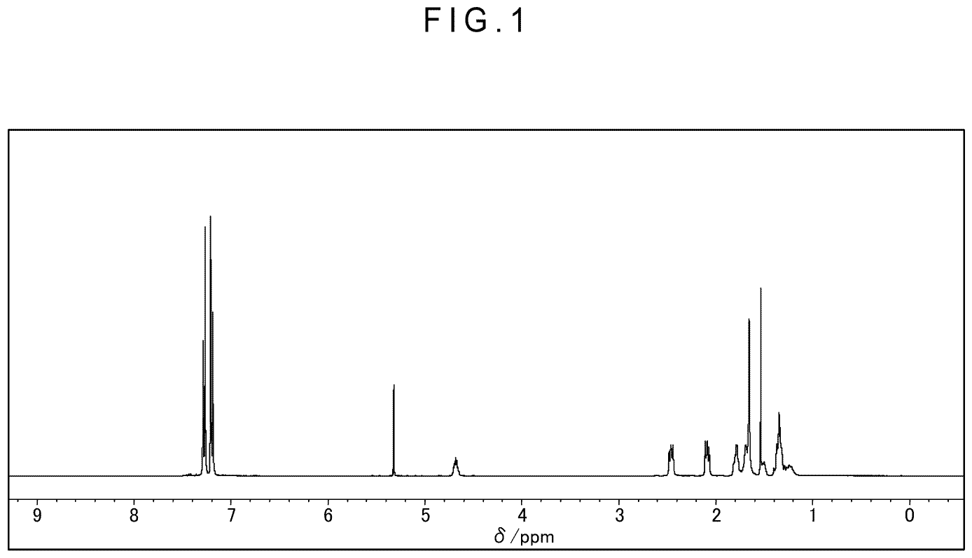

The PC polymer (PC-1) thus obtained was dissolved in methylene chloride to prepare a solution with a concentration of 0.5 g/dL, and a reduced viscosity [ηsp/C] at 20 degrees C. was measured. The reduced viscosity was 1.56 dL/g. The structure and the composition of the obtained PC polymer (PC-1) were analyzed by ¹H-NMR spectroscopy. The results confirmed that the PC polymer (PC-1) was a PC polymer having the following repeating units. The repeating units derived from the oligomer DPACyHex-CF according to Production Example 1 and the raw material monomer DPACyHex included the structural unit represented by the formula (C1) and the structural unit represented by the formula (B1), in which the mole fraction c was 50 mol % and the mole fraction b was 50 mol %. The ¹H-NMR spectrum of the PC polymer (PC-1) is shown in FIG. 1.

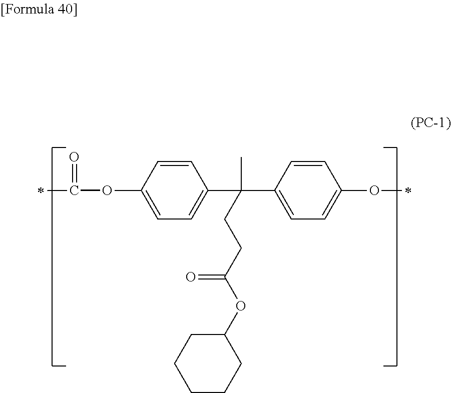

### Synthesis Example 2

### Production of PC Polymer

A PC polymer (PC-2) having a structure below was obtained in the same manner as in Synthesis Example 1, except that Z-CF obtained in Production Example 2 was used in place of DPACyHex-CF.

### Identification of PC Polymer

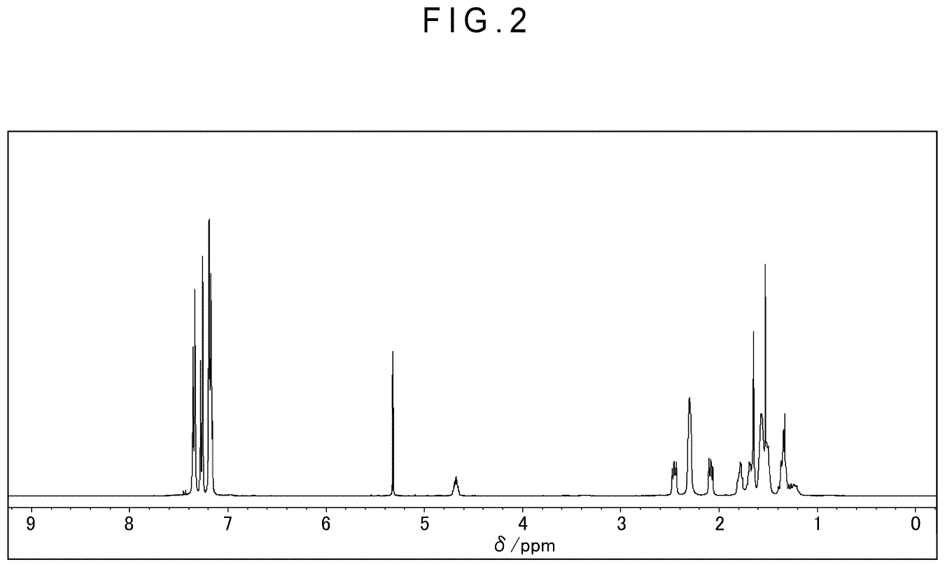

The PC polymer (PC-2) thus obtained was dissolved in methylene chloride to prepare a solution with a concentration of 0.5 g/dL, and a reduced viscosity [ηsp/C] at 20 degrees C. was measured. The reduced viscosity was 0.91 dL/g. The structure and the composition of the obtained PC polymer (PC-2) were analyzed by ¹H-NMR spectroscopy. The results confirmed that the PC polymer (PC-2) was a PC polymer having the following repeating units and composition. The ¹H-NMR spectrum of the PC polymer (PC-2) is shown in FIG. 2.

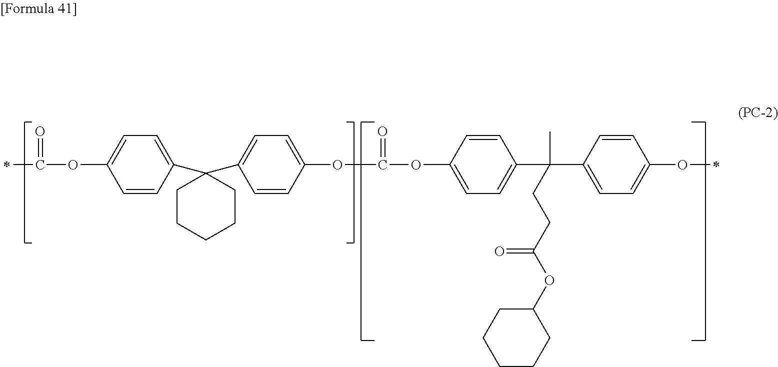

In the PC polymer (PC-2), the repeating unit [Z] derived from the oligomer Z-CF according to Production Example 2 included the structural unit represented by the formula (D1) and the structural unit represented by the formula (B1), and the repeating unit [DPACyHex] derived from the raw material monomer DPACyHex included the structural unit represented by the formula (C1) and the structural unit represented by the formula (B1), in which the mole fraction c was 20 mol %, the mole fraction b was 50 mol %, and the mole fraction d was 30 mol %. The composition ratio (mol %) of the repeating units in the PC polymer (PC-2) was [Z]:[DPACyHex]=60:40.

### Synthesis Example 3

### Production of PC Polymer

A PC polymer (PC-3) having a structure below was obtained in the same manner as in Synthesis Example 1, except that OCTMC-CF obtained in Production Example 3 was used in place of DPACyHex-CF.

### Identification of PC Polymer

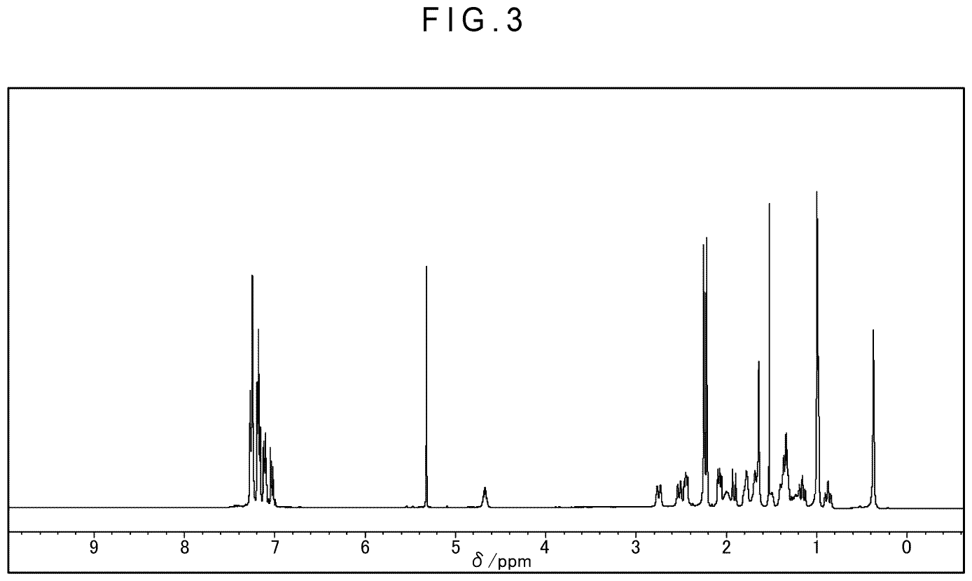

The PC polymer (PC-3) thus obtained was dissolved in methylene chloride to prepare a solution with a concentration of 0.5 g/dL, and a reduced viscosity [ηsp/C] at 20 degrees C. was measured. The reduced viscosity was 0.85 dL/g. The structure and the composition of the obtained PC polymer (PC-3) were analyzed by ¹H-NMR spectroscopy. The results confirmed that the PC polymer (PC-3) was a PC polymer having the following repeating units and composition. The ¹H-NMR spectrum of the PC polymer (PC-3) is shown in FIG. 3.

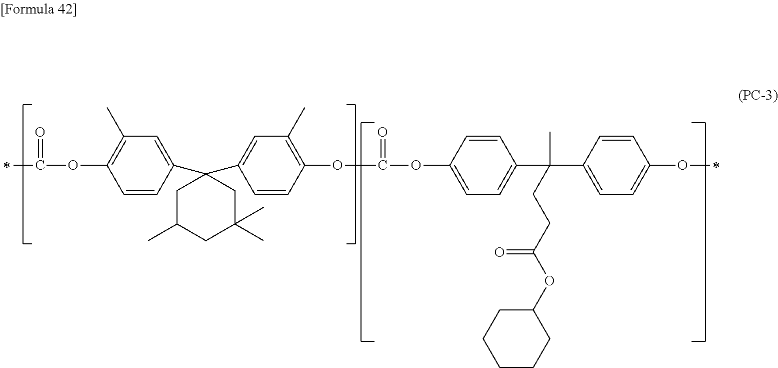

In the PC polymer (PC-3), the repeating unit [OCTMC] derived from the oligomer OCTMC-CF according to Production Example 3 included the structural unit represented by the formula (D1) and the structural unit represented by the formula (B1), and the repeating unit [DPACyHex] derived from the raw material monomer DPACyHex included the structural unit represented by the formula (C1) and the structural unit represented by the formula (B1), in which the mole fraction c was 20 mol %, the mole fraction b was 50 mol %, and the mole fraction d was 30 mol %. The composition ratio (mol %) of the repeating units in the PC polymer (PC-3) was [OCTMC]:[DPACyHex]=60:40.

### Synthesis Example 4

### Production of PC Polymer

A PC polymer (PC-4) having a structure below was obtained in the same manner as in Synthesis Example 1, except that CHZ-CF obtained in Production Example 4 was used in place of DPACyHex-CF.

### Identification of PC Polymer

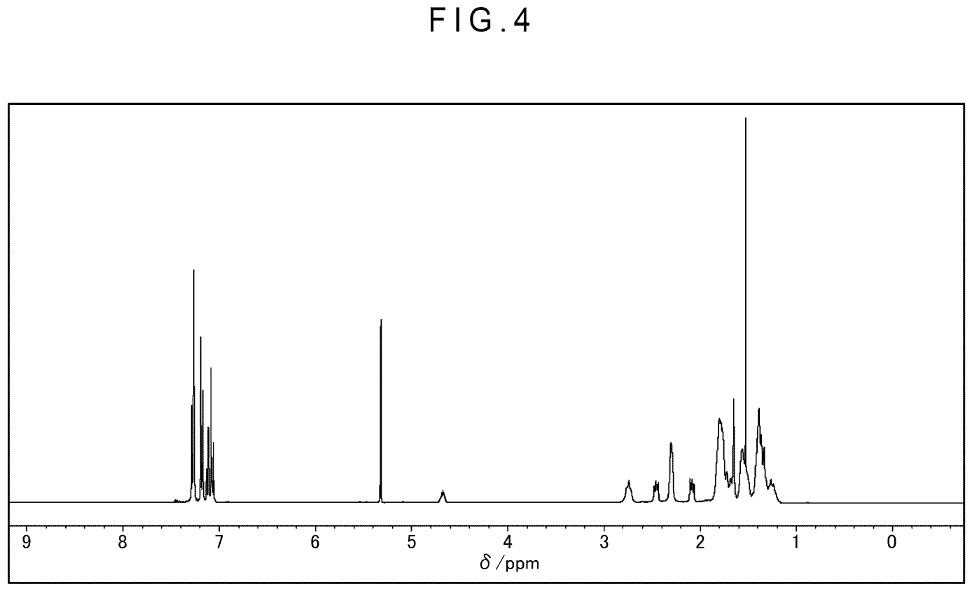

The PC polymer (PC-4) thus obtained was dissolved in methylene chloride to prepare a solution with a concentration of 0.5 g/dL, and a reduced viscosity [ηsp/C] at 20 degrees C. was measured. The reduced viscosity was 0.75 dL/g. The structure and the composition of the obtained PC polymer (PC-4) were analyzed by ¹H-NMR spectroscopy. The results confirmed that the PC polymer (PC-4) was a PC polymer having the following repeating units and composition. The ¹H-NMR spectrum of the PC polymer (PC-4) is shown in FIG. 4.

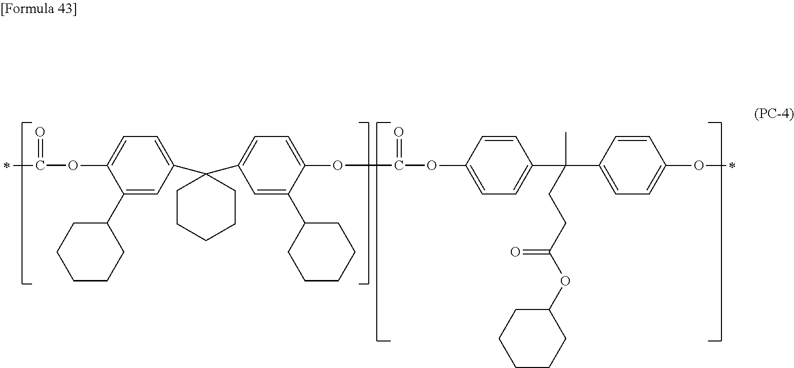

In the PC polymer (PC-4), the repeating unit [CHZ] derived from the oligomer CHZ-CF according to Production Example 4 included the structural unit represented by the formula (D1) and the structural unit represented by the formula (B1), and the repeating unit [DPACyHex] derived from the raw material monomer DPACyHex included the structural unit represented by the formula (C1) and the structural unit represented by the formula (B1), in which the mole fraction c was 20 mol %, the mole fraction b was 50 mol %, and the mole fraction d was 30 mol %. The composition ratio (mol %) of the repeating units in the PC polymer (PC-4) was [CHZ]:[DPACyHex]=60:40.

### Synthesis Example 5

### Production of PC Polymer

A PC polymer (PC-5) having a structure below was obtained in the same manner as in Synthesis Example 2, except that 46.3 g of 2,2-bis(4-hydroxy-3,5-dimethylphenyl)pentanoic acid-3,3,5-trimethylcyclohexyl (hereinafter referred to as TMDPATMC) was used in place of DPACyHex-CF.

### Identification of PC Polymer

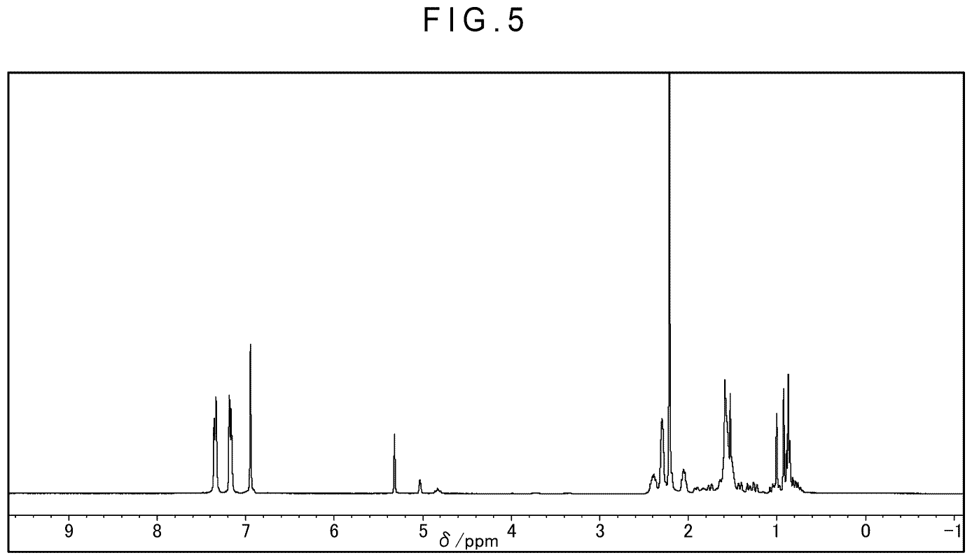

The PC polymer (PC-5) thus obtained was dissolved in methylene chloride to prepare a solution with a concentration of 0.5 g/dL, and a reduced viscosity [ηsp/C] at 20 degrees C. was measured. The reduced viscosity was 1.27 dL/g. The structure and the composition of the obtained PC polymer (PC-5) were analyzed by ¹H-NMR spectroscopy. The results confirmed that the PC polymer (PC-5) was a PC polymer having the following repeating units and composition. The ¹H-NMR spectrum of the PC polymer (PC-5) is shown in FIG. 5.

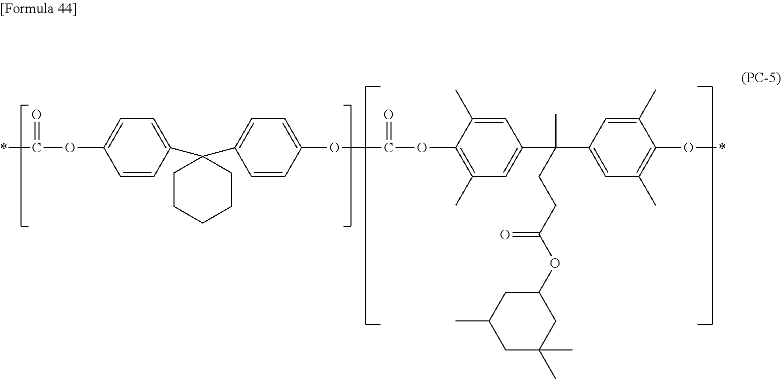

In the PC polymer (PC-5), the repeating unit [Z] derived from the oligomer Z-CF according to Production Example 2 included the structural unit represented by the formula (D1) and the structural unit represented by the formula (B1), and the repeating unit [TMDPATMC] derived from the raw material monomer TMDPATMC included the structural unit represented by the formula (C1) and the structural unit represented by the formula (B1), in which the mole fraction c was 20 mol %, the mole fraction b was 50 mol %, and the mole fraction d was 30 mol %. The composition ratio (mol %) of the repeating units in the PC polymer (PC-5) was [Z]:[TMDPATMC]=60:40.

### Synthesis Example 6

### Production of PC Polymer

A PC polymer (PC-6) having a structure below was obtained in the same manner as in Synthesis Example 5, except that OCTMC-CF obtained in Production Example 3 was used in place of Z-CF.

### Identification of PC Polymer

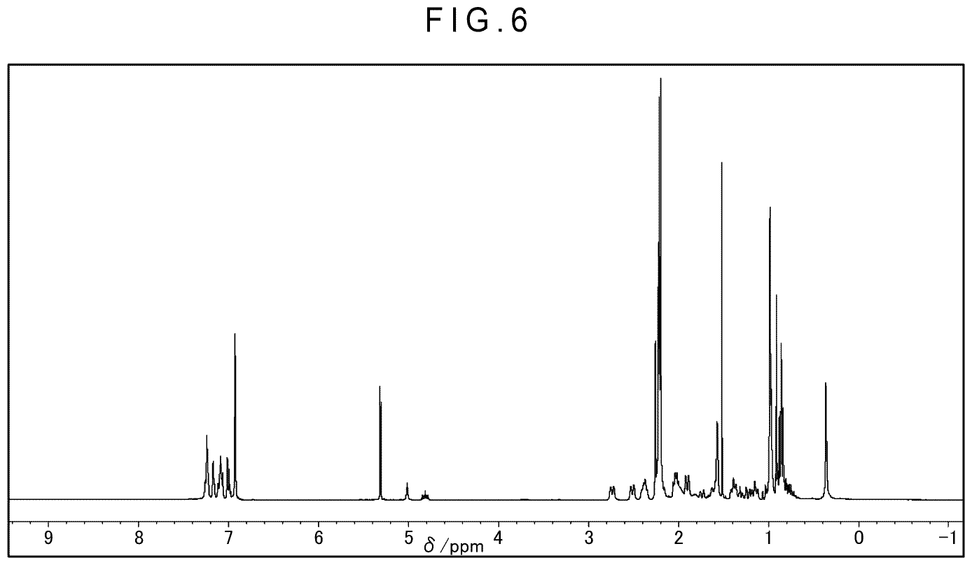

The PC polymer (PC-6) thus obtained was dissolved in methylene chloride to prepare a solution with a concentration of 0.5 g/dL, and a reduced viscosity [ηsp/C] at 20 degrees C. was measured. The reduced viscosity was 0.95 dL/g. The structure and the composition of the obtained PC polymer (PC-6) were analyzed by ¹H-NMR spectroscopy. The results confirmed that the PC polymer (PC-6) was a PC polymer having the following repeating units and composition. The ¹H-NMR spectrum of the PC polymer (PC-6) is shown in FIG. 6.

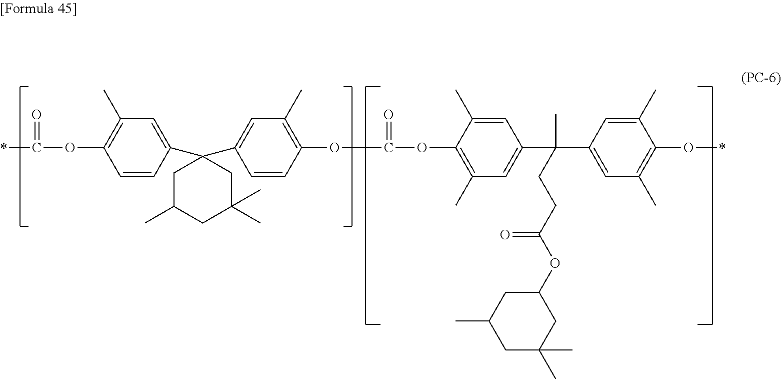

In the PC polymer (PC-6), the repeating unit [OCTMC] derived from the oligomer OCTMC-CF according to Production Example 3 included the structural unit represented by the formula (D1) and the structural unit represented by the formula (B1), and the repeating unit [TMDPATMC] derived from the raw material monomer TMDPATMC included the structural unit represented by the formula (C1) and the structural unit represented by the formula (B1), in which the mole fraction c was 20 mol %, the mole fraction b was 50 mol %, and the mole fraction d was 30 mol %. The composition ratio (mol %) of the repeating units in the PC polymer (PC-6) was [OCTMC]:[TMDPATMC]=60:40.

### Synthesis Example 7

### Production of PC Polymer

A PC polymer (PC-7) having a structure below was obtained in the same manner as in Synthesis Example 5, except that CHZ-CF obtained in Production Example 4 was used in place of Z-CF.

### Identification of PC Polymer

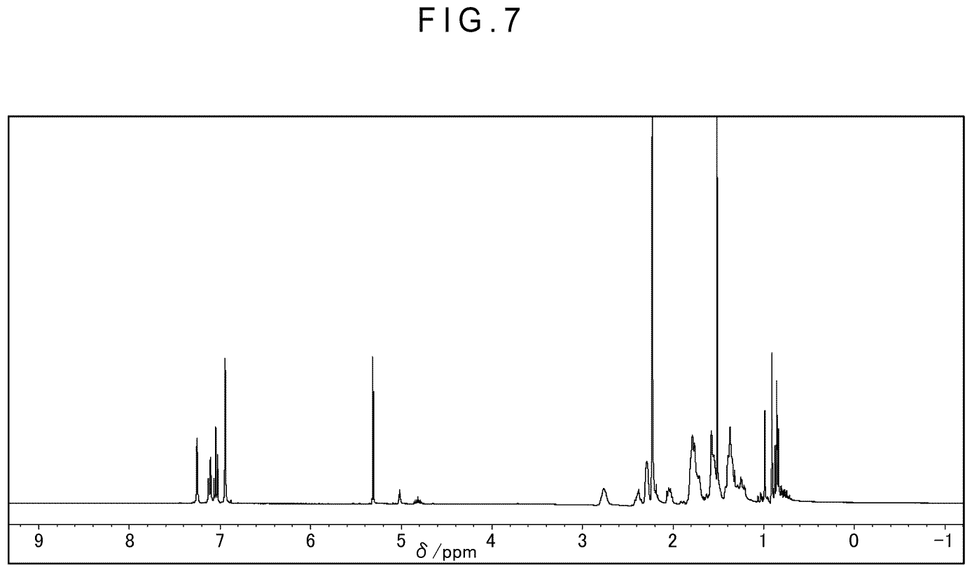

The PC polymer (PC-7) thus obtained was dissolved in methylene chloride to prepare a solution with a concentration of 0.5 g/dL, and a reduced viscosity [ηsp/C] at 20 degrees C. was measured. The reduced viscosity was 0.71 dL/g. The structure and the composition of the obtained PC polymer (PC-7) were analyzed by ¹H-NMR spectroscopy. The results confirmed that the PC polymer (PC-7) was a PC polymer having the following repeating units and composition. The ¹H-NMR spectrum of the PC polymer (PC-7) is shown in FIG. 7.

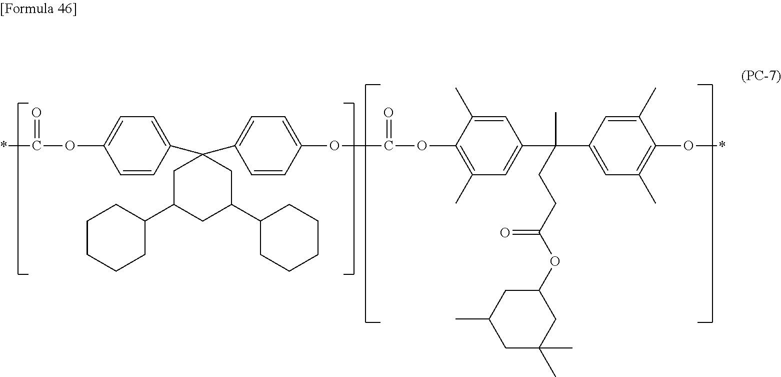

In the PC polymer (PC-7), the repeating unit [CHZ] derived from the oligomer CHZ-CF according to Production Example 4 included the structural unit represented by the formula (D1) and the structural unit represented by the formula (B1), and the repeating unit [TMDPATMC] derived from the raw material monomer TMDPATMC included the structural unit represented by the formula (C1) and the structural unit represented by the formula (B1), in which the mole fraction c was 20 mol %, the mole fraction b was 50 mol %, and the mole fraction d was 30 mol %. The composition ratio (mol %) of the repeating units in the PC polymer (PC-7) was [CHZ]:[TMDPATMC]=60:40.

### Synthesis Example 8

### Production of Polyester Polymer

Into a reaction vessel equipped with a mechanical stirrer, stirring blades, and baffles were charged 18.6 g of sodium hydroxide and 813 g of purified water, and after being completely dissolved and cooled to room temperature or lower, 55.0 g of 2,2-bis(4-hydroxyphenyl)pentanoic acid cyclohexyl (DPACyHex), 0.19 g of PTBP, 450 mg of sodium hydrosulfite, and 395 mg of benzyltripropylammonium chloride were added, thereby obtaining an aqueous sodium hydroxide solution. To this solution, a methylene chloride solution prepared by dissolving 31.4 g of 1,4-cyclohexanedicarbonyl dichloride (14CHDC) in 348 mL of methylene chloride was added dropwise over 30 minutes while maintaining the temperature at 13±3 degrees C., and stirring was continued for 1 hour.

The resulting reaction mixture was diluted with 1.36 L of methylene chloride and washed. The lower layer was separated and further washed with 0.30 L of water once, with 0.30 L of 0.03 N hydrochloric acid once, and with 0.30 L of water twice in this order. The resulting methylene chloride solution was added dropwise to methanol under stirring, and the resulting reprecipitated substance was filtered and dried to obtain a polyester (PE) polymer (PE-1) having a structure below.

### Identification of PE Polymer

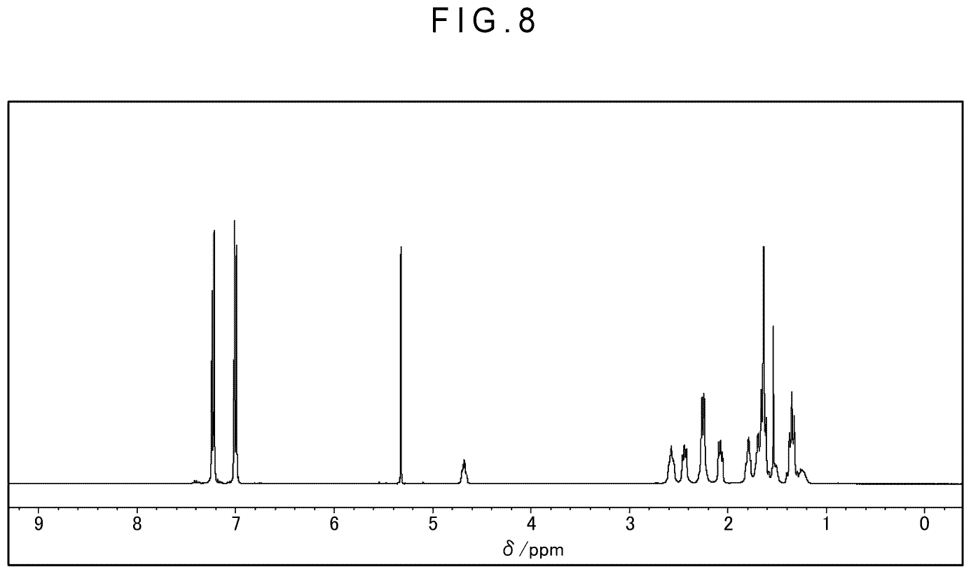

The PE polymer (PE-1) thus obtained was dissolved in methylene chloride to prepare a solution with a concentration of 0.5 g/dL, and a reduced viscosity [ηsp/C] at 20 degrees C. was measured. The reduced viscosity was 0.83 dL/g. The structure and the composition of the obtained PE polymer (PE-1) were analyzed by ¹H-NMR spectroscopy. The results confirmed that the PE polymer (PE-1) was a PE polymer having the following repeating units and composition. The ¹H-NMR spectrum of the PE polymer (PE-1) is shown in FIG. 8.

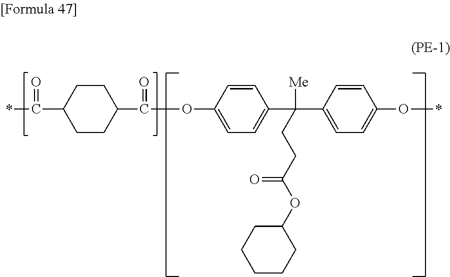

In the PE polymer (PE-1), the repeating unit [14CHDC] derived from the raw material monomer 14CHDC included the structural unit represented by formula (A1), and the repeating unit [DPACyHex] derived from the raw material monomer DPACyHex included the structural unit represented by the formula (C1), in which the mole fraction c was 50 mol % and the mole fraction a was 50 mol %. The composition ratio (mol %) of the repeating units in the PE polymer (PE-1) was [14CHDC]:[DPACyHex]=50:50.

Preparation of Coating Liquid Composition including Polycarbonate or Polyester, and Production of Resin Film (1)

### Example 1-1

1.1 g of the PC polymer (PC-1) was weighed into a sample tube with a screw cap, dissolved in 6 g of tetrahydrofuran, whereby a coating liquid composition was obtained. The resulting coating liquid composition was applied to a glass plate by casting using an applicator with a gap of 500 μm to form a film of the coating liquid composition. The film was air-dried for 1 hour and dried under reduced pressure in a vacuum dryer at a temperature of 50 degrees C. for 8 hours and then at a temperature of 110 degrees C. for 8 hours to remove the solvent, thereby obtaining a resin film of Example 1-1 having a thickness of 50 to 100 μm.

### Example 1-2

A resin film according to Example 1-2 was obtained in the same manner as in Example 1-1, except that the PC polymer (PC-2) was used in place of the PC polymer (PC-1).

### Example 1-3

A resin film according to Example 1-3 was obtained in the same manner as in Example 1-1, except that the PC polymer (PC-3) was used in place of the PC polymer (PC-1).

### Example 1-4

A resin film according to Example 1-4 was obtained in the same manner as in Example 1-1, except that the PC polymer (PC-4) was used in place of the PC polymer (PC-1).

### Example 1-5

A resin film according to Example 1-5 was obtained in the same manner as in Example 1-1, except that the PC polymer (PC-5) was used in place of the PC polymer (PC-1).

### Example 1-6

A resin film according to Example 1-6 was obtained in the same manner as in Example 1-1, except that the PC polymer (PC-6) was used in place of the PC polymer (PC-1).

### Example 1-7

A resin film according to Example 1-7 was obtained in the same manner as in Example 1-1, except that the PC polymer (PC-7) was used in place of the PC polymer (PC-1).

### Example 1-8

A resin film according to Example 1-8 was obtained in the same manner as in Example 1-1, except that the PC polymer (PE-1) was used in place of the PC polymer (PC-1).

### Comparative 1-1

A resin film according to Comparative 1-1 was obtained in the same manner as in Example 1-1, except that a polycarbonate resin (BisA-PC) made from bisphenol A was used in place of the PC polymer (PC-1). BisA-PC had a repeating unit below, and its reduced viscosity [ηsp/C] at 20 degrees C. was 0.74 dL/g.

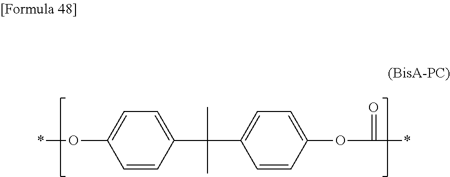

### Comparative 1-2

A resin film was obtained in the same manner as in Example 1-1, except that a polycarbonate resin (BisZ-PC) made from 1,1-bis(4-hydroxyphenyl)cyclohexane was used in place of the PC polymer (PC-1). BisZ-PC had a repeating unit below, and its reduced viscosity [ηsp/C] at 20 degrees C. was 0.92 dL/g.

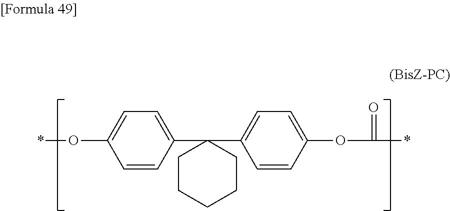

### Evaluation of Physical Properties of Polycarbonate Resin and Polyester Resin

The physical properties of the polycarbonate resin (PC polymer) and the polyester resin (PE polymer) were evaluated by the following methods.

Reduced Viscosity [ηsp/C]

A solution having a concentration of 0.5 g/dL was prepared by dissolving a polycarbonate resin or a polyester resin in methylene chloride serving as a solvent, and the reduced viscosity [ηsp/C] of this solution was measured at 20±0.01 degrees C. using an Ubbelohde viscometer. A flow time of the solvent alone was 72.4 seconds.

### Viscosity Average Molecular Weight Mv

The viscosity average molecular weight (Mv) was calculated according to the following Schnell's equation, by preparing a solution through dissolving a polycarbonate resin or a polyester resin in methylene chloride serving as a solvent, measuring the intrinsic viscosity [9] of the solution at 20 degrees C. using an Ubbelohde viscometer, and using the measured value in the equation.

$$[ η ] = 1.23 \times 1 {0}^{- 5} {Mv}^{0.83}$$

### Evaluation of Dielectric Constant and Dissipation Factor

A square film having 60 mm in length and 60 mm in width was cut out from the resin film and conditioned for 24 hours at a room temperature of 22±1 degrees C. and humidity of 33±5%. The dielectric constant (Dk) and dissipation factor (Df) were then measured at a frequency of 10 GHz using a split cylinder resonator (produced by EM labs, Inc.) and a network analyzer (Keysight Technologies). The obtained results are shown in Table 1.

### Evaluation of Solubility in Non-Halogen Solvents (Methyl Ethyl Ketone, Cyclohexanone)

Into a sample tube, 0.5 g (20 mass %) or 0.105 g (5 mass %) of the resin film and 2.0 g of methyl ethyl ketone (MEK) or cyclohexanone were charged and stirred at room temperature to prepare a solution. After 24 hours, the appearance of the solution was visually inspected. The obtained results are shown in Table 1.
A: In the solution with a concentration of 20 mass %, no insoluble matter was observed, and the solution was transparent.
B: In the solution with a concentration of 20 mass %, turbidity was visually observed, and in the solution with a concentration of 5 mass %, no insoluble matter was observed, and the solution was transparent.
C: In both the 20 mass % solution and the 5 mass % solution, insoluble matter was present.

### Evaluation of Glass Transition Temperature and Thermal Expansion Coefficient

A strip of film having 40 mm in length and 4 mm in width was cut out from the resin film, and measurement was performed using TMA (product name TMA7100 produced by Hitachi High-Tech Corporation). The obtained results are shown in Table 1.
Measurement mode: Tensile
Temperature condition: −30 degrees C. to 320 degrees C.
Heating rate: 5 degrees C./min

Data processing method: The coefficient of thermal expansion (CTE) was calculated in a range from 40 degrees C. to 100 degrees C., and the glass transition temperature (Tg) was determined using an inflection point temperature.

TABLE 1

| | PC resin/PE resin | | | | | | | |
|---|---|---|---|---|---|---|---|---|
| | | Viscosity average | | | Thermal properties | | | |
| | | molecular weight | Dielectric properties | | Tg | CTE | Solubility (A/B/C) | |
| | Name | M v | Dk | Df | [° C.] | [ppm/K] | Cyclohexane | MEK |
| Ex. 1-1 | PC-1 | 68500 | 2.73 | 0.01558 | 165 | 113 | A | A |
| Ex. 1-2 | PC-2 | 48600 | 2.71 | 0.00664 | 143 | 90 | A | B |
| Ex. 1-3 | PC-3 | 40100 | 2.59 | 0.00539 | 176 | 84 | A | A |
| Ex. 1-4 | PC-4 | 32200 | 2.64 | 0.00456 | 128 | 79 | A | A |
| Ex. 1-5 | PC-5 | 55800 | 2.74 | 0.00227 | 166 | 79 | A | A |
| Ex. 1-6 | PC-6 | 41100 | 2.52 | 0.00304 | 164 | 84 | A | A |
| Ex. 1-7 | PC-7 | 30100 | 2.49 | 0.00262 | 140 | 76 | A | A |
| Ex. 1-8 | PE-1 | 36000 | 2.77 | 0.01811 | 188 | 118 | A | B |
| Comp. 1-1 | BisA-PC | 33000 | 2.76 | 0.00502 | 172 | 76 | C | C |
| Comp. 1-2 | BisZ-PC | 40000 | 2.73 | 0.00385 | 186 | 73 | A | C |

### Results and Discussion

The polycarbonate resins according to Examples 1-1 to 1-7 and the polyester resin according to Example 1-8, which included a diphenolic acid ester structure in the repeating units, were well dissolved in methyl ethyl ketone and cyclohexanone, which were non-halogen solvents, at a specific concentration. On the other hand, the polycarbonate resins according to Comparative 1-1 and 1-2 were not dissolved in methyl ethyl ketone in either case, and it was difficult to perform solution molding using non-halogen solvents. Furthermore, all of the resin films according to Examples 1-1 to 1-8 were transparent. In addition, the polycarbonate resins according to Examples 1-1 to 1-7 and the polyester resin according to Example 1-8 exhibited dielectric properties that enabled their use as the electronic substrate material. Accordingly, the resin according to one embodiment of the invention is suitable for solution molding using a non-halogen solvent without impairing the dielectric properties and thermal properties of the resin.

Preparation of Coating Liquid Composition including Polycarbonate or Polyester, and Production of Resin Film (2)

### Example 2-1

25 parts by mass of the PC polymer (PC-1), 25 parts by mass of a bisphenol A epoxy resin (hereinafter referred to as EP-BisA), and 1 part by mass of dimethylaminopyridine (hereinafter referred to as DMAP) were weighed into a sample tube with a screw cap, dissolved in 200 parts by mass of toluene, whereby a coating liquid composition was obtained. The resulting coating liquid composition was cast on a glass plate using an applicator with a gap of 500 μm to form a film, whereby a composition film was obtained. The composition film was allowed to stand at room temperature (25 degrees C.) and under atmospheric pressure for 1 hour, and then dried under reduced pressure at 100 degrees C. for 1 hour in a vacuum dryer. Subsequently, the composition film was peeled from the glass plate and dried under reduced pressure at 200 degrees C. for 1 hour, whereby a cured film having a thickness of 50 to 100 μm was obtained.

### Example 2-2

A cured film was obtained in the same manner as in Example 2-1, except that the PC polymer (PC-2) was used in place of the PC polymer (PC-1).

### Example 2-3

A cured film was obtained in the same manner as in Example 2-1, except that the PC polymer (PC-3) was used in place of the PC polymer (PC-1).

### Example 2-4

A cured film was obtained in the same manner as in Example 2-1, except that the PC polymer (PC-4) was used in place of the PC polymer (PC-1).

### Example 2-5

A cured film was obtained in the same manner as in Example 2-1, except that the PC polymer (PC-5) was used in place of the PC polymer (PC-1).

### Example 2-6

A cured film was obtained in the same manner as in Example 2-1, except that the PC polymer (PC-6) was used in place of the PC polymer (PC-1).

### Example 2-7

A cured film was obtained in the same manner as in Example 2-1, except that the PC polymer (PC-7) was used in place of the PC polymer (PC-1).

### Example 2-8

A cured film was obtained in the same manner as in Example 2-1, except that the PE polymer (PE-1) was used in place of the PC polymer (PC-1).

### Comparative 2-1

A cured film was obtained in the same manner as in Example 2-1, except that a polycarbonate resin (hereinafter referred to as BisA-PC, having a reduced viscosity [ηsp/C] of 0.74 dL/g at 20 degrees C.) made from bisphenol A was used in place of the PC polymer (PC-1) employed in Example 2-1, and methylene chloride (hereinafter referred to as MC) was used in place of toluene.

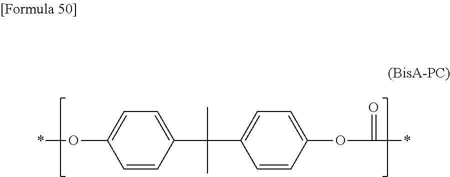

### Comparative 2-2

A cured film was obtained in the same manner as in Example 2-1, except that a polycarbonate resin (hereinafter referred to as BisZ-PC, having a reduced viscosity [ηsp/C] of 0.92 dL/g at 20 degrees C.) made from 1,1-bis(4-hydroxyphenyl)cyclohexane was used in place of the PC polymer (PC-1) employed in Example 2-1.

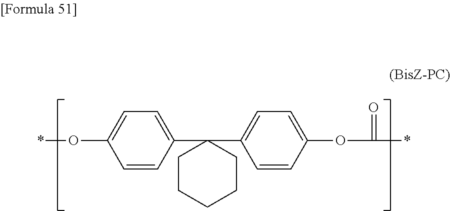

The physical properties of the cured films prepared were evaluated by the following methods.

### Evaluation of Dielectric Constant and Dissipation Factor

In the same manner as described above in “Evaluation of Dielectric Constant and Dissipation Factor”, the dielectric constant (Dk) and the dissipation factor (Df) of the cured films prepared were measured. The obtained results are shown in Table 2.

### Evaluation of Solubility of Composition in Non-Halogen Solvent (Toluene)

25 parts by mass of a polycarbonate resin or a polyester resin, 25 parts by mass of a bisphenol A epoxy resin (hereinafter referred to as EP-BisA), 1 part by mass of dimethylaminopyridine (hereinafter referred to as DMAP), and 200 parts by mass of toluene were weighed into a sample tube with a screw cap, whereby a coating liquid composition was prepared. After the prepared coating liquid composition was stirred at room temperature, the appearance of the coating liquid composition after 24 hours was visually inspected. The solubility was evaluated based on the evaluation criteria below, and the evaluation results are shown in Table 2. In the table, toluene is denoted as PhMe.

### Evaluation Criteria for Solubility in Non-Halogen Solvent

A: No insoluble matter was observed, and the solution was transparent.
B: A small amount of insoluble matter was present.
C: Insoluble matter was present.

### Evaluation of Curing Performance

As confirmation of the progress of the curing reaction, the solubility in methylene chloride, in which any of the polycarbonate resins or polyester resins dissolve, was examined. First, each cured film prepared was heated at 100 degrees C. for 1 hour. After heating, 1 part by mass of the film sample and 100 parts by mass of methylene chloride were weighed into a sample tube with a screw cap, stirred at room temperature (25 degrees C.), and the appearance of the film after 24 hours was visually inspected. The curing performance was evaluated based on the evaluation criteria below, and the evaluation results are shown in Table 2. In the table, methylene chloride is denoted as MC.

### Evaluation Criteria of Curing Performance

A: Insoluble matter was present. (That is, the curing reaction had proceeded.)
B: A small amount of insoluble matter was present.
C: No insoluble matter was observed, and the solution was transparent. (That is, the curing reaction had not proceeded.)

TABLE 2

| | Composition | | | | | | | |
|---|---|---|---|---|---|---|---|---|
| | Epoxy | PC resin/ | Curing | | | | | |
| | resin | PE resin | catalyst | Solvent | Dielectric | | Solubility | |
| | 25 parts | 25 parts | 1 parts | 200 parts | properties | | | MC |
| | by mass | by mass | by mass | by mass | Dk | Df | PhMe | (100° C.) |
| Ex. 2-1 | EP-BisA | PC-1 | DMAP | PhMe | 2.95 | 0.0202 | A | A |
| Ex. 2-2 | EP-BisA | PC-2 | DMAP | PhMe | 2.54 | 0.0095 | A | A |
| Ex. 2-3 | EP-BisA | PC-3 | DMAP | PhMe | 2.69 | 0.0171 | A | A |
| Ex. 2-4 | EP-BisA | PC-4 | DMAP | PhMe | 2.71 | 0.0171 | A | A |
| Ex. 2-5 | EP-BisA | PC-5 | DMAP | PhMe | 2.68 | 0.0187 | A | A |
| Ex. 2-6 | EP-BisA | PC-6 | DMAP | PhMe | 2.59 | 0.0216 | A | A |
| Ex. 2-7 | EP-BisA | PC-7 | DMAP | PhMe | 2.63 | 0.0204 | A | A |
| Ex. 2-8 | EP-BisA | PE-1 | DMAP | PhMe | 2.74 | 0.0163 | A | A |
| Comp. 2-1 | EP-BisA | BisA-PC | DMAP | MC | 2.70 | 0.0129 | C | C |
| Comp. 2-2 | EP-BisA | BisZ-PC | DMAP | PhMe | UM | UM | A | C |

“UM” in the table indicates that the value was unmeasurable.

### Results and Discussion

The polycarbonate resins according to Examples 2-1 to 2-7 and the polyester resin according to Example 2-8, each including a diphenolic acid ester structure in its repeating units, were insolubilized in the solvent under the conditions of low-temperature heat treatment at 100 degrees C. for a short time of 1 hour, and the progress of the curing reaction with the epoxy resin was confirmed. On the other hand, in the polycarbonate resins according to Comparatives 2-1 and 2-2, the curing reaction had not proceeded under the same heat treatment conditions. In addition, in Comparative 2-2, the film strength was insufficient, and it was difficult to produce a self-standing cured film.

The cured films obtained by heat-treating the resin compositions according to Examples at 200 degrees C. were all transparent. In addition, it was confirmed that the resin compositions according to Examples had the effect of reducing the dielectric constant and the dissipation factor of the cured films, as compared with the case where the epoxy compound was cured alone. According to the resin composition of Comparative 2-1, the dissipation factor was suppressed; however, the cured film obtained was whitened and the film strength was also insufficient. This is considered to be due to crystallization of the bisphenol A backbone, whereby the molecular mobility decreased and the dissipation factor was reduced, but the mechanical strength deteriorated. In particular, BisA-PC of Comparative 2-1 exhibited extremely low solubility in non-halogen solvents such as toluene, cyclohexanone, and methyl ethyl ketone, and was unsuitable for semiconductor applications.

Accordingly, the resin according to one embodiment of the invention can be easily cured together with an epoxy resin even under mild conditions of a low temperature and a short time, and can provide a material having favorable mechanical strength.

1. An electronic substrate material comprising: a first resin, wherein
the first resin is at least one resin selected from the group consisting of polycarbonate, polyester, and polyester polycarbonate, and
the first resin includes a structural unit represented by a formula (C1) below, and at least one structural unit selected from the group consisting of structural units represented by formulae (A1), (B1), and (D1) below, 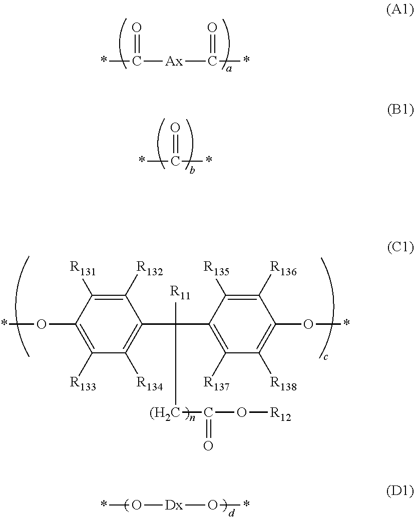
where in the formula (A1):
Ax is a divalent group containing at least one group selected from the group consisting of a substituted or unsubstituted divalent aromatic hydrocarbon group, a substituted or unsubstituted divalent cyclic aliphatic hydrocarbon group, and a substituted or unsubstituted divalent acyclic aliphatic hydrocarbon group; and
a is a mole fraction of the structural unit represented by the formula (A1),
in the formula (B1):
b is a mole fraction of the structural unit represented by the formula (B1); and
the structural unit represented by the formula (B1) is different from carbonyl groups in the formulae (A1), (C1), and (D1),
in the formula (C1):
R₁₁ is a hydrogen atom, a substituted or unsubstituted alkyl group having 1 to 20 carbon atoms, a substituted or unsubstituted cycloalkyl group having 3 to 20 ring carbon atoms, a substituted or unsubstituted cycloalkoxy group having 3 to 20 ring carbon atoms, a substituted or unsubstituted alkenyl group having 2 to 10 carbon atoms, or a substituted or unsubstituted aryl group having 6 to 14 carbon atoms;
R₁₂ is a group containing at least one selected from the group consisting of a substituted or unsubstituted monovalent aromatic hydrocarbon group, a substituted or unsubstituted monovalent cyclic aliphatic hydrocarbon group, a substituted or unsubstituted monovalent acyclic aliphatic hydrocarbon group, a substituted or unsubstituted divalent aromatic hydrocarbon group, a substituted or unsubstituted divalent cyclic aliphatic hydrocarbon group, and a substituted or unsubstituted divalent acyclic aliphatic hydrocarbon group;
R₁₃₁ to R₁₃₈ are each independently a hydrogen atom, a substituted or unsubstituted alkyl group having 1 to 10 carbon atoms, a substituted or unsubstituted alkenyl group having 2 to 10 carbon atoms, a substituted or unsubstituted alkynyl group having 2 to 10 carbon atoms, a substituted or unsubstituted cycloalkyl group having 3 to 20 ring carbon atoms, or a substituted or unsubstituted aryl group having 6 to 14 carbon atoms;
c is a mole fraction of the structural unit represented by the formula (C1); and
n represents 0, 1, 2, 3, or 4; and
in the formula (D1):
Dx is a divalent group containing at least one group selected from the group consisting of a substituted or unsubstituted divalent aromatic hydrocarbon group, a substituted or unsubstituted divalent cyclic aliphatic hydrocarbon group, and a substituted or unsubstituted divalent acyclic aliphatic hydrocarbon group; and
d is a mole fraction of the structural unit represented by the formula (D1),
substituents for a “substituted or unsubstituted” group are bonded to each other to form a monocyclic ring, bonded to each other to form a fused ring, or not bonded to each other,
each * in the formulae (A1), (B1), (C1), and (D1) represents a bond,
when the first resin includes a plurality of structural units represented by the formula (A1), the plurality of structural units represented by the formula (A1) are identical to each other or different from each other,
when the first resin includes a plurality of structural units represented by the formula (C1), the plurality of structural units represented by the formula (C1) are identical to each other or different from each other, and
when the first resin includes a plurality of structural units represented by the formula (D1), the plurality of structural units represented by the formula (D1) are identical to each other or different from each other.

2. The electronic substrate material according to claim 1, wherein the structural unit represented by the formula (D1) is represented by a formula (D2) below, 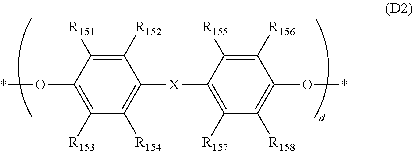
where in the formula (D2):
R₁₅₁ to R₁₅₈ are each independently selected from the group consisting of a hydrogen atom, a halogen atom, a substituted or unsubstituted alkyl group having 1 to 18 carbon atoms, a substituted or unsubstituted alkoxy group having 1 to 18 carbon atoms, a substituted or unsubstituted cycloalkyl group having 6 to 20 ring carbon atoms, a substituted or unsubstituted cycloalkoxy group having 6 to 20 ring carbon atoms, a substituted or unsubstituted alkenyl group having 2 to 10 carbon atoms, a substituted or unsubstituted aryl group having 6 to 14 ring carbon atoms, a substituted or unsubstituted aryloxy group having 6 to 14 ring carbon atoms, a substituted or unsubstituted aralkyl group having 7 to 20 carbon atoms, a substituted or unsubstituted aralkyloxy group having 7 to 20 carbon atoms, a nitro group, an aldehyde group, a cyano group, and a carboxy group;
X is (i) a single bond, (ii) a group selected from the group consisting of a substituted or unsubstituted alkylene group having 1 to 28 carbon atoms, a substituted or unsubstituted alkylidene group having 2 to 28 carbon atoms, a substituted or unsubstituted cycloalkylene group having 5 to 15 ring carbon atoms, a substituted or unsubstituted cycloalkylidene group having 3 to 26 ring carbon atoms, a substituted or unsubstituted arylene group having 6 to 20 ring carbon atoms, —S—, —SO—, —SO₂—, —O—, and —CO—, or (iii) a divalent group formed by linking two or more groups selected from the group recited in (ii);
d represents the same as d in the formula (D1); and
each * represents a bond.

3. The electronic substrate material according to claim 2, wherein X is a substituted or unsubstituted cycloalkylidene group having 5 to 15 ring carbon atoms.

4. (canceled)

5. (canceled)

6. The electronic substrate material according to claim 1, wherein
the first resin is a resin including the structural units represented by the formulae (C1) and (B1), and
a ratio c:d of a mole fraction c of the structural unit represented by the formula (C1) to a mole fraction d of the structural unit represented by the formula (D1) is from 0.5:99.5 to 100:0.

7. (canceled)

8. The electronic substrate material according to claim 1, wherein R₂ includes a substituted or unsubstituted monovalent cyclic aliphatic hydrocarbon group.

9. (canceled)

10. (canceled)

11. (canceled)

12. A coating liquid composition comprising:
the electronic substrate material according to claim 1; and
a non-halogen solvent.

13. The coating liquid composition according to claim 12, further comprising: an epoxy resin.

14. A film comprising the electronic substrate material according to claim 1.

15. A sheet comprising the electronic substrate material according to claim 1.

16. An electronic substrate comprising the electronic substrate material according to claim cl.

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. A resin composition comprising:
a first resin and a second resin, wherein
the first resin is at least one resin selected from the group consisting of polycarbonate, polyester, and polyester polycarbonate,
the first resin includes a structural unit represented by a formula (C1) below, and at least one structural unit selected from the group consisting of structural units represented by formulae (A1), (B1), and (D1) below, and
the second resin is an epoxy resin, 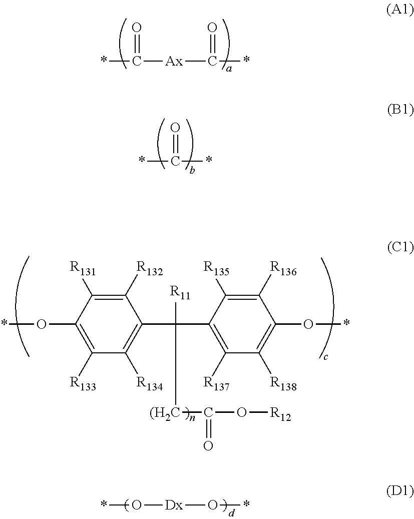
where in the formula (A1):
Ax is a divalent group containing at least one group selected from the group consisting of a substituted or unsubstituted divalent aromatic hydrocarbon group, a substituted or unsubstituted divalent cyclic aliphatic hydrocarbon group, and a substituted or unsubstituted divalent acyclic aliphatic hydrocarbon group;
a is a mole fraction of the structural unit represented by the formula (A1),
in the formula (B1):
b is a mole fraction of the structural unit represented by the formula (B1); and
the structural unit represented by the formula (B1) is different from carbonyl groups in the formulae (A1), (C1), and (D1),
in the formula (C1):
R₁₁ is a hydrogen atom, a substituted or unsubstituted alkyl group having 1 to 20 carbon atoms, a substituted or unsubstituted cycloalkyl group having 3 to 20 ring carbon atoms, a substituted or unsubstituted cycloalkoxy group having 3 to 20 ring carbon atoms, a substituted or unsubstituted alkenyl group having 2 to 10 carbon atoms, or a substituted or unsubstituted aryl group having 6 to 14 carbon atoms;
R₁₂ is a group containing at least one selected from the group consisting of a substituted or unsubstituted monovalent aromatic hydrocarbon group, a substituted or unsubstituted monovalent cyclic aliphatic hydrocarbon group, a substituted or unsubstituted monovalent acyclic aliphatic hydrocarbon group, a substituted or unsubstituted divalent aromatic hydrocarbon group, a substituted or unsubstituted divalent cyclic aliphatic hydrocarbon group, and a substituted or unsubstituted divalent acyclic aliphatic hydrocarbon group;
R₁₃₁ to R₁₃₈ are each independently a hydrogen atom, a substituted or unsubstituted alkyl group having 1 to 10 carbon atoms, a substituted or unsubstituted alkenyl group having 2 to 10 carbon atoms, a substituted or unsubstituted alkynyl group having 2 to 10 carbon atoms, a substituted or unsubstituted cycloalkyl group having 3 to 20 ring carbon atoms, or a substituted or unsubstituted aryl group having 6 to 14 carbon atoms;
c is a mole fraction of the structural unit represented by the formula (C1); and
n represents 0, 1, 2, 3, or 4; and
in the formula (D1):
Dx is a divalent group containing at least one group selected from the group consisting of a substituted or unsubstituted divalent aromatic hydrocarbon group, a substituted or unsubstituted divalent cyclic aliphatic hydrocarbon group, and a substituted or unsubstituted divalent acyclic aliphatic hydrocarbon group;
d is a mole fraction of the structural unit represented by the formula (D1),
substituents for a “substituted or unsubstituted” group are bonded to each other to form a monocyclic ring, bonded to each other to form a fused ring, or not bonded to each other,
each * in the formulae (A1), (B1), (C1), and (D1) represents a bond,
when the first resin includes a plurality of structural units represented by the formula (A1), the plurality of structural units represented by the formula (A1) are identical to each other or different from each other,
when the first resin includes a plurality of structural units represented by the formula (C1), the plurality of structural units represented by the formula (C1) are identical to each other or different from each other, and
when the first resin includes a plurality of structural units represented by the formula (D1), the plurality of structural units represented by the formula (D1) are identical to each other or different from each other.

30. The resin composition according to claim 29, wherein the structural unit represented by the formula (D1) is represented by a formula (D2) below, 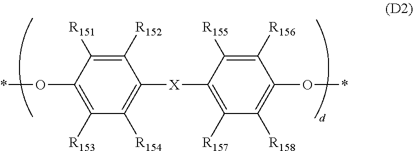
where in the formula (D2):
R₁₅₁ to R₁₅₈ are each independently selected from the group consisting of a hydrogen atom, a halogen atom, a substituted or unsubstituted alkyl group having 1 to 18 carbon atoms, a substituted or unsubstituted alkoxy group having 1 to 18 carbon atoms, a substituted or unsubstituted cycloalkyl group having 6 to 20 ring carbon atoms, a substituted or unsubstituted cycloalkoxy group having 6 to 20 ring carbon atoms, a substituted or unsubstituted alkenyl group having 2 to 10 carbon atoms, a substituted or unsubstituted aryl group having 6 to 14 ring carbon atoms, a substituted or unsubstituted aryloxy group having 6 to 14 ring carbon atoms, a substituted or unsubstituted aralkyl group having 7 to 20 carbon atoms, a substituted or unsubstituted aralkyloxy group having 7 to 20 carbon atoms, a nitro group, an aldehyde group, a cyano group, and a carboxy group;
X is (i) a single bond, (ii) a group selected from the group consisting of a substituted or unsubstituted alkylene group having 1 to 28 carbon atoms, a substituted or unsubstituted alkylidene group having 2 to 28 carbon atoms, a substituted or unsubstituted cycloalkylene group having 5 to 15 ring carbon atoms, a substituted or unsubstituted cycloalkylidene group having 3 to 26 ring carbon atoms, a substituted or unsubstituted arylene group having 6 to 20 ring carbon atoms, —S—, —SO—, —SO₂—, —O—, and —CO—, or (iii) a divalent group formed by linking two or more groups selected from the group described in (ii);
d represents the same as d in the formula (D1); and
each * represents a bond.

31. The resin composition according to claim 30, wherein X is a substituted or unsubstituted cycloalkylidene group having 5 to 15 ring carbon atoms.

32. (canceled)

33. (canceled)

34. The resin composition according to claim 29, wherein
the first resin is a resin including the structural units represented by the formulae (C1) and (B1), and
a ratio c:d of the mole fraction c of the structural unit represented by formula (C1) to the mole fraction d of the structural unit represented by formula (D1) is from 0.5:99.5 to 100:0.

35. (canceled)

36. (canceled)

37. (canceled)

38. (canceled)

39. (canceled)

40. (canceled)

41. The resin composition according to claim 29, wherein the structural unit represented by the formula (A1) is represented by a formula (A2), (A3), (A4), or (A5) below, 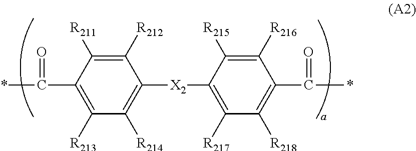
where in the formula (A2):
R₂₁₁ to R₂₁₈ are each independently selected from the group consisting of a hydrogen atom, a halogen atom, a substituted or unsubstituted alkyl group having 1 to 18 carbon atoms, a substituted or unsubstituted alkoxy group having 1 to 18 carbon atoms, a substituted or unsubstituted cycloalkyl group having 6 to 20 ring carbon atoms, a substituted or unsubstituted cycloalkoxy group having 6 to 20 ring carbon atoms, a substituted or unsubstituted alkenyl group having 2 to 10 carbon atoms, a substituted or unsubstituted aryl group having 6 to 14 ring carbon atoms, a substituted or unsubstituted aryloxy group having 6 to 14 ring carbon atoms, a substituted or unsubstituted aralkyl group having 7 to 20 carbon atoms, a substituted or unsubstituted aralkyloxy group having 7 to 20 carbon atoms, a nitro group, an aldehyde group, a cyano group, and a carboxy group;
X₂ is (i) a single bond, (ii) a group selected from the group consisting of a substituted or unsubstituted alkylene group having 1 to 28 carbon atoms, a substituted or unsubstituted alkylidene group having 2 to 28 carbon atoms, a substituted or unsubstituted cycloalkylene group having 5 to 15 ring carbon atoms, a substituted or unsubstituted cycloalkylidene group having 3 to 26 ring carbon atoms, a substituted or unsubstituted arylene group having 6 to 20 ring carbon atoms, —S—, —SO—, —SO₂—, —O—, and —CO—, or (iii) a divalent group formed by linking two or more groups selected from the group described in (ii);
a represents the same as a in the formula (A1); and
each * represents a bond, 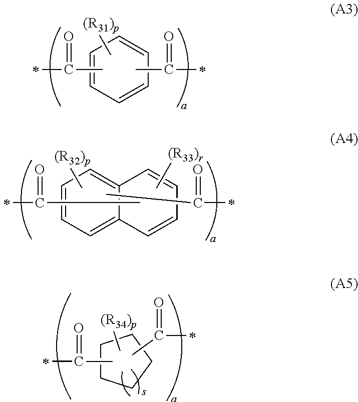
where in the formulae (A3), (A4), and (A5):
R₃₁ to R₃₄ are each independently selected from the group consisting of a hydrogen atom, a halogen atom, a substituted or unsubstituted alkyl group having 1 to 18 carbon atoms, a substituted or unsubstituted alkoxy group having 1 to 18 carbon atoms, a substituted or unsubstituted cycloalkyl group having 6 to 20 ring carbon atoms, a substituted or unsubstituted cycloalkoxy group having 6 to 20 ring carbon atoms, a substituted or unsubstituted alkenyl group having 2 to 10 carbon atoms, a substituted or unsubstituted aryl group having 6 to 14 ring carbon atoms, a substituted or unsubstituted aryloxy group having 6 to 14 ring carbon atoms, a substituted or unsubstituted aralkyl group having 7 to 20 carbon atoms, a substituted or unsubstituted aralkyloxy group having 7 to 20 carbon atoms, a nitro group, an aldehyde group, a cyano group, and a carboxy group;
p is 4;
q is 2, 3, or 4; r is 2, 3, or 4; and q+r is 6;
s is 1, 2, 3, 4, 5, 6, 7, or 8; and t is 2s+6;
a plurality of R₃₁ are identical to each other or different from each other;
a plurality of R₃₂ are identical to each other or different from each other;
a plurality of R₃₃ are identical to each other or different from each other;
a plurality of R₃₄ are identical to each other or different from each other;
a represents the same as a in the formula (A1); and
each * represents a bond.

42. The resin composition according to claim 29, wherein R12 includes a substituted or unsubstituted monovalent cyclic aliphatic hydrocarbon group.

43. (canceled)

44. (canceled)

45. (canceled)

46. (canceled)

47. A cured product comprising the resin composition according to claim 29.

48. (canceled)
